(19) United States
(12) Patent Application Publication
(10) Pub. No.: US 2016/0168422 A1
(43) Pub. Date: Jun. 16, 2016

(54) LAMINATE AND APPLICATION THEREFOR

(71) Applicant: FUJIFILM Corporation, Tokyo (JP)

(72) Inventors: Yu IWAI, Haibara-gun (JP); Ichiro KOYAMA, Haibara-gun (JP); Yoshitaka KAMOCHI, Haibara-gun (JP)

(73) Assignee: FUJIFILM Corporation, Tokyo (JP)

(21) Appl. No.: 15/047,945

(22) Filed: Feb. 19, 2016

Related U.S. Application Data
(63) Continuation of application No. PCT/JP2014/072368, filed on Aug. 27, 2014.

(30) Foreign Application Priority Data
Aug. 30, 2013 (JP) 2013-180041

(51) Int. Cl. C09J 4/06; C09D 169/00; H01L 21/683; C09D 145/00; C09J 4/00; C09D 181/06; C09D 125/06

(52) U.S. Cl. CPC C09J 4/06; C09D 181/06; C09D 169/00; C09D 125/06; C09D 145/00; C09J 4/00; H01L 21/6835; H01L 2221/68318; H01L 2221/6834

(57) ABSTRACT

Provided are a laminate capable of providing a temporary support for a member to be treated by a strongly adhesive force when the member to be treated is subjected to a mechanical or chemical treatment, and of easily releasing the temporary support for the treated member while not damaging the treated member, in which the TTV of the treated member is excellent; a composition for forming a protective layer; a composition for forming an adhesive layer; and a kit.

The laminate has, on a support (A), an adhesive layer having a softening point of 250° C. or higher (B), a protective layer (C), and a device wafer (D) in this order, in which the adhesive layer (B) is a cured product of an adhesive layer precursor and the adhesive layer precursor has a polymerizable compound (b-1).

This application is a Continuation of PCT International Application No. PCT/JP2014/072368 filed on Aug. 27 2014, which claims priority under 35 U.S.C §119(a) to Japanese Patent Application No. 2013-180041 filed on Aug. 30, 2013. Each of the above application(s) is hereby expressly incorporated by reference, in its entirety, into the present application.

### BACKGROUND OF THE INVENTION

1. Field of the Invention

The present invention relates to a laminate, a composition for forming a protective layer, a composition for forming an adhesive layer, and a kit. More specifically, the present invention relates to a laminate temporarily bonded to a support using a temporary adhesive for producing a semiconductor device; a composition for forming a protective layer and a composition for forming an adhesive layer, each of which is used in the laminate; and a kit including the composition for forming a protective layer and the composition for forming an adhesive layer.

2. Description of the Related Art

Heretofore, in the production process of a semiconductor device such as an IC and an LSI, usually, a large number of IC chips are formed on a semiconductor silicon wafer and diced by dicing.

With the needs for further miniaturization and higher performance of electronic devices, there is a demand for further miniaturization and higher integration of IC chips mounted on electronic devices, but the high integration of the integrated circuit in the plane direction of a silicon substrate is close to the limit.

As a method for electrical connection of an integrated circuit in an IC chip to an external terminal of the IC chip, a wire bonding method has been heretofore widely known. In order to miniaturize the IC chip, in recent years, a method where a through hole is provided in a silicon substrate and a metal plug, as the external terminal is connected to the integrated circuit so as to pass through the through hole (a method for forming a so-called through-silicon electrode (TSV)) has become known. However, according to the method for forming a through silicon-electrode singly, the needs of higher integration for the IC chip in recent years as described above have not been sufficiently fulfilled.

In light of the above, a technique of improving the integration density per unit area of the silicon substrate by making the integrated circuit in an IC chip multi-layered is known. However, since a multi-layered integrated circuit increases the thickness of the IC chip, reduction in the thickness of members constituting the IC chip is required. As to the reduction in the thickness of the members, for example, reduction in the thickness of the silicon substrate has been studied and is promising not only to lead to the miniaturization of an IC chip but also to save labor in a through-hole producing step of the silicon substrate in the manufacture of the through-silicon electrode.

As a semiconductor silicon wafer which is used in a process for producing a semiconductor device, a semiconductor silicon wafer having a thickness from about 700 μm to about 900 μm is widely known. In recent years, for the purpose of miniaturization of an IC chip, it has been attempted to reduce the thickness of a semiconductor silicon wafer to 200 μm or less.

However, since a semiconductor silicon wafer having a thickness of 200 μm or less is very thin and a member for producing a semiconductor device using this semiconductor silicon wafer as a base material is also very thin, and therefore, in the case, for example, where the member is subjected to an additional treatment or where the member is simply moved, it is difficult to support the member stably while not damaging the member.

In order to solve the problems as described above, a technique is known, in which a semiconductor wafer having a device provided on the surface thereof before reducing the thickness, a support substrate for a processing is temporarily adhered to a support substance for processing with a silicone adhesive, a back surface of the semiconductor wafer is ground to make it thin, the semiconductor wafer is punched to provide a through-silicon electrode, and then the support substrate for a processing is dissociated from the semiconductor wafer (see JP2011-119427A). It is described that according to this technique, resistance to grinding during grinding of the back surface of the semiconductor wafer, heat resistance in an anisotropic dry etching step or the like, chemical resistance during plating and etching, smooth final peeling from the support substrate for processing and a low adherend contamination property are able to be achieved at the same time.

Furthermore, as a method of supporting a wafer, a technique for supporting a wafer by a support layer system, in which between the wafer and the support layer system, a plasma polymer layer obtained by a plasma deposition method is interposed as a separation layer, and an adhesive bond between the support layer system and the separation layer is made greater than an adhesive bond between the wafer and the separation layer such that the wafer can be easily released from the separation layer when the wafer is dissociated from the support layer system is also known (see JP2009-528688A).

Furthermore, a technique for performing temporary adhesion using a polyethersulfone and a viscosity imparting agent, and then releasing the temporary adhesion with heating is known (see JP2011-225814A).

Incidentally, a technique for performing temporary adhesion with a mixture formed of carboxylic acids and amines, and then releasing the temporary adhesion with heating is known (see JP2011-052142A).

In addition, a technique is known, in which a device wafer and a support substrate are bonded with pressure to be adhered in a state where an adhesion layer formed of cellulose polymers and the like is heated, and then the device wafer is dissociated from the support substrate by laterally sliding under heating (see JP2010-506406A).

Moreover, an adhesion film formed of syndiotactic 1,2-polybutadiene and a photopolymerization initiator, an adhesive force of which is changed by irradiation with radiation is known (see JP2007-045939A).

Further, a technique is known, in which a support substrate and a semiconductor wafer are temporarily adhered to each other with an adhesive formed of polycarbonates, the semiconductor wafer is treated and then irradiated with radiation and then heating to dissociate the treated semiconductor wafer from the support substrate (see US2011/0318938A).

Furthermore, a technique is known, in which a support substrate and a semiconductor wafer are temporarily bonded in two layers having different softening points, a semiconductor wafer is treated, and then the support substrate is dissociated from the semiconductor wafer by laterally sliding under heating (see US2012/0034437A).

In addition, a temporary adhesive using a polyfunctional methacrylate, in which the glass transition point (Tg) of the cured product is 250° C. or higher is known (see WO2011/049138A).

### SUMMARY OF THE INVENTION

Meanwhile, in the case where a surface of a semiconductor wafer provided with a device (that is, a device surface of a device wafer) is temporarily adhered to a support substrate (that is, a carrier substrate) through a layer formed of the adhesive known in JP2011-119427A or the like, a certain level of adhesive strength is required for the adhesive layer in order to stably support the semiconductor wafer.

Therefore, in the case where the whole device surface of the semiconductor wafer and the support substrate are temporarily adhered to each other through the adhesive layer, when the temporary adhesion between the semiconductor wafer and the support substrate is made sufficient in order to support the semiconductor wafer stably and while not damaging the semiconductor wafer, due to too strong temporary adhesion between the semiconductor wafer and the support substrate, on the other hand, a problem in that the device is damaged or in that the device is dissociated from the semiconductor wafer is likely to occur, when the semiconductor wafer is dissociated from the support substrate.

Furthermore, the method of forming as a separation layer, a plasma polymer layer by a plasma deposition method between the wafer and the support layer system as in JP2009-528688A in order to prevent the adhesion between the wafer and the support layer system becoming too strong has problems (1) in that the equipment cost for performing the plasma deposition method is ordinarily high; (2) in that the layer formation by the plasma deposition method requires time for vacuumization in the plasma apparatus and deposition of monomers; (3) in that even when the separation layer formed of a plasma polymer layer is provided, it is not easy to control the adhesive bond in such a manner that the wafer is easily dissociated from the separation layer in the case of releasing the supporting of the wafer, while, on the other hand, the adhesive bond between the wafer and the separation layer is sufficiently maintained in the ease of supporting the wafer subjected to the processing; and in others.

Moreover, in a method of releasing the temporary adhesion with heating as described in JP2011-225814A, JP2011-052142A, JP2010-506406A, and US2012/0034437A, a problem in that the device may be damaged when the semiconductor wafer is dissociated is likely to occur.

Furthermore, in the method of releasing the temporary adhesion by irradiation with radiation as described in JP2007-045939A and US2011/0318938A, it is necessary to use a support substrate which transmits the radiation.

Moreover, in the case where the softening point of a bonding layer on the side of a semiconductor wafer is higher than the softening point of a bonding layer on the side of a substrate by 20° C. or higher as in US2012/0034437A, the bonding layer on the side of the substrate is transferred to the bonding layer on the side of the thinned semiconductor wafer and thus a problem that the cleaning properties of the semiconductor wafer is reduced occurs.

Furthermore, if a (meth)acrylic resin having a Tg of a cured film of 250° C. or higher is used as a temporary adhesive as in WO2011/049138A, the adhesiveness is excellent in an environment at 250° C., but the peeling properties at room temperature are insufficient and there is a problem in the total thickness variation (TTV) of a device wafer after reducing the thickness.

Under these circumstances, the present invention has been realized, and it is an object of the present invention to provide a laminate, in which when a member to be treated (a semiconductor wafer or the like) is subjected to a mechanical or chemical treatment, the member to be treated can be temporarily supported by strong adhesive force, and further, the temporary support can be easily released (due to excellent releasing properties) without damaging the treated member even after undergoing a process at a high temperature in a vacuum; and a composition for forming a protective layer; a composition for forming an adhesive layer; a kit thereof; and a method for using a laminate.

The present inventors have conducted extensive studies to accomplish the above-described object, and as a result, they have found that it is possible to provide a temporary support for the device wafer and the support and to easily release the temporary support for the device wafer by using a laminate including, on a support (A), an adhesive layer having a softening point of 250° C. or higher (B), a protective layer (C), and a device wafer (D) in this order, in which the adhesive layer (B) is a cured product of an adhesive layer precursor and the adhesive layer precursor includes a polymerizable compound (b-1), thereby completing the present invention.

Although not limited to any theory, in the laminate of the present invention, both of the adhesiveness during formation of a thinner wafer and the peelability after formation of the thinner wafer are satisfied due to an anchor effect suitable at the interface between the protective layer and the adhesive layer. Further, by using an adhesive layer having a softening point of 250° C. or higher, the adhesive force during a high-temperature process and the peelability after the high-temperature process are excellent. Further, by disposing a protective layer between the device wafer and the adhesive layer, a tensile is not applied to a chip or the like on the device wafer, and thus, the breakage of the chip disappeared and the peelability is not dependent on the shape of a chip. In addition, since there are less effects such as volume shrinkage occurring during the curing of the (meth)acrylic resin, there is an advantage that the total thickness variation (TTV) of the device wafer after formation of the thinner wafer is also improved.

Based on this knowledge, it was found that a highly adhesive and easily peelable laminate can be formed, thereby completing the present invention.

Specifically, the above object was accomplished by the following means <1>, and more preferably by <2> to <22>.

<1> A laminate including, on a support (A), an adhesive layer having a softening point of 250° C. or higher (B), a protective layer (C), a device wafer (D) in this order, in which the adhesive layer (B) is a cured product of an adhesive layer precursor and the adhesive layer precursor includes a polymerizable compound (b-1).

<2> The laminate as described in <1>, in which the adhesive layer has a 3-dimensional crosslinked structure.

<3> The laminate as described in <1> or <2>, in which the polymerizable compound (b-1) includes at least one kind of trifunctional or higher functional radically polymerizable compound.

<4> The laminate as described in any one of <1> to <3>, in which the polymerizable compound (b-1) includes at least one kind of radically polymerizable compound containing a fluorine atom.

<5> The laminate as described in any one of <1> to <4>, in which the adhesive layer precursor further includes a photo-radical initiator (b-2).

<6> The laminate as described in any one of <1> to <4>, in which the adhesive layer precursor further includes a thermo-radical initiator (b-3).

<7> The laminate as described in any one of <1> to <6>, in which the adhesive layer precursor further includes a polymer compound (b-4).

<8> The laminate as described in any one of <1> to <7>, in which the softening point of the protective layer (C) is from 170° C. to 250° C.

<9> The laminate as described in any one of <1> to <8>, in which the protective layer (C) is a thermoplastic resin.

<10> The laminate as described in any one of <1> to <9>, in which the protective layer (C) is at least one kind of thermoplastic resin selected from a polyethersulfone resin, a polyimide resin, a polyester resin, a polybenzimidazole resin, a polyester resin, a polyamideimide resin, and a polyetheretherketone resin.

<11> The laminate as described in any one of <1> to <10>, in which the device wafer (D) has a structure having a height of from 1 μm to 150 μm on the surface.

<12> The laminate as described in any one of <1> to <11>, in which the film thickness of the device wafer (D) is 100 μm or less.

<13> The laminate as described in any one of <1> to <12>, in which the temperature difference in the softening point between the adhesive layer and the protective layer is 10° C. to 300° C.

<14> A composition for forming a protective layer, used for producing a protective layer of the laminate as described in any one of <1> to <13>, including a resin and a solvent.

<15> The composition for forming a protective layer as described in <14>, in which the softening point of the resin is from 170° C. to 250° C.

<16> A composition for forming an adhesive layer, used for producing an adhesive layer of the laminate as described in any one of <1> to <13>, including a solvent and a polymerizable compound (b-1).

<17> The composition for forming an adhesive layer as described in <16>, further including a photo-radical initiator (b-2).

<18> The composition for forming an adhesive layer as described in <16>, further including a thermo-radical initiator (b-3).

<19> The composition for forming an adhesive layer as described in any one of <16> to <18>, further including a polymer compound (b-4).

<20> A kit including a composition for forming a protective layer, including a resin and a solvent, and a composition for forming an adhesive layer, including a solvent and a polymerizable compound.

<21> The kit as described in <20>, in which the softening point of the resin included in the composition for forming a protective layer is from 170° C. to 250° C.

<22> The kit as described in <20> or <21>, which is a kit for the production of the laminate as described in any one of <1> to <13>.

According to the present invention, it became possible to provide a laminate which can provide a temporary support for a member to be treated when the member to be treated is subjected to a mechanical or chemical treatment by a high adhesive force and can easily release the temporary support for the member to be treated while not damaging the member to be treated, with the TTV of the treatment member being excellent; a composition for forming a protective layer; a composition for forming an adhesive layer; and a kit.

### BRIEF DESCRIPTION OF THE DRAWINGS

FIGS. 1A, 1B, 1C, 1D, 1E, and 1F in FIG. 1 are a schematic cross-sectional view showing the temporary adhesion between a carrier support and a device wafer, a schematic cross-sectional view showing a state in which the device wafer temporarily adhered to the carrier support becomes thinner, a schematic cross-sectional view showing a state in which the carrier support is peeled from the device wafer, and a schematic cross-sectional view showing a state after cleaning of the surface of the carrier support and the device wafer, respectively.

FIGS. 2A, 2B, 2C, 2D, 2E, and 2F in FIG. 2 are a schematic cross-sectional view showing the temporary adhesion between a carrier support and a device wafer through a photomask in a halftone dot shape, a schematic cross-sectional view showing a state in which the device wafer temporarily adhered on the carrier support becomes thinner via a photomask in the halftone dot shape, a schematic cross-sectional view showing a state in which the carrier support is peeled from the device wafer via photomask in a halftone dot shape, and a schematic cross-sectional view showing a state after cleaning of the surface of the carrier support and the device wafer via a photomask in a halftone dot shape, respectively.

FIG. 3 is a schematic cross-sectional view showing the releasing in the temporary adhesion state between the adhesive support and the device wafer in the prior art.

FIG. 4 is a schematic top view of an adhesive support in an embodiment of the present invention.

FIG. 5 is a schematic top view of an adhesive support in an embodiment of the present invention.

FIG. 6 is a schematic top view of an aspect of an adhesive support in an embodiment of the present invention.

FIG. 7 is a schematic top view of an aspect of an adhesive support in an embodiment of the present invention.

FIG. 8 is a schematic top view of an aspect of an adhesive support in an embodiment of the present invention.

FIG. 9 is a schematic top view of an aspect of an adhesive support in an embodiment of the present invention.

FIG. 10 is a schematic top view of an aspect of an adhesive support in an embodiment of the present invention.

FIG. 11 is a schematic top view of an aspect of an adhesive support in an embodiment of the present invention.

FIG. 12 is a schematic top view of an aspect of an adhesive support in an embodiment of the present invention.

FIG. 13 is a schematic top view of an aspect of an adhesive support in an embodiment of the present invention.

FIG. 14 is a schematic top view of an aspect of n adhesive support in an embodiment of the present invention.

### DESCRIPTION OF THE PREFERRED EMBODIMENTS

Hereinafter, embodiments of the present invention will be described in detail.

In citations for a group (atomic group) in the present specification, when the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

Furthermore, “actinic ray” or “radiation” in the present specification means, for example, visible light, ultraviolet rays, far ultraviolet rays, electron beams, X-rays, or the like. In addition, in the present invention, “light” means actinic rays or radiation.

Incidentally, “exposure” in the present specification includes, unless otherwise specified, not only exposure by a mercury lamp, ultraviolet rays, far ultraviolet rays represented by an excimer laser, X-rays, EUV rays, or the like, but also writing by particle rays such as electron beams and ion beams.

In addition, in the present specification, “(meth)acrylate” represents either or both of acrylate and methacrylate, “(meth)acryl” represents either or both of acryl and methacryl, and “(meth)acryloyl” represents either or both of acryloyl and methacryloyl. Further, in the present specification, a “monomer material” and a “monomer” have the same definition.

The weight average molecular weight in the present invention refers to a weight average molecular weight as determined by a gel permeation chromatography (GPC) method and calculated in terms of polystyrene.

Furthermore, in the embodiments as described below, the member or the like described in the drawing already referred to is indicated by the same or corresponding symbol in the figure and its description is simplified or omitted.

Laminate:

The laminate of the present invention includes, on a support (A), an adhesive layer having a softening point of 250° C. or higher (B), a protective layer (C), and a device wafer (D) in this order, in which the adhesive layer (B) is a cured product of an adhesive layer precursor and the adhesive layer precursor has a polymerizable compound (b-1). The laminate of the present invention can be used in an environment at 250° C. or higher.

By the laminate of the present invention, it is possible to provide a temporary support for a member to be treated when the member to be treated is subjected to a mechanical or chemical treatment by a high adhesive force as well as to release the temporary support for a treated member while not damaging the treated member.

The laminate of the present invention is preferably used for formation of a through-silicon electrode. The formation of a through-silicon electrode will be described in detail later.

Hereinafter, the respective components which may be included in the laminate of the present invention will be described in detail.

<Adhesive Layer (B)>

The laminate of the present invention has an adhesive layer (B) having a softening point of 250° C. or higher.

The adhesive layer is a cured product of an adhesive layer precursor having a polymerizable compound (b-1), and has a softening point of 250° C. or higher. It is preferable that the adhesive layer has a 3-dimensional crosslinked structure, and by using such a configuration, a firm adhesive layer can be formed and the effects of the present invention is effectively exerted. Hereinafter, the components included in the adhesive layer precursor that forms an adhesive layer will be described.

<Adhesive Layer Precursor>

<<Polymerizable Compound (b-1)>>

The adhesive layer precursor has a polymerizable compound (b-1). As the polymerizable compound, any one can be used, and a polymerizable compound can be arbitrarily selected from the radically polymerizable compounds as described below such that the softening point of the cured product becomes 250° C. or higher.

From the viewpoints of adhesiveness and peelability, it is preferable to include at least one kind of bifunctional or higher functional polymerizable compound, it is more preferable to include at least one kind of trifunctional or higher functional polymerizable compound, and it is still more preferable to include at least one kind of pentafunctional or higher functional polymerizable compound.

Furthermore, it is preferable that polymerizable compound contains a fluorine atom and/or a silicon atom, and it is more preferable that polymerizable compound contains at least a fluorine atom. In the present invention, the polymerizable compound in which 5% by mass or more of the polymerizable compound (b-1) contains a fluorine atom is preferable, the polymerizable compound in which 30% by mass or more of the polymerizable compound (b-1) contains a fluorine atom is preferable, and the polymerizable compound in which 45% by mass or more of the polymerizable compound (b-1) contains a fluorine atom is more preferable.

As a preferred embodiment of the polymerizable compound in the present invention, a pentafunctional or higher functional polymerizable compound or a fluorine atom-containing polymerizable compound is preferably contained.

The polymerizable compound means a compound having a polymerizable group, but the polymerizable group is preferably a radically polymerizable group. That is, as the polymerizable compound, a radically polymerizable compound is preferable. The number of functional groups of the radically polymerizable compound in the present invention means the number of radically polymerizable groups in one molecule. The radically polymerizable group is typically a group that can be polymerized by irradiation with actinic rays or radiation, or by the action of radicals.

The polymerizable group is preferably, for example, a functional group which can undergo an addition-polymerization reaction, and examples of the functional group which can undergo the addition-polymerization reaction include an ethylenically unsaturated bonding group. As the ethylenically unsaturated bonding group, a styryl group, a (meth)acryloyl group, and an allyl group are preferable, and the (meth)acryloyl group is more preferable. That is, the radically polymerizable compound used in the present invention is preferably a (meth)acrylate monomer, and more preferably an acrylate monomer.

The polymerizable compound may have any chemical form such as, for example, a monomer, a prepolymer, that is, a dimer, a trimer, and an oligomer, or a mixture and a multimer thereof, with the monomer and/or the oligomer being preferable, and the monomer being more preferable. The monomer is typically a low molecular compound, and is preferably a low molecular compound having a molecular weight of 2,000 or less, more preferably a low molecular compound having a molecular weight of 1,500 or less, and still more preferably a low molecular compound having a molecular weight of 900 or less. Further, the molecular weight is usually 100 or more.

The oligomer is typically a polymer having a relatively low molecular weight, and preferably a polymer to which 10 to 100 monomers are bonded. The weight average molecular weight is preferably 2,000 to 20,000, more preferably 2,000 to 15,000, and most preferably 2,000 to 10,000, as a weight average molecular weight determined by a gel permeation chromatography (GPC) method and calculated in terms of polystyrene.

The weight average molecular weight of polymerizable compound used in the present invention is preferably 20,000 or less.

More specifically, examples of the polymerizable compound include an unsaturated carboxylic acid (for example, acrylic acid, methacrylic acid, itaconic acid, crotonic acid, isocrotonic acid, and maleic acid), its esters and amides, and a multimer thereof. Esters of an unsaturated carboxylic acid and a polyhydric alcohol compound, amides of an unsaturated carboxylic acid, and a polyvalent amine compound, and multimers thereof are preferred. In addition, an addition reaction product of unsaturated carboxylic esters or amides having a nucleophilic substituent such as a hydroxyl group, an amino group, and a mercapto group, with monofunctional or polyfunctional isocyanates or epoxies, and a dehydration condensation reaction product with a monofunctional or polyfunctional carboxylic acid, may be also suitably used. Furthermore, an addition reaction product of unsaturated carboxylic esters or amides having an electrophilic substituent such as an isocyanate group and an epoxy group, with monofunctional or polyfunctional alcohols, amines, or thiols, and a substitution reaction product of unsaturated carboxylic esters or amides having a leaving substituent such as a halogen group and a tosyloxy group, with monofunctional or polyfunctional alcohols, amines, or thiols, are also suitable. In addition, as other examples, compound groups in which the above-described unsaturated carboxylic acid is substituted with an unsaturated phosphonic acid, a vinylbenzene derivative such as styrene, a vinyl ether, an allyl ether, or the like can also be used.

As for specific examples of the ester monomer of a polyhydric alcohol compound with an unsaturated carboxylic acid, examples of the acrylic ester include ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, dipentaerythritol diacrylate, dipentaerythritol hexaacrylate, pentaerythritol tetraacrylate, sorbitol triacrylate, sorbitol tetraacrylate, sorbitol pentaacrylate, sorbitol hexaacrylate, tri(acryloyloxyethyl)isocyanurate, isocyanuric acid ethylene oxide (EO)-modified triacrylate, and a polyester acrylate oligomer.

Examples of the methacrylic ester include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, and bis[p-(methacryloxyethoxy)phenyl]dimethylmethane.

Examples of the itaconic ester include ethylene glycol diitaconate, propylene glycol diitaconate, 1,3-butanediol diitaconate, 1,4-butanediol diitaconate, tetramethylene glycol diitaconate, pentaerythritol diitaconate, and sorbitol tetraitaconate.

Examples of the crotonic ester include ethylene glycol dicrotonate, tetramethylene glycol dicrotonate, pentaerythritol dicrotonate, and sorbitol tetradicrotonate.

Examples of the isocrotonic ester include ethylene glycol diisocrotonate, pentaerythritol diisocrotonate, and sorbitol tetraisocrotonate.

Examples of the maleic ester include ethylene glycol dimaleate, triethylene glycol dimaleate, pentaerythritol dimaleate, and sorbitol tetramaleate.

Other examples of the ester, including aliphatic alcohol-based esters described in JP1971-27926B (JP-S46-27926B), JP1976-47334B (JP-S51-47334B) and JP1982-196231A (JP-S57-196231A), those having an aromatic skeleton described in JP1984-5240A (JP-S59-5240A), JP 1984-5241A (JP-S59-5241A), and JP1990-226149A (JP-H02-226149A), and those containing an amino group described in JP1989-165613A (JP-H01-165613A), are also suitably used.

Furthermore, specific examples of the amide monomer of a polyvalent amine compound with an unsaturated carboxylic acid include methylenebis-acrylamide, methylenebis-methacrylamide, 1,6-hexamethylenebis-acrylamide, 1,6-hexamethylenebis-methacrylamide, diethylenetriamine trisacrylamide, xylylenebisacrylamide, and xylylenebismethacrylamide.

Other preferred examples of the amide-based monomer include those having a cyclohexylene structure described in JP1979-21726B (JP-S54-21726B).

Moreover, a urethane-based addition-polymerizable monomer produced using an addition reaction of isocyanate with a hydroxyl group is also preferred, and specific examples thereof include a vinyl urethane compound having two or more polymerizable vinyl groups per molecule described in JP1973-41708B (JP-S48-41708B), which is obtained by adding a hydroxyl group-containing vinyl monomer represented by the following General Formula (A) to a polyisocyanate compound having two or more isocyanate groups per molecule:

CH₂═C(R⁴)COOCH₂CH(R⁵)OH (A)

(in which R⁴ and R⁵ each represent H or CH₃).

In addition, urethane acrylates described in JP1976-37193A (JP-S51-37193A), JP1990-32293B (JP-H02-32293B), and JP1990-16765B (JP-H02-16765B), and urethane compounds having an ethylene oxide-based skeleton described in JP1983-49860B (JP-S58-49860B), JP1981-17654B (JP-S56-17654B), JP1987-39417B (JP-S62-39417B), and JP1987-39418B (JP-S62-39418B) are also suitable.

Furthermore, as for the radically polymerizable monomer, the compounds described in paragraphs “0095” to “0108” of JP2009-288705A can also be suitably used in the present invention.

Moreover, as the radically polymerizable monomer, an ethylenically unsaturated group-containing compound having at least one addition-polymerizable ethylene group and having a boiling point of 100° C. or higher under normal pressure, is also preferred. Examples thereof include a monofunctional acrylate or methacrylate such as polyethylene glycol mono(meth)acrylate, polypropylene glycol mono(meth)acrylate and phenoxyethyl(meth)acrylate; a polyfunctional acrylate or methacrylate such as polyethylene glycol di(meth)acrylate, trimethylolethane tri(meth)acrylate, neopentyl glycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol(meth)acrylate, trimethylolpropane tri(acryloyloxypropyl)ether, tri(acryloyloxyethyl)isocyanurate, compound obtained by adding ethylene oxide or propylene oxide to a polyfunctional alcohol (for example, glycerin, trimethylolethane) and (meth)acrylating the adduct, urethane(meth)acrylates described in JP1973-41708B (JP-S48-41708B), JP1975-6034B (JP-S50-6034B) and JP1976-37193A (JP-S51-37193A), polyester acrylates described in JP1973-64183A (JP-S48-64183A), JP1974-43191B) (JP-S49-43191B), and JP 1977-30490B (JP-S52-30490B), and epoxy acrylates as a reaction product of epoxy resin and (meth)acrylic acid; and a mixture thereof.

Examples of the compound further include a polyfunctional (meth)acrylate obtained by reacting a polyfunctional carboxylic acid with a compound having a cyclic ether group and an ethylenically unsaturated group, such as glycidyl(meth)acrylate.

As other preferred radically polymerizable monomers, the compounds having a fluorene ring and a bifunctional or higher functional ethylenically polymerizable group, described in JP2010-160418A, JP2010-129825A, and JP4364216B, and a cardo resin can also be used.

Other examples of the radically polymerizable monomers include specific unsaturated compounds described in JP1971-43946B (JP-S46-43946A), JP1989-40337B (JP-H01-40337B), and JP1989-40336B (JP-H01-40336B), and a vinyl phosphonic acid-based compound described in JP1990-25493A (JP-H02-25493A). In some cases, a structure containing a perfluoroalkyl group described in JP1986-22048A (JP-S61-22048A) is suitably used. In addition, those described as a photocurable monomer or oligomer in the Adhesion Society of Japan, Vol. 20, No. 7, pp. 300-308 (1984) can also be used.

As the compound having a boiling point of 100° C. or higher under normal pressure and having at least one addition-polymerizable ethylenically unsaturated group, the compounds described in paragraphs “0254” to “0257” of JP2008-292970A are also preferred.

In addition, radically polymerizable monomers represented by the following General Formulae (MO-1) to (MO-5) can be suitably used. Further, in the formulae, in the case where T is an oxyalkylene group, the terminal on the carbon atom side is bonded to R.

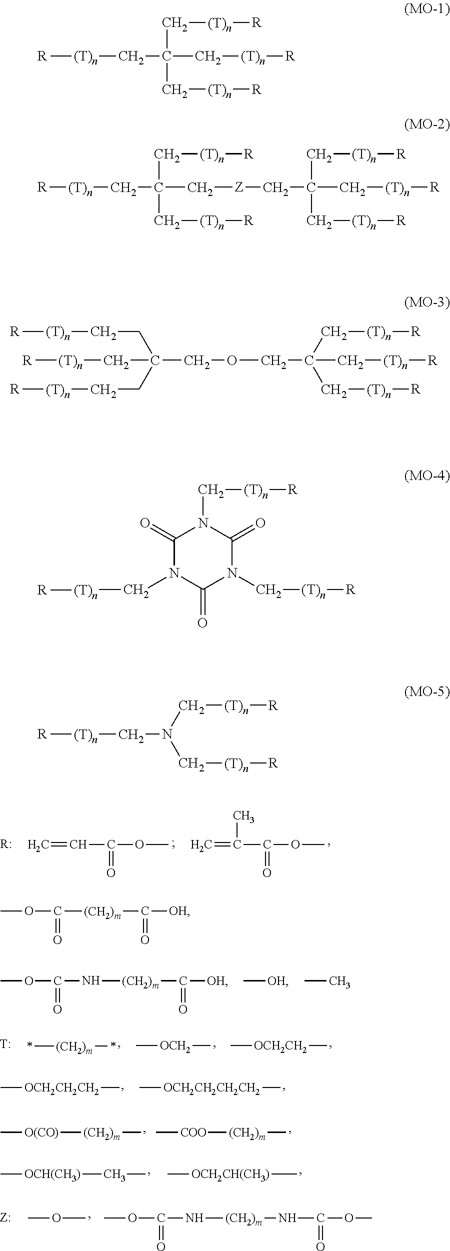

In the general formulae, n is an integer of 0 to 14 and m is an integer of 1 to 8. R's or T's, which are present in plurality in one molecule, may be the same as or different from each other.

In each of the radically polymerizable monomers represented by General Formulae (MO-1) to (MO-5), at least one of the plurality of R's represents a group represented by —OC(═O)CH═CH₂ or —OC(═O)C(CH₃)═CH₂.

As for specific examples of the radically polymerizable monomers represented by General Formulae (MO-1) to (MO-5), the compounds described in paragraphs “0248” to “0251” of JP2007-269779A may also be suitably used in the present invention.

Compounds obtained by adding an ethylene oxide or a propylene oxide to the above-described polyfunctional alcohol and (meth)acrylating the adduct, described as the compounds of General Formulae (1) and (2) together with their specific examples in JP1998-62986A (JP-H10-62986A), can also be used as the radically polymerizable monomer.

Among those, as the radically polymerizable monomer, dipentaerythritol triacrylate (as a commercial product, KAYARAD D-330, manufactured by Nippon Kayaku Co., Ltd.), dipentaerythritol tetraacrylate (as a commercial product, KAYARAD D-320, manufactured by Nippon Kayaku Co., Ltd.), dipentaerythritol penta(meth)acrylate (as a commercial product, KAYARAD D-310, manufactured by Nippon Kayaku Co., Ltd.), dipentaerythritol hexa(meth)acrylate (as a commercial product, KAYARAD DPHA, manufactured by Nippon Kayaku Co., Ltd.), and structures in which the (meth)acryloyl group of these compounds is bonded through an ethylene glycol or propylene glycol residue are preferable. Their oligomer types can also be used.

The radically polymerizable monomer may be a polyfunctional monomer having an acid group such as carboxyl group, sulfonic acid group and phosphoric acid group. Accordingly, an ethylenic compound having an unreacted carboxyl group as in the case of the mixture above may be directly used, but, if desired, a non-aromatic carboxylic anhydride may be reacted with a hydroxyl group of the above-described ethylenic compound to introduce an acid group. In this case, specific examples of the non-aromatic carboxylic anhydride used include tetrahydrophthalic anhydride, alkylated tetrahydrophthalic anhydride, hexahydrophthalic anhydride, alkylated hexahydrophthalic anhydride, succinic anhydride, and maleic anhydride.

The acid group-containing monomer is preferably a polyfunctional monomer which is an ester of an aliphatic polyhydroxy compound and an unsaturated carboxylic acid and is imparted with an acid group by reacting a non-aromatic carboxylic anhydride with an unreacted hydroxyl group of an aliphatic polyhydroxy compound, particularly preferably the ester above where the aliphatic polyhydroxy compound is pentaerythritol and/or dipentaerythritol. Examples of the commercial product thereof include polybasic acid-modified acryl oligomers M-510 and M-520, manufactured by Toagosei Co., Ltd.

In the present invention, as the monomer, an acid group-free polyfunctional monomer and an acid group-containing polyfunctional monomer may be used in combination, if desired.

The acid value of the acid group-containing polyfunctional monomer is preferably 0.1 mg-KOH/g to 40 mg-KOH/g, and particularly preferably 5 mg-KOH/g to 30 mg-KOH/g. If the acid value of the polyfunctional monomer is too low, the developer solubility characteristics are reduced, whereas if it is excessively high, production or handling becomes difficult and the photopolymerization performance is reduced to impair the curability such as surface flatness of pixel. Accordingly, in the case where two or more polyfunctional monomers differing in the acid group are used in combination or where an acid group-free polyfunctional monomer is used in combination, the monomers must be adjusted such that the acid value of the entire polyfunctional monomer falls in the range above.

Furthermore, it is preferable to contain a polyfunctional monomer having a caprolactone structure as the radically polymerizable monomer.

The polyfunctional monomer having a caprolactone structure is not particularly limited as long as it has a caprolactone structure in a molecule thereof, but examples thereof include an ε-caprolactone-modified polyfunctional (meth)acrylate obtained by esterifying a polyhydric alcohol such as trimethylolethane, ditrimethylolethane, trimethylolpropane, ditrimethylolpropane, pentaerythritol, dipentaerythritol, tripentaerythritol, glycerin, diglycerol, and trimethylolmelamine, with a (meth)acrylic acid and s-caprolactone. Among others, a polyfunctional monomer having a caprolactone structure represented by the following General Formula (B) is preferable:

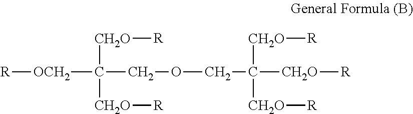

(in which all of 6 R's are a group represented by the following General Formula (C) or 1 to 5 members out of 6 R's are a group represented by the following General Formula (C) and the residual members are a group represented by the following General Formula (D))

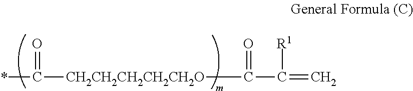

(in which R¹ represents a hydrogen atom or a methyl group, m represents a number of 1 or 2, and “*” indicates a direct bond).

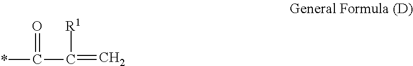

(in which R¹ represents a hydrogen atom or a methyl group, and “*” indicates a direct bond).

The polyfunctional monomer having a caprolactone structure is commercially available as KAYARAD DPCA Series from Nippon Kayaku Co., Ltd., and examples thereof include DPCA-20 (a compound in which in General Formulae (B) to (D), m=1, the number of groups represented by General Formula (C)=2, and all R¹s are a hydrogen atom), DPCA-30 (a compound in which in the same formulae, m=1, the number of groups represented by General Formula (C)=3, and all R¹'s are a hydrogen atom), DPCA-60 (a compound in which in the same formulae, m=1, the number of groups represented by General Formula (C)=6, and all R¹'s are a hydrogen atom), and DPCA-120 (a compound in which in the same formulae, m=2, the number of groups represented by General Formula (C)=6, and all R¹'s are a hydrogen atom).

In the present invention, the polyfunctional monomer having a caprolactone structure can be used singly or as a mixture of two or more kinds thereof.

Moreover, the polyfunctional monomer is preferably at least one kind selected from a group of compounds represented by the following General Formula (i) or (ii).

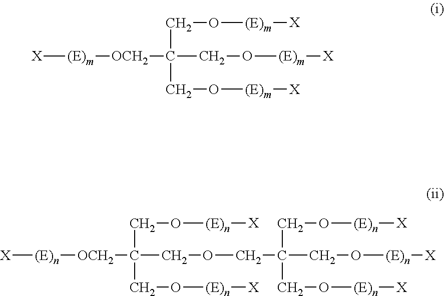

In General Formula (i) and (ii), E's each independently represent —((CH₂)yCH₂O)— or —((CH₂)yCH(CH₃)O)—, y's each independently represent an integer of 0 to 10, and X's each independently represent a (meth)acryloyl group, a hydrogen atom, or a carboxyl group.

In General Formula (i), the sum of the (meth)acryloyl groups is 3 or 4, m's each independently represent an integer of 0 to 10, and the sum of the respective m's is an integer of 0 to 40. Here, in the case where the sum of the respective m's is 0, any one of X's is a carboxyl group.

In General Formula (ii), the sum of the (meth)acryloyl group is 5 or 6, n's each independently represent an integer of 0 to 10, and the sum of the respective n's is an integer of 0 to 60. Here, in the case where the sum of the respective n's is 0, any one of X's is a carboxyl group.

In General Formula (i), m is preferably an integer of 0 to 6, and more preferably an integer of 0 to 4.

Further, the sum of the respective m's is preferably an integer of 2 to 40, more preferably an integer of 2 to 16, and particularly preferably an integer of 4 to 8.

In General Formula (ii), n is preferably an integer of 0 to 6, and more preferably an integer of 0 to 4.

Furthermore, the sum of the respective n's is preferably an integer of 3 to 60, more preferably an integer of 3 to 24, and particularly preferably an integer of 6 to 12.

In addition, —((CH₂)_{y}CH₂O)— or —((CH₂)_{y}CH(CH₃)O)— in General Formula (i) or (ii) is preferably in the form in which the terminal at an oxygen atom side is bonded to X.

In particular, a form in which in General Formula (ii), all of 6 X's are acryloyl groups is preferable.

The compound represented by General Formula (i) or (ii) can be synthesized by steps known in the related art, which includes a step of binding ethylene oxide or propylene oxide to pentaerythritol or dipentaerythritol by a ring-opening addition reaction to form a ring-opening skeleton, and a step of reacting, for example, (meth)acryloyl chloride to a terminal hydroxyl group of the ring-opening skeleton to introduce a (meth)acryloyl group. Since the respective steps are well-known, a person skilled in the art can easily synthesize the compound represented by General Formula (i) or (ii).

Among the compounds represented by General Formula (i) or (ii), a pentaerythritol derivative and/or a dipentaerythritol derivative is/are more preferable.

Specific examples of the compounds include compounds represented by the following Formulae (a) to (f) (hereinafter also referred to as “exemplary compounds (a) to (f)”). Among these, the exemplary compounds (a), (b), (e), and (f) are preferable.

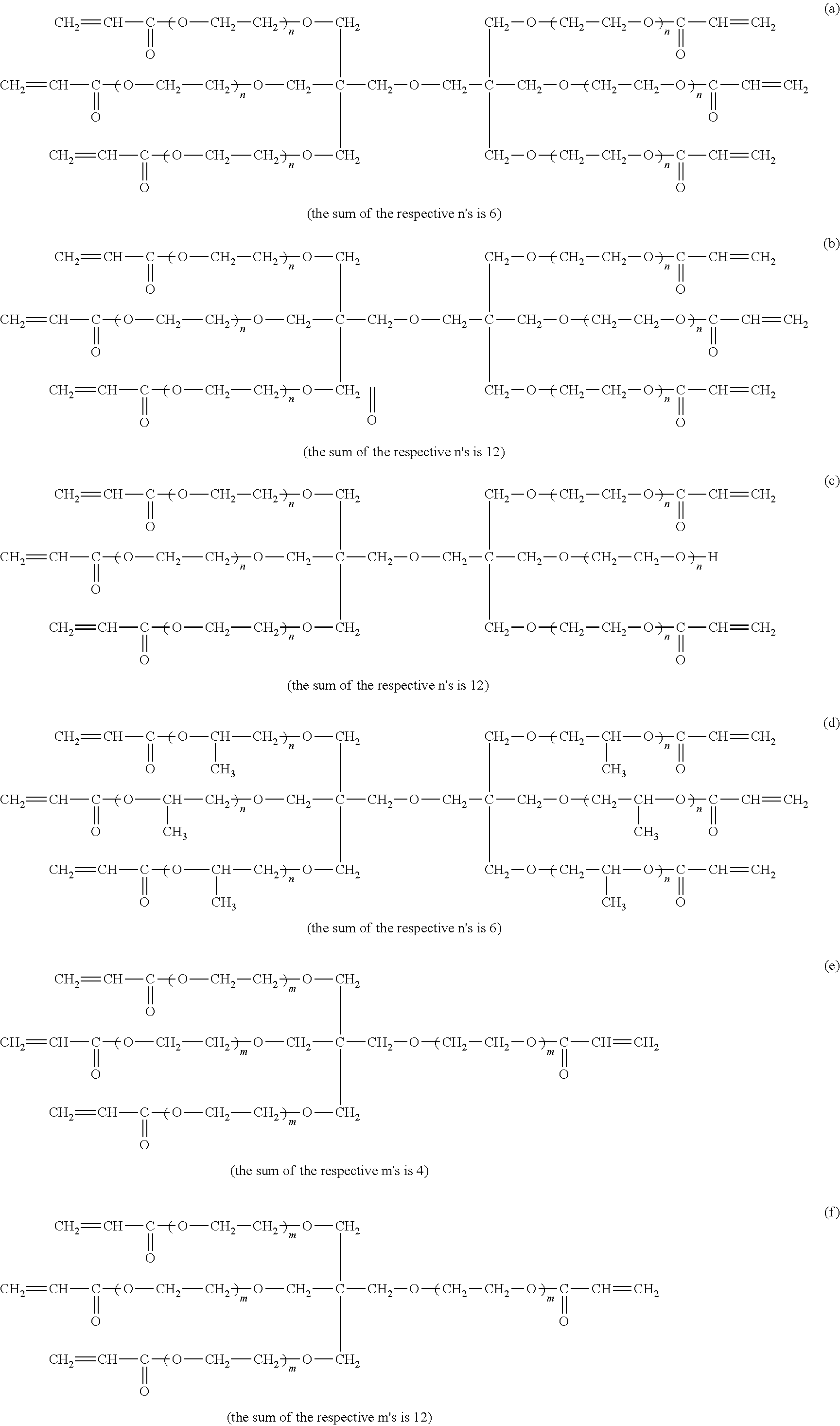

Examples of commercially available products of the radically polymerizable monomers represented by General Formulae (i) and (ii) include SR-494 which is a tetrafunctional acrylate having four ethyleneoxy chains, manufactured by Sartomer, and DPCA-60 which is a hexafunctional acrylate having 6 pentyleneoxy chains and TPA-330 which is a trifunctional acrylate having three isobutyleneoxy chains, manufactured by Nippon Kayaku Co., Ltd.

Moreover, as the radically polymerizable monomer, the urethane acrylates described in JP1973-41708B (JP-S48-41708B), JP1976-37193A (JP-S51-37193A), JP1990-32293B (JP-H02-32293B), and JP1990-16765B (JP-H02-16765B) or urethane compounds having an ethylene oxide-based skeleton described in JP1983-49860B (JP-S58-49860B), JP1981-17654B (JP-S56-17654B), JP1987-39417B (JP-S62-39417B), and JP1987-39418B (JP-S62-39418B) are also suitable. Furthermore, addition-polymerizable monomers having an amino structure or a sulfide structure in a molecule, which are described in JP1988-277653A (JP-S63-277653A), JP1988-260909A (JP-S63-260909A), and JP1989-105238A (JP-H01-105238A), can also be used as the polymerizable monomers.

Examples of commercially available products of the radically polymerizable monomers include urethane oligomers UAS-10 and UAB-140 (manufactured by Sanyo-Kokusaku Pulp, Co., Ltd.), UA-7200, A-TMMT, A-9300, AD-TMP, A-DPH, and A-TMM-3 (manufactured by SHIN-NAKAMURA CHEMICAL CO., LTD.), DPHA-40H (manufactured by Nippon Kayaku Co., Ltd.), and UA-306H, UA-306T, UA-3061, AH-600, T-600, AI-600, and Light Acrylate TMP-A (manufactured by KYOEISHA CHEMICAL CO., LTD.).

The polymerizable monomers in the present invention may be used singly, or is preferably used in combination with two or more kinds thereof, with respect to the bifunctional or lower radically polymerizable monomer and the trifunctional or higher functional radically polymerizable monomer, and from the viewpoint of having a 3-dimensional crosslinked structure, it is preferable that at least one kind of trifunctional or higher functional radically polymerizable monomer is included.

As the radically polymerizable monomer, it is preferable to include at least one of 1,3-adamantyl dimethanol di(meth)acrylate, trimethylolpropane tri(meth)acrylate, isocyanuric acid ethylene oxide-modified di(meth)acrylate, isocyanuric acid ethylene oxide-modified tri(meth)acrylate, pentaerythritol tri(meth)acrylate, pentaerythritol tetra(meth)acrylate, dimethylol propane tetra(meth)acrylate, dipentaerythritol penta(meth)acrylate, dipentaerythritol hexa(meth)acrylate, and tetramethylolmethane tetra(meth)acrylate, in order to set the softening point of the cured film to 250° C. or higher. Thus, the release peelability at a room temperature after a high-temperature process is improved.

The content of the polymerizable compound is preferably 50% by mass to 100% by mass, more preferably 90% by mass to 100% by mass, and still more preferably 95% by mass to 100% by mass, with respect to the total solid contents of the adhesive precursor, from the viewpoints of good adhesive strength and peelability. One kind or two or more kinds of the polymerizable compounds may be used. In the case where two or more kinds of the polymerizable compound is used, the total sum thereof is preferably within the above range.

[Polymerizable Compound Containing Fluorine Atom and/or Silicon Atom]

The polymerizable compound in the present invention is particularly preferably one having a polymerizable compound containing a fluorine atom and/or a silicon atom in the addition amount such that the softening point of the adhesive layer is not lower than 250° C. The polymerizable compound containing a fluorine atom and/or a silicon atom is preferably a radically polymerizable monomer in which one or more fluorine atom(s) or silicon atom(s) are contained in one molecule, and particularly preferably a polymerizable compound having a group, generally referred to as a perfluoro group, in which two or more fluorine atoms or silicon atoms are contained in one molecule.

The radically polymerizable compound containing a fluorine atom and/or a silicon atom contains a radically polymerizable functional group, and the radically polymerizable functional group is not particularly limited, but is preferably an unsaturated group (an ethylenically unsaturated bonding group or the like).

The radically polymerizable compound containing a fluorine atom and/or a silicon atom is preferably one having two or more radically polymerizable functional groups, whereby the laminate can have further improvement in the releasablity of the temporary support for the treated member after undergoing the process at a high temperature.

[[Polymerizable Compound Containing Fluorine Atom]]

The polymerizable compound containing a fluorine atom can be selected from known compounds, and is preferably a crosslinking agent having a polymerizable group as a crosslinkable group. Examples of the crosslinkable group include a silyl group having a hydroxyl group or a hydrolyzable group (for example, an alkoxysilyl group and an acyloxysilyl group), a group having a reactive unsaturated double bond (a (meth)acryloyl group, an allyl group, a vinyloxy group, or the like), a ring-opening polymerization reactive group (an epoxy group, an oxetanyl group, an oxazolyl group, or the like), a group having an active hydrogen atom (a hydroxyl group, a carboxyl group, an amino group, a carbamoyl group, a mercapto group, a β-ketoester group, a hydrosilyl group, a silanol group, or the like), an acid anhydride, a group which can be substituted with a nucleophilic agent (an active halogen atom, a sulfonic acid ester, or the like), or the like.

The radically polymerizable compound containing a fluorine atom is preferably a compound represented by the following General Formula (1).

Rf{-L-Y}n General Formula (1)

(in which Rf represents a chained or cyclic n-valent group which may contained any one of an oxygen atom and a hydrogen atom, including at least a carbon atom and a fluorine atom, n represents an integer of 2 or more, L represents a single bond or a divalent linking group, and Y represents a polymerizable group)

In General Formula (1), Y is preferably a polymerizable group, and examples thereof include a silyl group having a hydroxyl group or a hydrolyzable group (for example, an alkoxysilyl group and an acyloxysilyl group), a group having a reactive unsaturated double bond (a (meth)acryloyl group, an allyl group, a vinyloxy group, or the like), a ring-opening polymerization reactive group (an epoxy group, an oxetanyl group, an oxazolyl group, or the like), a group having an active hydrogen atom (for example, a hydroxyl group, a carboxyl group, an amino group, a carbamoyl group, a mercapto group, a β-ketoester group, a hydrosilyl group, a silanol group, or the like), an acid anhydride, a group which can be substituted with a nucleophilic agent (an active halogen atom, a sulfonic acid ester, or the like), or the like.

Y is more preferably a radically polymerizable group, and still more preferably a group having a reactive unsaturated double bond. Specifically, T preferably represents a radically polymerizable functional group represented by the following General Formula (9).

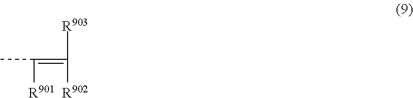

(in General Formula (9), R⁹⁰¹ to R⁹⁰³ each independently represent a hydrogen atom, an alkyl group, or an aryl group. The dotted line represents a bond to a group linking to L)

As an example of the alkyl group, it is preferably an alkyl group having 1 to 8 carbon atoms, and examples thereof include a methyl group, an ethyl group, a propyl group, an octyl group, an isopropyl group, a tert-butyl group, an isopentyl group, a 2-ethylhexyl group, a 2-methylhexyl group, and a cyclopentyl group. As an example of the aryl group, an aryl group having 6 to 12 carbon atoms is preferable, and examples thereof include a phenyl group, a 1-naphthyl group, and a 2-naphthyl group. Among them, as R⁹⁰¹ to R⁹⁰³, a hydrogen atom or a methyl group is preferable.

L represents a single bond or a divalent linking group. The divalent linking group represents a divalent aliphatic group, a divalent aromatic group, —O—, —S—, —CO—, —N(R)—, and a divalent linking group obtained by combination of two or more kinds of these groups. Here, R represents a hydrogen atom or an alkyl group having 1 to 5 carbon atoms.

In the case where L has an alkylene group or an arylene group, the alkylene group and the arylene group is preferably substituted with a halogen atom, and more preferably substituted with a fluorine atom.

Rf represents a chained or cyclic n-valent group which contains at least a carbon atom and a fluorine atom, and may contain any one of an oxygen atom and a hydrogen atom. Rf may be a linear or branched polymer structure having a repeating unit containing a fluorine atom.

As the polymerizable compound containing a fluorine atom, the compounds described in paragraphs “0019” to “0033” of JP2011-48358A can also be preferably used, the contents of which are incorporated herein.

Further, the radically polymerizable compound containing a fluorine atom is preferably at least one selected from the compounds represented by the following Structural Formulae (1), (2), (3), (4), and (5).

CH₂═CR¹COOR²R^{f} Structural Formula (1)

(in Structural Formula (1), R¹ represents a hydrogen atom or a methyl group, R² represents —CₚH₂ₚ—, —C(CₚH₂ₚ₊₁)H—, —CH₂C(CₚH₂ₚ₊₁)H—, or —CH₂CH₂O—, and R^{f} represents —CₙF₂ₙ₊₁, —(CF₂)ₙH, —CₙF₂ₙ₊₁—CF₃, —(CF₂)ₚOCₙH₂ₙCᵢF₂ᵢ₊₁, —(CF₂)ₚOCₘH₂ₘCᵢF₂ᵢH, —N(CₚH₂ₚ₊₁)COCₙF₂ₙ₊₁, or —N(CₚH₂ₚ₊₁)SO₂CₙF₂ₙ₊₁, in which p is an integer of 1 to 10, n is an integer of 1 to 16, m is an integer of 0 to 10, and i is an integer of 0 to 16).

CF₂═CFOR^{g} Structural Formula (2)

(in Structural Formula (2), R^{g} represents a fluoroalkyl group having 1 to 20 carbon atoms).

CH₂═CHR_{g} Structural Formula (3)

(in Structural Formula (3), R^{g} represents a fluoroalkyl group having 1 to 20 carbon atoms).

CH₂═CR³COOR⁵R^{j}R⁶OCOCR⁴═CH₂ Structural Formula (4)

(in Structural Formula (4), R³ and R⁴ each independently represent a hydrogen atom or a methyl group, R⁵ and R⁶ each independently represent —C_{q}H_{2q}—, —C(C_{q}H_{2q+1})H—, —CH₂C(C_{q}H_{2q+1})H— or —CH₂CH₂O—, and Rⱼ represents —CₜF₂ₜ, in which q is an integer of 1 to 10 and t is an integer of 1 to 16).

CH₂═CHR⁷COOCH₂(CH₂R^{k})CHOCOCR⁸═CH₂ Structural Formula (5)

(in Structural Formula (5), R⁷ and R⁸ each independently represent a hydrogen atom or a methyl group, and R^{k} is —CyF_{2y+1}, in which y is an integer of 1 to 16).

Examples of the monomer represented by Structural Formula (1) include CF₃(CF₂)₅CH₂CH₂OCOCH═CH₂, CF₃CH₂OCOCH═CH₂, CF₃(CF₂)₄CH₂CH₂OCOC(CH₃)═CH₂, C₇F₁₅CON(C₂H₅)CH₂OCOC(CH₃)═CH₂, CF₃(CF₂)₇SO₂N(CH₂)CH₂CH₂OCOCH═CH₂, CF₂(CF₂)₇SO₂N(C₃H₇)CH₂CH₂OCOCH═CH₂, C₂F₅SO₂N(C₃H₇)CH₂CH₂OCO(CH₃)═CH₂, (CF₃)₂CF(CF₂)₆(CH₂)₃OCOCH═CH₂, (CF₃)₂CF(CF₂)₁₀(CH₂)₃OCOC(CH₃)═CH₂, CF₃(CF₂)₄CH(CH₃)OCOC(CH₃)═CH₂, CF₃CH₂OCH₂CH₂OCOCH═CH₂, C₂F₅(CH₂CH₂O)₂CH₂OCOCH═CH₂, (CF₃)₂CFO(CH₂)₅OCOCH═CH₂, CF₃(CF₂)₄OCH₂CH₂OCOC(CH₃)═CH₂, C₂F₅CON(C₂H₅)CH₂OCOCH═CH₂, CF₃(CF₂)₂CON(CH₃)CH(CH₃)CH₂OCOCH═CH₂, H(CF₂)₆C(C₂H₅)OCOC(CH₃)═CH₂, H(CF₂)₈CH₂OCOCH═CH₂, H(CF₂)₄CH₂OCOCH═CH₂, H(CF₂)CH₂OCOC(CH₃)═CH₂, CF₃(CF₂)₇SO₂N(CH₃)CH₂CH₂OCOC(CH₃)═CH₂, CF₃(CF₂)₇SO₂N(CH₃)(CH₂)₁₀OCOCH═CH₂, C₂F₅SO₂N(C₂H₅)CH₂CH₂OCOC(CH₃)═CH₂, and CF₃(CF₂)₇SO₂N(CH₃)(CH₂)₄OCOCH═CH₂, C₂F₅SO₂N(C₂H₅)C(C₂H₅)HCH₂OCOCH═CH₂. These may be used singly or in combination of two or more kinds thereof.

Examples of the fluoroalkylated olefin represented by Structural Formula (2) or (3) include C₃F₇CH═CH₂, C₄F₉CH═CH₂, C₁₀F₂₁CH═CH₂, C₃F₇OCF═CF₂, C₇F₁₅OCF═CF₂, and C₈F₁₇OCF═CF₂.

Examples of the monomer represented by Structural Formula (4) or (5) include CH₂═CHCOOCH₂(CF₂)₃CH₂OCOCH═CH₂ and CH₂═CHCOOCH₂CH(CH₂C₈F₁₇)OCOCH═CH₂.

Furthermore, as the radically polymerizable compound containing a fluorine atom, an oligomer having a repeating unit containing a fluorine atom and a repeating unit having a radically polymerizable functional group can be preferably used.

As the repeating unit containing a fluorine atom, one selected from at least one of the repeating units represented by the following Formulae (6), (7), and (10) is preferable.

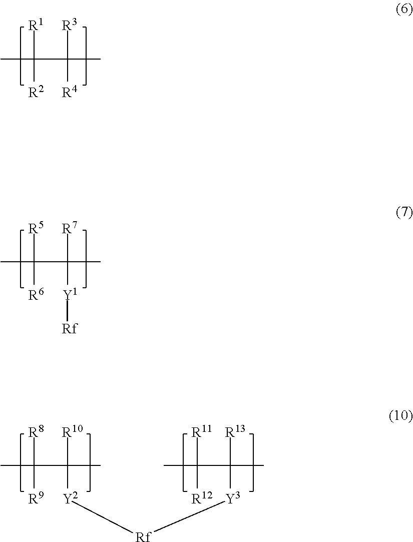

In Formula (6), R¹, R², R³, and R⁴ each independently represent a hydrogen atom, a halogen atom, a hydroxyl group, or a monovalent organic group, and at least one of R¹, R², R³, and R⁴ is a fluorine atom, or a monovalent organic group containing a fluorine atom.

In Formula (7), R⁵, R⁶, and R⁷ each independently represent a hydrogen atom, a halogen atom, a hydroxyl group, or a monovalent organic group, Y1 represents a single bond, or a divalent linking group selected from the group consisting of —CO—, —O—, —NH—, a divalent aliphatic group, a divalent aromatic group, and a combination thereof. Rf represents a fluorine atom, or a monovalent organic group containing a fluorine atom.

In Formula (10), R⁸, R⁹, R¹⁰, R¹¹, R¹², and R¹³ each independently represent a hydrogen atom, a halogen atom, a hydroxyl group, or a monovalent organic group, Y² and Y³ represents a single bond, or a divalent linking group selected from the group consisting of —CO—, —O—, —NH—, a divalent aliphatic group, a divalent aromatic group, and a combination thereof, and Rf represents a divalent organic group containing a fluorine atom.

The monovalent organic group containing a fluorine atom in Formulae (6) and (7) is not particularly limited, and a fluorine-containing alkyl group having 1 to 30 carbon atoms is preferable, a fluorine-containing alkyl group having 1 to 20 carbon atoms is more preferable, and a fluorine-containing alkyl group having 1 to 15 carbon atoms is particularly preferable. This fluorine-containing alkyl group may be linear (for example, —CF₂CF₃, —CH₂(CF₂)₄H, —CH₂(CF₂)₈CF₃, and —CH₂CH₂(CF₂)₄H), may have a branched structure (for example, —CH(CF₃)₂, —CH₂CF(CF₃)₂, —CH(CH₃)CF₂CF₃, and —CH(CH₃)(CF₂)₅CF₂H), may have an alicyclic structure (preferably a 5- or 6-membered ring, for example, a perfluorocyclohexyl group, a perfluorocyclopentyl group, and an alkyl group substituted therewith), and may have an ether bond (for example, —CH₂OCH₂CF₂CF₃, —CH₂CH₂OCH₂C₄F₈H, —CH₂CH₂OCH₂CH₂C₈F₁₇, and —CH₂CF₂OCF₂CF₂OCF₂CF₂H). Further, it may be a perfluoroalkyl group.

The divalent organic group containing a fluorine atom in Formula (10) is not particularly limited, and is preferably a fluorine-containing alkylene group having 1 to 30 carbon atoms, more preferably a fluorine-containing alkylene group having 1 to 20 carbon atoms, and particularly preferably a fluorine-containing alkylene group having 1 to 15 carbon atoms. The fluorine-containing alkylene group may have a linear structure (for example, —CF₂CF₂—, —CH₂(CF₂)₄—, —CH₂(CF₂)₈CF₂—, and —CH₂CH₂(CF₂)₄—) or a branched structure (for example, —CH(CF₃)CF₂—, —CH₂CF(CF₃)CF₂—, —CH(CH₃)CF₂CF₂—, and —CH(CH₃)(CF₂)5CF₂—), and may also be a linking group having an alicyclic structure (preferably a 5- or 6-membered ring, for example, a perfluorocyclohexyl group, a perfluorocyclopentyl group, or an alkyl group substituted therewith) and may have an ether bond (for example, —CH₂OCH₂CF₂CF₂—, —CH₂CH₂OCH₂C₄F₈—, —CH₂CH₂OCH₂CH₂C₈F₁₆—, —CH₂CF₂OCF₂CF₂OCF₂CF₂—, —CH₂CF₂OCF₂CF₂OCF₂CF₂—, and a polyperfluoroalkylene ether chain). Further, the fluorine-containing alkylene group may be a perfluoroalkylene group.

The monovalent organic group in Formulae (6), (7), and (10) is preferably an organic group constituting from 3- to 10-valent nonmetallic atoms, and examples thereof include an organic group constituted with at least one element selected from 1 to 60 carbon atoms, 0 to 10 nitrogen atoms, 0 to 50 oxygen atoms, 1 to 100 hydrogen atoms and 0 to 20 sulfur atoms.

More specific examples of the monovalent organic group include organic groups having the structures shown below and organic groups constituted with one or a combination of two or more of the following structures.

The monovalent organic group may further have a substituent, and examples of the substituent which may be introduced include a halogen atom, a hydroxy group, a carboxy group, a sulfonate group, a nitro group, a cyano group, an amido group, an amino group, an alkyl group, an alkenyl group, an alkynyl group, an aryl group, a substituted oxy group, a substituted sulfonyl group, a substituted carbonyl group, a substituted sulfinyl group, a sulfo group, a phosphono group, a phosphonate group, a silyl group, and a heterocyclic group. Further, the organic group may also contain an ether bond, an ester bond, or a ureido bond.

The monovalent organic group is preferably an alkyl group, an alkenyl group, an alkynyl group or an aryl group. The alkyl group is preferably an alkyl group having 1 to 8 carbon atoms, and examples thereof include a methyl group, an ethyl group, a propyl group, an octyl group, an isopropyl group, a t-butyl group, an isopentyl group, a 2-ethylhexyl group, a 2-methylhexyl group, and a cyclopentyl group. The alkenyl group is preferably an alkenyl group having 2 to 20 carbon atoms, and examples thereof include a vinyl group, an allyl group, a prenyl group, a geranyl group, and an oleyl group. The alkynyl group is preferably an alkynyl group having 3 to 10 carbon atoms, and examples thereof include an ethynyl group, a propargyl group, and a trimethylsilylethynyl group. The aryl group is preferably an aryl group having 6 to 12 carbon atoms, and examples thereof include a phenyl group, a 1-naphthyl group, and a 2-naphthyl group. The heterocyclic group is preferably a heterocyclic group having 2 to 10 carbon atoms, and examples thereof include a furanyl group, a thiophenyl group, and a pyridinyl group.

The monovalent organic groups represented by R¹, R², R³, and R⁴ in Formula (6), R⁵, R⁶, and R⁷ in Formula (7), and R⁸, R⁹, R¹⁰, R¹¹, R¹², and R13 in Formula (10) are preferably an alkyl group or an aryl group.

The alkyl group is preferably an alkyl group having 1 to 8 carbon atoms, and examples thereof include a methyl group, an ethyl group, a propyl group, an octyl group, an isopropyl group, a tert-butyl group, an isopentyl group, a 2-ethylhexyl group, a 2-methylhexyl group, and a cyclopentyl group. As the aryl group, an aryl group having 6 to 12 carbon atoms is preferable, and examples thereof include a phenyl group, a 1-naphthyl group, and a 2-naphthyl group. R⁹⁰¹ to R⁹⁰³ are preferably a hydrogen atom or a methyl group.

Specific examples of the divalent linking group selected from the group consisting of —CO—, —O—, —NH—, the divalent aliphatic group, the divalent aromatic group, and a combination thereof represented by Y¹ in Formula (7) and Y² and Y³ in Formula (10) include the following groups. Further, in the following examples, the left side connects to the main chain and the right side connects to Rf.

L1: —CO—NH-divalent aliphatic group-O—CO—NH-divalent aliphatic group-O—CO—

L2: —CO—NH-divalent aliphatic group-O—CO—

L3: —CO-divalent aliphatic group-O—CO—

L4: —CO—O-divalent aliphatic group-O—CO—

L5: -divalent aliphatic group-O—CO—

L6: —CO—NH-divalent aromatic group-O—CO—

L7: —CO-divalent aromatic group-O—CO—

L8: -divalent aromatic group-O—CO—

L9: —CO—O-divalent aliphatic group-CO—O-divalent aliphatic group-O—CO—

L10: —CO—O-divalent aliphatic group-O—CO-divalent aliphatic group-O—CO—

L11: —CO—O-divalent aromatic group-CO—O-divalent aliphatic group-O—CO—

L12: —CO—O-divalent aromatic group-O—CO-divalent aliphatic group-O—CO—

L13: —CO—O-divalent aliphatic group-CO—O-divalent aromatic group-O—CO—

L14: —CO—O-divalent aliphatic group-O—CO-divalent aromatic group-O—CO—

L15: —CO—O-divalent aromatic group-CO—O-divalent aromatic group-O—CO—

L16: —CO—O-divalent aromatic group-O—CO-divalent aromatic group-O—CO—

L17: —CO—O-divalent aromatic group-O—CO—NH-divalent aliphatic group-O—CO—

L18: —CO—O-divalent aliphatic group-O—CO—NH-divalent aliphatic group-O—CO—

L19: -divalent aromatic group-divalent aliphatic group

L20: -divalent aromatic group-divalent aliphatic group-O-divalent aliphatic group-

L21: -divalent aromatic group-divalent aliphatic group-O-divalent aliphatic group-O—

L22: —CO—O-divalent aliphatic group-

L23: —CO—O-divalent aliphatic group-O—

Here, the divalent aliphatic group means an alkylene group, a substituted alkylene group, an alkenylene group, a substituted alkenylene group, an alkynylene group, a substituted alkynylene group, or a polyalkyleneoxy group. Among these, an alkylene group, a substituted alkylene group, an alkenylene group, and a substituted alkenylene group are preferable, and an alkylene group and a substituted alkylene group are more preferable.

As the divalent aliphatic groups, a chained structure is preferred to a cyclic structure, and a linear structure is preferred to a chained structure having a branch. The number of carbon atoms contained in the divalent aliphatic group is preferably 1 to 20, more preferably 1 to 15, still more preferably 1 to 12, even still more preferably 1 to 10, even still more preferably 1 to 8, and particularly preferably 1 to 4.

Examples of the substituent for the divalent aliphatic group include a halogen atom (F, Cl, Br, or I), a hydroxy group, a carboxy group, an amino group, a cyano group, an aryl group, an alkoxy group, an aryloxy group, an acyl group, an alkoxycarbonyl group, an aryloxycarbonyl group, an acyloxy group, a monoalkylamino group, a dialkylamino group, an arylamino group, and a diarylamino group.

Examples of the divalent aromatic group include a phenylene group, a substituted phenylene group, a naphthylene group and a substituted naphthylene group, with the phenylene group being preferable. Examples of the substituent for the divalent aromatic group include an alkyl group in addition to the substituents described for the divalent aliphatic group above.

The content of the repeating unit containing a fluorine atom is preferably 2% by mole to 98% by mole, and more preferably 10% by mole to 90% by mole, with respect to the total repeating units of the radically polymerizable oligomer containing a fluorine atom.

The repeating unit containing a radically polymerizable functional group is preferably a repeating unit represented by the following Formula (8).

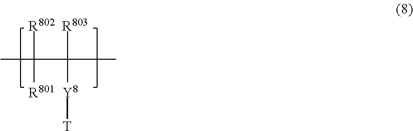

(in General Formula (8), R⁸⁰¹ to R⁸⁰³ each independently represent a hydrogen atom, an alkyl group, or a halogen atom, Y⁸ represents a single bond, or a divalent linking group selected from the group consisting of —CO—, —O—, —NH—, a divalent aliphatic group, a divalent aromatic group, and a combination thereof, and T represents a structure having a radically polymerizable functional group)

The alkyl group represented by R⁸⁰¹ to R⁸⁰³ is preferably an alkyl group having 1 to 6 carbon atoms.

T preferably represents a radically polymerizable functional group represented by General Formula (9).

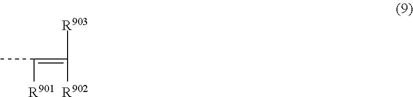

(in General Formula (9), R⁹⁰¹ to R⁹⁰³ each independently represent a hydrogen atom, an alkyl group, or an aryl group. The dotted line represents a bond to a group linking to Y⁸)

The alkyl group is preferably an alkyl group having 1 to 8 carbon atoms, and examples thereof include a methyl group, an ethyl group, a propyl group, an octyl group, an isopropyl group, a tert-butyl group, an isopentyl group, a 2-ethylhexyl group, a 2-methylhexyl group and a cyclopentyl group. The aryl group is preferably an aryl group having 6 to 12 carbon atoms, and examples thereof include a phenyl group, a 1-naphthyl group, and a 2-naphthyl group. Among these, R⁹⁰¹ to R⁹⁰³ are preferably a hydrogen atom or a methyl group.

Y⁸ represents a single bond or a divalent linking group selected from the group consisting of —CO—, —O—, —NH—, a divalent aliphatic group, a divalent aromatic group, and a combination thereof. Specific examples of the combination of groups represented by Y⁸ are set forth below. Further, in the following examples, the left side is bonded to the main chain and the right side is bonded to Formula (9).

L1: —CO—NH-divalent aliphatic group-O—CO—NH-divalent aliphatic group-O—CO—

L2: —CO—NH-divalent aliphatic group-O—CO—

L3: —CO-divalent aliphatic group-O—CO—

L4: —CO—O-divalent aliphatic group-O—CO—

L5: -divalent aliphatic group-O—CO—

L6: —CO—NH-divalent aromatic group-O—CO—

L7: —CO-divalent aromatic group-O—CO—

L8: -divalent aromatic group-O—CO—

L9: —CO—O-divalent aliphatic group-CO—O-divalent aliphatic group-O—CO—

L10: —CO—O-divalent aliphatic group-O—CO-divalent aliphatic group-O—CO—

L11: —CO—O-divalent aromatic group-CO—O-divalent aliphatic group-O—CO—

L12: —CO—O-divalent aromatic group-O—CO-divalent aliphatic group-O—CO—

L13: —CO—O-divalent aliphatic group-CO—O-divalent aromatic group-O—CO—

L14: —CO—O-divalent aliphatic group-O—CO-divalent aromatic group-O—CO—

L15: —CO—O-divalent aromatic group-CO—O-divalent aromatic group-O—CO—

L16: —CO—O-divalent aromatic group-O—CO-divalent aromatic group-O—CO—

L17: —CO—O-divalent aromatic group-O—CO—NH-divalent aliphatic group-O—CO—

L18: —CO—O-divalent aliphatic group-O—CO—NH-divalent aliphatic group-O—CO—

Here, the divalent aliphatic group means an alkylene group, a substituted alkylene group, an alkenylene group, a substituted alkenylene group, an alkynylene group, a substituted alkynylene group, or a polyalkyleneoxy group. Among these, an alkylene group, a substituted alkylene group, an alkenylene group and a substituted alkenylene group are preferred, and an alkylene group and a substituted alkylene group are more preferable.

As the divalent aliphatic group, a chained structure is preferred to a cyclic structure, and a linear structure is preferred to a chained structure having a branch. The number of carbon atoms contained in the divalent aliphatic group is preferably 1 to 20, more preferably 1 to 15, still more preferably 1 to 12, even still more preferably 1 to 10, even still more preferably 1 to 8, and particularly preferably 1 to 4.

Examples of the substituent for the divalent aliphatic group include a halogen atom (F, Cl, Br, or I), a hydroxy group, a carboxy group, an amino group, a cyano group, an aryl group, an alkoxy group, an aryloxy group, an acyl group, an alkoxycarbonyl group, an aryloxycarbonyl group, an acyloxy group, a monoalkylamino group, a dialkylamino group, an arylamino group, and a diarylamino group.

Examples of the divalent aromatic group include a phenylene group, a substituted phenylene group, a naphthylene group and a substituted naphthylene group, with a phenylene group being preferable. Examples of the substituent for the divalent aromatic group include an alkyl group, in addition to the substituents described for the divalent aliphatic group above.

The content of the repeating unit containing a radically polymerizable functional group is preferably 2% by mole to 98% by mole, and more preferably 10% by mole to 90% by mole, with respect to the total repeating units of the radically polymerizable oligomer containing a fluorine atom.

The weight average molecular weight of the radically polymerizable oligomer containing a fluorine atom, as determined by a gel permeation chromatography (GPC) method and calculated in terms of polystyrene, is preferably 2,000 to 20,000, more preferably 2,000 to 15,000, and most preferably 2,000 to 10,000.

The content of the radically polymerizable compound containing a fluorine atom is not particularly limited as long as the softening point of the cured film is set to 250° C. or higher, and is preferably 0.1% by mass to 100% by mass, more preferably 10% by mass to 100% by mass, and most preferably 50% by mass to less than 100% by mass, with respect to the total solid content of the temporary adhesive for producing a semiconductor device. When it is less than 0.1% by mass, the peelability tends to be insufficient.

One kind or two or more kinds of the radically polymerizable compound containing a fluorine atom may be used. In the case where two or more kinds of the radically polymerizable compound containing a fluorine atom are used, the total amount is preferably within the above range.

[Polymerizable Compound Containing Silicon Atom]

The radically polymerizable compound containing a silicon atom in the present invention is preferably a silicone monomer or a silicone oligomer, and examples thereof include a compound in which at least one terminal of polydimethylsiloxane bond is an ethylenically unsaturated group such as a (meth)acryloyl group and a styryl group, with a compound containing a (meth)acryloyl group being preferable.

The number average molecular weight of the radically polymerizable oligomer containing a silicon atom, as determined by a gel permeation chromatography method and calculated in terms of polystyrene, is preferably 1,000 to 10,000. When the number average molecular weight of the radically polymerizable oligomer containing a silicon atom, as determined by a gel permeation chromatography method and calculated in terms of polystyrene, is less than 1,000 or 10,000 or more, it becomes difficult the properties such as the peelability due to the silicon atom are developed.

As the radically polymerizable compound containing a silicon atom in the present invention, a compound represented by General Formula (11) or (12) is preferably used.

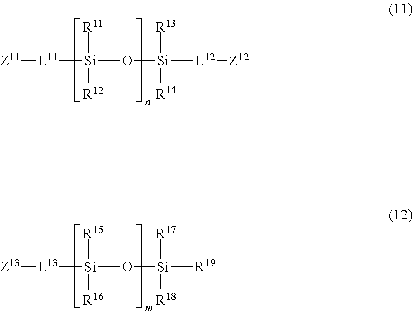

(in General Formulae (11) and (12), R¹¹ to R¹⁹ each independently represent a hydrogen atom, an alkyl group, alkoxy group, an alkoxycarbonyl group, or an aryl group, Z¹¹, Z¹², and Z¹³ each independently represent a radically polymerizable group, L¹¹, L¹², and L¹³ each independently represent a single bond or a divalent linking group, and n and m each independently represent an integer of 0 or more)

The alkyl group represented by R¹¹ to R¹⁹ may be linear or branched and is preferably an alkyl group having 1 to 5 carbon atoms, and specific examples thereof include a methyl group, an ethyl group, an n-propyl group, and an isopropyl group. The alkoxy group is represented by —OR²⁰, in which R²⁰ represents an alkyl group (preferably an alkyl group having 1 to 5 carbon atoms), and specific examples thereof include a methoxy group, an ethoxy group, a propoxy group, an isopropoxy group, and a butoxy group. The alkoxycarbonxyl group is represented by —C(═O)R²¹, in which R²¹ represents an alkoxy group (preferably an alkoxy group having 1 to 5 carbon atoms), and specific examples thereof include a methoxycarbonyl group, an ethoxycarbonyl group, and a propoxycarbonyl group. Examples of the aryl group include a phenyl group, a tolyl group, and a naphthyl group, each of which may have a substituent, and examples thereof include a phenylmethyl(benzyl) group, a phenylethyl group, a phenylpropyl group, a phenylbutyl group, and a naphthylmethyl group.

L¹¹, L¹², and L¹³ each independently represent a single bond or a divalent linking group. The divalent linking group represents a divalent linking group selected from the group consisting of —CO—, —O—, —NH—, a divalent aliphatic group, a divalent aromatic group, and a combination thereof.

n and m each independently represent an integer of 0 or more, and is preferably an integer of 0 to 100, and more preferably an integer of 0 to 50.

Z¹¹, Z¹², and Z¹³ each independently represent a radically polymerizable group, and is particularly preferably a functional group represented by any one of the following General Formulae (i) to (iii).

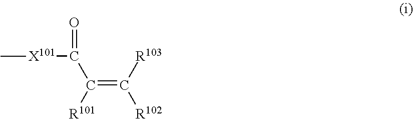

(in General Formula (i), R¹⁰¹ to R¹⁰³ each independently represent a hydrogen atom or a monovalent organic group, X¹⁰¹ represents an oxygen atom, a sulfur atom, or —N(R¹⁰⁴)—, and R¹⁰⁴ represents a hydrogen atom or a monovalent organic group)

In General Formula (i), R¹⁰¹ to R¹⁰³ each independently represent a hydrogen atom or a monovalent organic group. Preferred examples of R¹⁰¹ include a hydrogen atom and an alkyl group which may have a substituent, and among these, a hydrogen atom or a methyl group is preferable due to high radical reactivity. Further, R¹⁰² and R¹⁰³ each independently preferably represent a hydrogen atom, a halogen atom, an amino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent or an arylsulfonyl group which may have a substituent, and among these, a hydrogen atom, a carboxyl group, an alkoxycarbonyl group, an alkyl group which may have a substituent, or an aryl group which may have a substituent is preferable due to high radical reactivity.

X¹⁰¹ represents an oxygen atom, a sulfur atom, or and —N(R¹⁰⁴)—, and R¹⁰⁴ represents a hydrogen atom or a monovalent organic group. Examples of the monovalent organic group include an alkyl group which may have a substituent. R¹⁰⁴ is preferably a hydrogen atom, a methyl group, an ethyl group, or an isopropyl group due to high radical reactivity.

Examples of the substituent which may be introduced include an alkyl group, an alkenyl group, an alkynyl group, an aryl group, an alkoxy group, an aryloxy group, a halogen atom, an amino group, an alkylamino group, an arylamino group, a carboxyl group, an alkoxycarbonyl group, a sulfo group, a nitro group, a cyano group, an amido group, an alkylsulfonyl group, and an arylsulfonyl group.

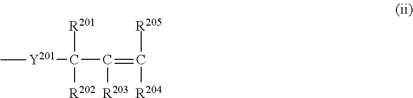

(in General Formula (ii), R²⁰¹ to R²⁰⁵ each independently represent a hydrogen atom or a monovalent organic group, Y²⁰¹ represents an oxygen atom, a sulfur atom, or —N(R²⁰⁶)—, and R²⁰⁶ has the same definition as R¹⁰⁴ in General Formula (i))

In General Formula (ii), R²⁰¹ to R²⁰⁵ each independently represent a hydrogen atom or a monovalent organic group. R²⁰¹ to R²⁰⁵ are each independently preferably a hydrogen atom, a halogen atom, an amino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent and an arylsulfonyl group which may have a substituent, and more preferably a hydrogen atom, a carboxyl group, an alkoxycarbonyl group, an alkyl group which may have a substituent, or an aryl group which may have a substituent.

Examples of the substituent which may be introduced include the same ones as the substituents described in General Formula (i).

Y²⁰¹ represents an oxygen atom, a sulfur atom, or —N(R²⁰⁶)—. R²⁰⁶ has the same definition as R¹⁰⁴ in General Formula (i) and preferred examples thereof are also the same.

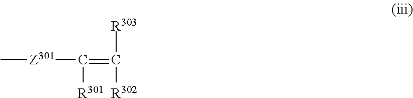

(in General Formula (iii), R³⁰¹ to R³⁰³ each independently represent a hydrogen atom or a monovalent organic group, Z³⁰¹ represents an oxygen atom, a sulfur atom, —N(R³⁰⁴)—, or a phenylene group which may have a substituent, and R³⁰⁴ has the same definition as R¹⁰⁴ in General Formula (i))

In General Formula (iii), R³⁰¹ to R³⁰³ each independently represent a hydrogen atom or a monovalent organic group. R³⁰¹ is preferably a hydrogen atom, an alkyl group which may have a substituent or the like, and among these, a hydrogen atom or a methyl group is more preferable due to high radical reactivity. R³⁰² and R³⁰³ are each preferably a hydrogen atom, a halogen atom, an amino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent, or an arylsulfonyl group which may have a substituent, and a hydrogen atom, a carboxyl group, an alkoxycarbonyl group, an alkyl group which may have a substituent, or an aryl group which may have a substituent is more preferable due to high radical reactivity.

Examples of the substituent which can be introduced include the substituents described in General Formula (i). Z³⁰¹ represents an oxygen atom, a sulfur atom, —N(R³⁰⁴)—, or a phenylene group which may have a substituent. R³⁰⁴ has the same definition as R¹⁰⁴ in General Formula (i), and examples of the monovalent organic group include an alkyl group which may have a substituent, and among these, a methyl group, an ethyl group, or an isopropyl group is preferable due to high radical reactivity.

The content of the radically polymerizable monomer or oligomer containing a silicon atom is preferably 0.1% by mass to 100% by mass, more preferably 10% by mass to 100% by mass, and most 50% by mass or more and less than 100% by mass, with respect to the total solid content of the temporary adhesive for producing a semiconductor device. When it is less than 0.1% by mass, the peelability tends to decrease.

One kind or two or more kinds of the radically polymerizable compound containing a silicon atom may be used. In the case where two or more kinds of the radically polymerizable compound containing a silicon atom are used, the total amount thereof is preferably within the above range.

Examples of the radically polymerizable monomer or oligomer containing a fluorine atom or a silicon atom include RS-75, RS-72-K, RS-76-E, and RS-72-K, manufactured by DIC Corporation, OPTOOL DAC-HP manufactured by Daikin Industries, Ltd., X-22-164, X-22-164AS, X-22-164A, X-22-164B, X-22-164C, and X-22-164E, manufactured by Shin-Etsu Chemical Co., Ltd., EBECRYL 350 and EBECRYL 1360, manufactured by Daicel-Cytec Co., Ltd., and TEGO Rad 2700 manufactured by Degussa Co.

<<Photo-Radical Initiator (b-2) and Thermo-Radical Initiator (b-3)>>

The adhesive layer precursor of the present invention preferably contains a radical polymerization initiator, that is, a compound capable of generating a radical by irradiation with actinic rays or radiation (light irradiation) (b-2) (photo-radical initiator (also referred to as a photo-radical polymerization initiator)), or a compound capable of generating a radical by heat (b-3) (thermo-radical initiator (also referred to as a thermo-radical polymerization initiator)).

When the temporary adhesive for producing a semiconductor device of the present invention has a radical polymerization initiator, a curing reaction occurs with radicals by irradiating an adhesive layer with light or heating the adhesive layer, and thus, the adhesiveness of the adhesive layer can be adjusted.

[Photo-Radical Initiator]

As the photo-radical initiator, for example, ones known as a polymerization initiator which will be described later can be used.

The photo-radical initiator is not particularly limited as long as it has an ability to initiate a polymerization reaction (crosslinking reaction) of a reactive compound having a polymerizable group as the polymerizable monomer, and can be appropriately selected from known polymerization initiators. For example, a polymerization initiator having photosensitivity to light from an ultraviolet ray region to a visible region is preferable. Further, the photo-radical initiator may be an activator which causes any action with a photo-excited sensitizer to produce an active radical.

Furthermore, it is preferable that the polymerization initiator contains at least one compound having a molecular absorption coefficient of at least about 50 within the range of about 300 nm to 800 nm (preferably 330 nm to 500 nm).

As the photo-radical initiator, known compounds can be used without limitation, but examples thereof include a halogenated hydrocarbon derivative (for example, a compound having a triazine skeleton, a compound having an oxadiazole skeleton, and a compound having a trihalomethyl group), an acylphosphine compound such as acylphosphine oxide, hexaarylbiimidazole, an oxime compound such as oxime derivative, an organic peroxide, a thio compound, a ketone compound, an aromatic onium salt, a ketoxime ether, an aminoacetophenone compound, hydroxyacetophenone, an azo-based compound, an azide compound, a metallocene compound, an organoboron compound, and an iron-arene complex.

Examples of the halogenated hydrocarbon compound having a triazine skeleton include the compounds described in Wakabayashi, et al., Bull. Chem. Soc. Japan, 42, 2924 (1969), the compounds described in UK1388492B, the compounds described in JP1978-133428A (JP-S53-133428A), the compounds described in GE3337024B, the compound described in F. C. Schaefer, et al., J. Org. Chem.; 29, 1527 (1964), the compounds described in JP1987-58241A (JP-S62-58241A), the compounds described in JP1993-281728A (JP-H05-281728A), the compounds described in JP1993-34920A (JP-H05-34920A), and the compounds described in U.S. Pat. No. 4,212,976A.

Examples of the compounds described in U.S. Pat. No. 4,212,976A include a compound having an oxadiazole skeleton (for example, 2-trichloromethyl-5-phenyl-1,3,4-oxadiazole, 2-trichloromethyl-5-(4-chlorophenyl)-1,3,4-oxadiazole, 2-trichloromethyl-5-(1-naphthyl)-1,3,4-oxadiazole, 2-trichloromethyl-5-(2-naphthyl)-1,3,4-oxadiazole, 2-tribromomethyl-5-phenyl-1,3,4-oxadiazole, 2-tribromomethyl-5-(2-naphthyl)-1,3,4-oxadiazole, 2-trichloromethyl-5-styryl-1,3,4-oxadiazole, 2-trichloromethyl-5-(4-chlorostyryl)-1,3,4-oxadiazole, 2-trichloromethyl-5-(4-methoxystyryl)-1,3,4-oxadiazole, 2-trichloromethyl-5-(1-naphthyl)-1,3,4-oxadiazole, 2-trichloromethyl-5-(4-n-butoxystyryl)-1,3,4-oxadiazole, and 2-tribromomethyl-5-styryl-1,3,4-oxadiazole).

Furthermore, examples of photo-radical initiators other than those above include acridine derivatives (for example, 9-phenylacridine and 1,7-bis(9,9′-acridinyl)heptane), N-phenylglycine, polyhalogen compounds (for example, carbon tetrabromide, phenyl tribromomethyl sulfone, and phenyl trichloromethyl ketone), coumarins (for example, 3-(2-benzofuranoyl)-7-diethylaminocoumarin, 3-(2-benzofuroyl)-7-(1-pyrrolidinyl)coumarin, 3-benzoyl-7-diethylaminocoumarin, 3-(2-methoxybenzoyl)-7-diethylaminocoumarin, 3-(4-dimethylaminobenzoyl)-7-diethylaminocoumarin, 3,3′-carbonyl bis(5,7-di-n-propoxycoumarin), 3,3′-carbonyl bis(7-diethylaminocoumarin), 3-benzoyl-7-methoxycoumarin, 3-(2-furoyl)-7-diethylaminocoumarin, 3-(4-diethylaminocinnamoyl)-7-diethylamino coumarin, 7-methoxy-3-(3-pyridylcarbonyl)coumarin, 3-benzoyl-5,7-dipropoxycoumarin, 7-benzotriazol-2-ylcoumarin, and coumarin compounds described in JP1993-19475A (JP-H05-19475A), JP1995-271028A (JP-H07-271028A), JP2002-363206A, JP2002-363207A, JP2002-363208A, JP2002-363209A, and the like), acyl phosphine oxides (for example, bis(2,4,6-trimethylbenzoyl)-phenyl phosphine oxide, bis(2,6-dimethoxybenzoyl)-2,4,4-trimethyl-pentylphenyl phosphine oxide, and Lucirin TPO), metallocenes (for example, bis(η5-2,4-cyclopentadien-1-yl)-bis(2,6-difluoro-3-(1H-pyrrol-1-yl)-phenyl)titanium, and η5-cyclopentadienyl-η6-cumenyl-iron(1+)-hexafluorophosphate(1−)), the compounds described in JP1978-133428A (JP-S53-133428A), JP1982-1819B (JP-S57-1819B), JP1982-6096B (JP-S57-6296B), and U.S. Pat. No. 3,615,455A, and the like.

Examples of the ketone compounds include benzophenone, 2-methylbenzophenone, 3-methylbenzophenone, 4-methylbenzophenone, 4-methoxybenzophenone, 2-chlorobenzophenone, 4-chlorobenzophenone, 4-bromobenzophenone, 2-carboxybenzophenone, 2-ethoxycarbonylbenzophenone, benzophenone tetracarboxylic acid or a tetramethyl ester thereof, 4,4′-bis(dialkylamino)benzophenones (for example, 4,4′-bis(dimethylamino)benzophenone, 4,4′-bisdicyclohexylamino)benzophenone, 4,4′-bis(diethylamino)benzophenone, 4,4′-bis(dihydroxyethylamino)benzophenone, 4-methoxy-4′-dimethylaminobenzophenone, 4,4′-dimethoxybenzophenone, 4-dimethylaminobenzophenone, 4-dimethylaminoacetophenone, benzyl, anthraquinone, 2-t-butylanthraquinone, 2-methylanthraquinone, phenanthraquinone, xanthone, thioxanthone, 2-chloro-thioxanthone, 2,4-diethylthioxanthone, fluorenone, 2-benzyl-dimethylamino-1-(4-morpholinophenyl)-1-butanone, 2-methyl-1-[4-(methylthio)phenyl]-2-morpholino-1-propanone, a 2-hydroxy-2-methyl-[4-(1-methylvinyl)phenyl]propanol oligomer, benzoin, benzoin ethers (for example, benzoin methyl ether, benzoin ethyl ether, benzoin propyl ether, benzoin isopropyl ether, benzoin phenyl ether, and benzyl dimethyl ketal), acridone, chloroacridone, N-methylacridone, N-butylacridone, and N-butyl-chloroacridone.

As a commercially available product, KAYACURE-DETX (manufactured by Nippon Kayaku Co., Ltd.) can also be suitably used.

As the photo-radical initiator, a hydroxyacetophenone compound, an aminoacetophenone compound, and an acyl phosphine compound can also be suitably used. More specifically, for example, the aminoacetophenone-based initiator described in JP1998-291969A (JP-H10-291969A), and the acyl phosphine oxide-based initiator described in JP4225898B can also be used.

As the hydroxyacetophenone-based initiator, IRGACURE-184, DAROCUR-1173, IRGACURE-500, IRGACURE-2959, and IRGACURE-127 (product names, all manufactured by BASF Corporation) can be used. As the aminoacetophenone-based initiator, IRGACURE-907, IRGACURE-369, IRGACURE-379, and IRGACURE-OXE379 (product names, all manufactured by BASF Corporation) which are commercially available products can be used. In addition, as the aminoacetophenone-based initiator, the compound described in JP2009-191179A, of which an absorption wavelength matches with a light source of a long wavelength of 365 nm, 405 nm, or the like can be used. Moreover, as the acyl phosphine-based initiator, IRGACURE-819 or DAROCUR-TPO (product name, both manufactured by BASF Corporation) which are commercially available products can be used.

More preferred examples of the photo-radical initiator include an oxime compound. As specific examples of the oxime-based initiator, the compound described in JP2001-233842A, the compound described in JP2000-80068A, or the compound described in JP2006-342166A can be used.

Examples of the oxime compound such as an oxime derivative, which is suitably used as the photo-radical initiator in the present invention, include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

Examples of the oxime compound include the compounds described in J. C. S. Perkin II (1979), pp. 1653-1660), J. C. S. Perkin II (1979), pp. 156-162, Journal of Photopolymer Science and Technology (1995), pp. 202-232, and JP2000-66385A; and the compounds described respectively in JP2000-80068A, JP2004-534797A, and JP2006-342166A.

Furthermore, as oxime compounds other than the above, the compound described in JP2009-519904A in which oxime is linked to an N-position of carbazole, the compound described in U.S. Pat. No. 7,626,957B in which a hetero-substituent is introduced into a benzophenone site, the compounds described in JP2010-15025A and US2009/292039A in which a nitro group is introduced into a dye site, the ketoxime compound described in WO2009/131189A, the compound described in U.S. Pat. No. 7,556,910B which contains a triazine skeleton and an oxime skeleton in the same molecule, the compound described in JP2009-221114A, which has maximum absorption at 405 nm and has excellent sensitivity to a light source of a g-ray, and the like may be used.

Preferably, the cyclic oxime compounds described in JP2007-231000A and JP2007-322744A can also be suitably used. Among the cyclic oxime compounds, the cyclic oxime compounds ring-fused to a carbazole dye, which are described in JP2010-32985A and JP2010-185072A, are preferable from the viewpoint of high sensitivity since these compounds have high light absorptivity.

Furthermore, the compound described in JP2009-242469A, which is an oxime compound having an unsaturated bond in a specific moiety, can also be suitably used since this compound makes it possible to improve sensitivity by reproducing active radicals from polymerization-inactive radicals.

The most preferred examples of the oxime compounds include the oxime compound having a specific substituent described in JP2007-269779A and the oxime compound having a thioaryl group described in JP2009-191061A.

The molar absorption coefficient of the compound can be measured using a known method, but specifically, it is preferable to measure the molar absorption coefficient by means of, for example, an ultraviolet-visible spectrophotometer (Carry-5 spectrophotometer manufactured by Varian) by using an ethyl acetate solvent at a concentration of 0.01 g/L.

From the viewpoint of exposure sensitivity, the photo-radical polymerization initiator is preferably a compound selected from a group consisting of a trihalomethyl triazine compound, a benzyl dimethyl ketal compound, an α-hydroxyketone compound, an α-aminoketone compound, an acyl phosphine compound, a phosphine oxide compound, a metallocene compound, an oxime compound, a triallylimidazole dimer, an onium compound, a benzothiazole compound, a benzophenone compound, an acetophenone compound and a derivative thereof, a cyclopentadiene-benzene-iron complex and a salt thereof, a halomethyl oxadiazole compound, and a 3-aryl-substituted coumarin compound.

The compound is more preferably a trihalomethyl triazine compound, an α-aminoketone compound, an acyl phosphine compound, a phosphine oxide compound, an oxime compound, a triallylimidazole dimer, an onium compound, a benzophenone compound, or an acetophenone compound, and most preferably at least one kind of compound selected from a group consisting of a trihalomethyl triazine compound, an α-aminoketone compound, an oxime compound, a triallylimidazole dimer, and a benzophenone compound, and further, the an oxime compound is most preferably used.

As a commercially available product thereof, IRGACURE-OXE01 (manufactured by BASF Corporation), IRGACURE-OXE02 (manufactured by BASF Corporation), or N-1919 (manufactured by AEKA) is suitably used.

In the case where the adhesive layer precursor has a photo-radical initiator, the content of the photo-radical initiator is preferably 0.1% by mass to 50% by mass, more preferably 0.1% by mass to 30% by mass, and still more preferably 0.1% by mass to 20% by mass, with respect to the total solid content of the adhesive layer precursor.

One kind or two or more kinds of the photo-radical initiator may be used. In the case where two or more kinds of the photo-radical initiator are used, the total sum thereof is preferably within the above range.

[Thermo-Radical Initiator]

As the thermo-radical initiator, a known thermo-radical generator can be used.

The thermo-radical polymerization initiator is a compound capable of generating a radical with heat energy to initiate or accelerate the polymerization reaction of the polymerizable compound.

By the addition of the thermo-radical generator, in the case where the adhesive layer precursor on a support is irradiated with heat and then the temporary adhesion of the member to be treated and the adhesive support is carried out, a crosslinking reaction in the reactive compound having a crosslinkable group proceeds by the heat so that the adhesiveness (that is, an adherence property and a tacking property) of the adhesive layer can be previously reduced as described in detail below.

On the other hand, in the case where heat is irradiated after performing the temporary adhesion of the protective layer and the adhesive layer, the crosslinking reaction in the reactive compound having a crosslinkable group proceeds by the heat so that the adhesive layer becomes more tough to prevent cohesion failure of the adhesive layer, which may likely occur when the member to be treated is subjected to a mechanical or chemical treatment. That is, the adhesiveness of the adhesive layer can be improved.

Preferred examples of the thermo-radical polymerization initiator include the compound capable of generating a radical by irradiation with actinic rays or radiation as described above, and a compound having a heat decomposition point in the range of 130° C. to 250° C., and preferably 150° C. to 220° C. can be preferably used.

Examples of the thermo-radical polymerization initiator include an aromatic ketone, an onium salt compound, an organic peroxide, a thio compound, a hexaarylbiimidazole compound, a ketoxime ester compound, a borate compound, an azinium compound, a metallocene compound, an active ester compound, a compound having a carbon-halogen bond, and an azo compound. Among these, an organic peroxide and an azo compound are more preferable, and an organic peroxide is particularly preferable.

Specific examples of the thermo-radical polymerization initiator include the compounds described in Paragraph Nos. “0074” to “0118” of JP2008-63554A.

As a commercially available product thereof, Perbutyl Z (manufactured by Nippon Yushi Co., Ltd.) can be suitably used.

In the case where the adhesive layer precursor in the present invention contains a thermo-radical polymerization initiator (b-3) (more preferably contains a photo-radical polymerization initiator (b-2) and a thermo-radical polymerization initiator (b-3)) as the radical polymerization initiator, in particular, the adhesiveness at a high temperature (for example, 100° C.) can further be increased.

the adhesive layer precursor in the present invention preferably contains the photo-radical polymerization initiator (b-2).

Further, the adhesive layer precursor in the present invention may contain one kind or two or more kinds of the radical polymerization initiators.

In the case where the adhesive layer precursor has a thermo-radical initiator, the content of the thermo-radical initiator (the total content in the case where two or more kinds of the thermo-radical initiator are used) is preferably 0.1% by mass to 50% by mass, more preferably 0.1% by mass to 30% by mass, and still more preferably 0.1% by mass to 20% by mass, with respect to the total solid content of the adhesive layer precursor.

One kind or two or more kinds of the thermo-radical initiator may be used. In the case where two or more kinds of the thermo-radical initiator are used, the total sum thereof is preferably within the above range.

<<Polymer Compound (b-4)>>

The adhesive layer precursor of the present invention may have a polymer compound in order to control the coating property. The coating property as used herein means the uniformity of layer thickness after coating and the film-forming property after coating.

In the present invention, an arbitrary polymer compound can be used. The polymer compound in the present invention is a compound having a weight average molecular weight of 2,000 or more, and usually a compound containing no polymerizable group. The weight average molecular weight of the polymer compound is preferably 10,000 or more, and more preferably 20,000 or more.

Examples thereof include synthetic resins such as a hydrocarbon resin, a polystyrene resin (including, for example, an acrylnitrile/butadiene/styrene copolymer (ABS resin), an acrylnitrile/styrene copolymer (AS resin), and a methyl methacrylate/styrene copolymer (MS resin)), a novolac resin, a phenol resin, an epoxy resin, a melamine resin, a urea resin, an unsaturated polyester resin, an alkyd resin, a polyurethane resin, a polyimide resin, a polyethylene resin, a polypropylene resin, a polyvinyl chloride resin, a polyvinyl acetate resin, Teflon (registered trademark), a (meth)acrylic resin, a polyamide resin, a polyacetal resin, a polycarbonate resin, a polyphenylene ether resin, a polybutylen terephthalate resin, a polyethylene terephthalate resin, a polyphenylene sulfide resin, a polysulfone resin, a polyethersulfone resin, a polyacrylate resin, a polyetherether ketone resin, and a polyamideimide resin; and natural resins such as a natural rubber. Among these, a hydrocarbon resin, an ABS resin, an AS resin, an MS resin, a polyurethane resin, a novolac resin, and a polyimide are preferable, and a hydrocarbon resin, an MS resin, and methyl polymethacrylate are more preferable, and an acrylic resin, an ABS resin, an AS resin, and an MS resin are still more preferable.

In the present invention, if desired, two or more kinds of binder may be used.

As a commercially available product thereof, ESTYRENE MS600 (manufactured by Nippon Steel & Sumikin Chemical Co., Ltd.) or the like can be suitably used.

In the present invention, an arbitrary one can be used as a hydrocarbon resin.

The hydrocarbon resin in the present invention basically means a resin formed of only carbon atoms and hydrogen atoms, but it may contain other atoms in its side chain as long as the basic skeleton is a hydrocarbon resin. Specifically, a case wherein a functional group other than a hydrocarbon group is directly connected to the main chain, for example, an acrylic resin, a polyvinyl alcohol resin, a polyvinyl acetal resin or a polyvinyl pyrrolidone resin is also included in the hydrocarbon resin in the present invention. In this case, the content of a repeating unit in which a hydrocarbon group is directly connected to the main chain is preferably 30% by mole or more with respect to the total repeating units of the resin.

Examples of the hydrocarbon resin which fulfills the condition described above include a polystyrene resin, a terpene resin, a terpene phenol resin, a modified terpene resin, a hydrogenated terpene resin, a hydrogenated terpene phenol resin, a rosin, a rosin ester, a hydrogenated rosin, a hydrogenated rosin ester, a polymerized rosin, a polymerized rosin ester, a modified rosin, a rosin-modified phenol resin, an alkylphenol resin, an aliphatic petroleum resin, an aromatic petroleum resin, a hydrogenated petroleum resin, a modified petroleum resin, an alicyclic petroleum resin, a coumarone petroleum resin, an indene petroleum resin, a styrene-olefin copolymer, an olefin polymer (for example, a methylpentene copolymer), and a cycloolefin polymer (for example, a norbornene copolymer, a dicyclopentadiene copolymer and a tetracyclododecene copolymer).

The hydrocarbon resin is preferably a polystyrene resin, a terpene resin, rosin, a petroleum resin, a hydrogenated rosin, a polymerized rosin, an olefin polymer or a cycloolefin polymer, more preferably a polystyrene resin, a terpene resin, rosin, an olefin polymer, or a cycloolefin polymer, still more preferably a polystyrene resin, a terpene resin, rosin, an olefin polymer, a polystyrene resin, or a cycloolefin polymer, even still more preferably a polystyrene resin, a terpene resin, rosin, a cycloolefin polymer, and an olefin polymer, and particularly preferably a polystyrene resin or a cycloolefin monomer polymer.

Specific examples of the polystyrene resin include polystyrene, a styrene/acrylonitrile resin, an acrylonitrile/butadiene/styrene resin, and a methyl methacrylate/styrene resin, and the resin is preferably an methyl methacrylate/styrene resin. From the viewpoint that heat resistance of a semiconductor substrate is required in a step of a high-temperature treatment, a resin having an amount of out-gas generated during the heating at 250° C. of preferably 3% by mass or less, and more preferably 2% by mass or less is preferable. As a commercially available product of the methyl methacrylate/styrene resin, ESTYRENE MS-200NT, MS-300, MS-500, and MS-600 (manufactured by Nippon Steel & Sumikin Chemical Co., Ltd.) or CEVIAN MAS10 and MAS30 (manufactured by Daicel Polymer Co., Ltd.)) can are particularly preferably used.

Examples of the cycloolefin polymer include a norbornene-based polymer, a polymer of monocyclic cycloolefin, a polymer of cyclic conjugated diene, a vinyl alicyclic hydrocarbon polymer, and hydrogenated compounds of these polymers. Preferred examples of the cycloolefin polymer include an addition (co)polymer containing at least one repeating unit represented by the following General Formula (II) and an addition (co)polymer further containing at least one repeating unit represented by the following General Formula (I). Further, other preferred examples of the cycloolefin polymer include a ring-opening (co)polymer containing at least one cyclic repeating unit represented by the following General Formula (III).

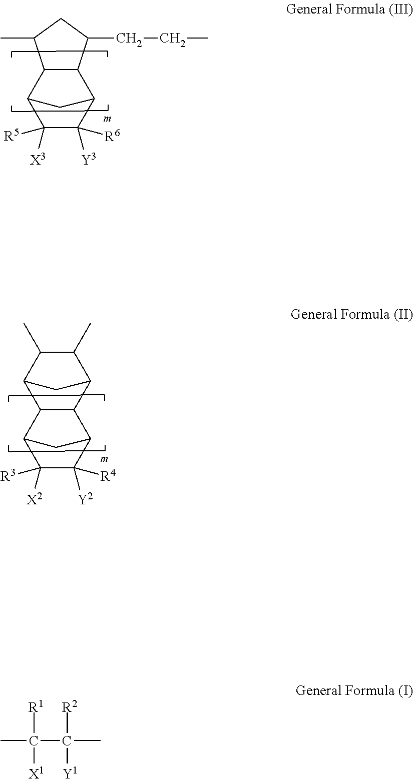

In the formulae, m represents an integer of 0 to 4, R¹ to R⁶ each independently represent a hydrogen atom or a hydrocarbon group having 1 to 10 carbon atoms, X X¹ to X³, and Y¹ to Y³ each independently represent a hydrogen atom, a hydrocarbon group having 1 to 10 carbon atoms, a halogen atom, a hydrocarbon group having 1 to 10 carbon atoms substituted with a halogen atom, —(CH₂)nCOOR¹¹, —(CH₂)nOCOR¹², —(CH₂)nNCO, —(CH₂)nNO₂, —(CH₂)nCN, —(CH₂)nCONR¹³R¹⁴, —(CH₂)nNR¹⁵R¹⁶, —(CH₂)nOZ, —(CH₂)nW, or (—CO)₂O or (—CO)₂NR¹⁷, each of which is constituted with X¹ and Y¹, X² and Y², or X³ and Y³. R¹¹, R¹², R¹³, R¹⁴, R¹⁵, R¹⁶ and R¹⁷ each independently represent a hydrogen atom or a hydrocarbon group (preferably a hydrocarbon group having 1 to 20 carbon atoms), Z represents a hydrocarbon group or a hydrocarbon group substituted with a halogen atom, W represents SiR¹⁸ₚD₃₋ₚ (R¹⁸ represents a hydrocarbon group having 1 to 10 carbon atoms, D represents a halogen atom, —OCOR¹⁸ or —OR¹⁸, and p represents an integer of 0 to 3), and n represents an integer of 0 to 10.

The norbornene-based polymers are disclosed, for example, in JP1998-7732A (JP-H10-7732A), JP2002-504184A, US2004/229157A1, and WO2004/070463A1. The norbornene polymer is obtained by addition polymerization of norbornene polycyclic unsaturated compounds to each other. Furthermore, if desired, the norbornene polycyclic unsaturated compound can be addition-polymerized with ethylene, propylene, butene; a conjugated diene, for example, butadiene or isoprene; or a non-conjugated diene, for example, ethylidene norbornene. The norbornene polymer is marketed under the trade name of APEL from Mitsui Chemicals, Inc. including the grades having different glass transition temperature (Tg), for example, APL 8008T (Tg: 70° C.), APL 6013T (Tg: 125° C.) and APL 601ST (Tg: 145° C.). Pellets, for example, TOPAS 8007, TOPAS 5013, TOPAS 6013, TOPAS 6015, and the like are marketed from Polyplastics Co., Ltd.

In addition, APPEAR 3000 is marketed from Ferrania S.p.A.

The hydrogenated product of norbornene polymer can be produced by addition polymerization or metathesis ring opening polymerization of the polycyclic unsaturated compound, followed by hydrogenation as disclosed, for example, in JP1989-240517A (JP-H01-240517A), JP1995-196736A (JP-H07-196736A), JP1985-26024A (JP-S60-26024A), JP1987-19801A (JP-S62-19801A), JP2003-1159767A, and JP2004-309979A.

In General Formula (III), R⁵ and R⁶ are each preferably a hydrogen atom or a methyl group, X³ and Y³ are each preferably a hydrogen atom, and other groups are appropriately selected. The norbornene polymers are commercially available under the trade names of ARTON G and ARTON F from JSR Corporation, and under the trade names of ZEONOR ZF14, ZEONOR ZF16, ZEONEX 250, ZEONEX 280, and ZEONEX 480R from Zeon Corporation, and these can be used.

The weight average molecular weight of the polymer compound, as determined by a gel permeation chromatography (GPC) method and calculated in terms of polystyrene, is preferably 10,000 to 1,000,000, more preferably 50,000 to 500,000, and still more preferably 100,000 to 300,000.

In the case where the adhesive layer precursor contains a polymer compound, the content of the polymer compound is preferably 5% by mass or more, more preferably 10% by mass or more, and still more preferably 20% by mass or more, with respect to the total solid content of adhesive layer precursor.

Furthermore, in the case where the adhesive layer precursor contains a polymer compound, the content of the polymer compound is preferably 70% by mass or less, more preferably 60% by mass or less, still more preferably 50% by mass or less, and particularly preferably 40% by mass or less, with respect to the total solid content of the adhesive layer precursor.

One kind or two or more kinds of the polymer compound may be used. In the case where two or more kinds of the polymer compound are used, the total sum thereof is preferably within the above range.

Moreover, the ratio (mass ratio) (radically polymerizable compound/polymer compound) of the content of the polymerizable compound (in particular, the polymerizable monomer) 9 to the polymer compound is preferably 100/0 to 10/90, more preferably 100/0 to 20/80, and still more preferably 100/0 to 30/70.

<Non-Polymerizable Polymer Compound Containing Fluorine Atom>

The adhesive precursor layer of the present invention preferably includes a non-polymerizable polymer compound containing a fluorine atom. As the non-polymerizable polymer compound containing a fluorine atom, a polymer formed of one kind or two or more kinds of fluorine-containing monofunctional monomer can be preferably used. More specific examples thereof include at least one kind of fluorine-containing resin selected from a homopolymer of one kind or two or more kinds of fluorine-containing monofunctional monomer selected from tetrafluoroethylene, hexafluoropropane, tetrafluoroethylene oxide, hexafluoropropane oxide, perfluoroalkylvinyl ether, chlorotrifluoroethylene, vinylidene fluoride, and a perfluoroalkyl group-containing (meth)acrylic ester, or a copolymer of these monomers; a copolymer of one kind or two or more kinds of the fluorine-containing monofunctional monomer with ethylene; and a copolymer of one kind or two or more kinds of the fluorine-containing monofunctional monomer with chlorotrifluoroethylene.

As the non-polymerizable polymer compound containing a fluorine atom, a perfluoroalkyl group-containing (meth)acrylic resin which can be synthesized from a perfluoroalkyl group-containing (meth)acrylic ester is preferable.

As the perfluoroalkyl group-containing (meth)acrylate ester, specifically, a compound represented by the following Formula (101) is preferable.

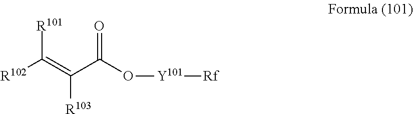

In General Formula (101), R¹⁰¹, R¹⁰², and R¹⁰³ each independently represent a hydrogen atom, an alkyl group, or a halogen atom. Y¹⁰¹ represents a single bond or a divalent linking group selected from the group consisting of —CO—, —O—, —NH—, a divalent aliphatic group, a divalent aromatic group, and a combination thereof. Rf is a fluorine atom or an monovalent organic group containing at least one fluorine atom.

In General Formula (101), a preferred example of the alkyl group represented by R¹⁰¹, R¹⁰², and R¹⁰³ is an alkyl group having 1 to 8 carbon atoms, and examples thereof include a methyl group, an ethyl group, a propyl group, an octyl group, an isopropyl group, a tert-butyl group, an isopentyl group, a 2-ethylhexyl group, a 2-methylhexyl group, and a cyclopentyl group. A preferred example of the aryl group is an aryl having 6 to 12 carbon atoms, and examples thereof include a phenyl group, a 1-naphthyl group, and a 2-naphthyl group. Among these, R¹⁰¹ to R¹⁰³ are preferably a hydrogen atom or a methyl group.

Y¹⁰¹ represents a single bond or a divalent linking group selected from the group consisting of —CO—, —O—, —NH—, a divalent aliphatic group, a divalent aromatic group, and a combination thereof, and as the divalent aliphatic group, a chained structure is preferred to a cyclic structure, and a linear structure is preferred to a chained structure having a branch. The number of carbon atoms contained in the divalent aliphatic group is preferably 1 to 20, more preferably 1 to 15, still more preferably 1 to 12, even still more preferably 1 to 10, even still more preferably 1 to 8, and particularly preferably 1 to 4. Examples of the divalent aromatic group include a phenylene group, a substituted phenylene group, a naphthalene group, and a substituted naphthalene group, with the phenylene group being preferable.

As Y¹⁰¹, an aliphatic group having a divalent linear structure is preferable.

The monovalent organic group containing a fluorine atom, represented by Rf, is not particularly limited, and is preferably a fluorine-containing alkyl group having 1 to 30 carbon atoms, more preferably a fluorine-containing alkyl group having 1 to 20 carbon atoms, and particularly preferably a fluorine-containing alkyl group having 1 to 15 carbon atoms. This fluorine-containing alkyl group may be linear {for example, —CF₂CF₃, —CH₂(CF₂)₄H, —CH₂(CF₂)₈CF₃, and —CH₂CH₂(CF₂)₄H}, may have a branched structure {for example, —CH(CF₃)₂, —CH₂CF(CF₃)₂, —CH(CH₃)CF₂CF₃, and —CH(CH₃)(CF₂)₅CF₂H}, may have an alicyclic structure (preferably a 5- or 6-membered ring, for example, a perfluorocyclohexyl group, a perfluorocyclopentyl group, and an alkyl group substituted therewith), and may have an ether bond (for example, —CH₂OCH₂CF₂CF₃, —CH₂CH₂OCH₂C₄F₈H, —CH₂CH₂OCH₂CH₂C₈F₁₇, and —CH₂CF₂OCF₂CF₂OCF₂CF₂H). Further, it may be a perfluoroalkyl group.

That is, the perfluoroalkyl group-containing (meth)acrylic resin specifically has a repeating unit represented by the following Formula (102).

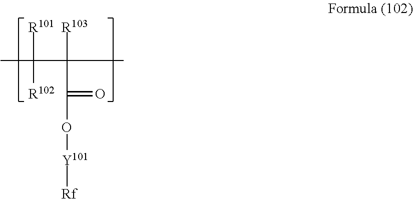

In General Formula (102), R¹⁰¹, R¹⁰², R¹⁰³, Y¹⁰¹, and Rf each have the same definitions as in General Formula (101), and preferred embodiments thereof are also the same.

The perfluoroalkyl group-containing (meth)acrylic resin can arbitrarily select components to be copolymerized, in addition to the perfluoroalkyl group-containing (meth)acrylic ester from the viewpoint of peelability. Examples of the radically polymerizable compound capable of forming the components to be copolymerized include radically polymerizable compounds selected from acylic esters, methacrylic esters, N,N-disubstituted acrylamides, N,N-disubstituted methacrylamides, styrenes, acrylonitriles, and methacrylonitriles.

More specific examples thereof include acrylic esters such as alkyl acrylates (preferably containing an alkyl group having 1 to 20 carbon atoms) (for example, methyl acrylate, ethyl acrylate, propyl acrylate, butyl acrylate, amyl acrylate, ethylhexyl acrylate, octyl acrylate, t-octyl acrylate, chloroethyl acrylate, 2,2-dimethylhydroxypropyl acrylate, 5-hydroxypentyl acrylate, trimethylolpropane monoacrylate, pentaerythritol monoacrylate, glycidyl acrylate, benzyl acrylate, methoxybenzyl acrylate, furfuryl acrylate, and tetrahydrofurfuryl acrylate); aryl acrylates (for example, phenyl acrylate); methacrylic esters such as alkyl methacrylates (preferably containing an alkyl group having 1 to 20 carbon atoms) (for example, methyl methacrylate, ethyl methacrylate, propyl methacrylate, isopropyl methacrylate, amyl methacrylate, hexyl methacrylate, cyclohexyl methacrylate, benzyl methacrylate, chlorobenzyl methacrylate, octyl methacrylate, 4-hydroxybutyl methacrylate, 5-hydroxypentyl methacrylate, 2,2-dimethyl-3-hydroxypropyl methacrylate, trimethylolpropane monomethacrylate, pentaerythritol monomethacrylate, glycidyl methacrylate, furfuryl methacrylate, and tetrahydrofurfuryl methacrylate); aryl methacrylates (for example, phenyl methacrylate, cresyl methacrylate, and naphthyl methacrylate); styrenes such as styrene and alkyl styrene (for example, methylstyrene, dimethylstyrene, trimethylstyrene, ethylstyrene, diethylstyrene, isopropylstyrene, butylstyrene, hexylstyrene, cyclohexylstyrene, decylstyrene, benzyl styrene, chloromethylstyrene, trifluoromethylstyrene, ethoxymethylstyrene, and acetoxymethylstyrene); alkoxystyrenes (for example, methoxystyrene, 4-methoxy-3-methylstyrene, and dimethoxystyrene); halogen-containing styrenes (for example, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, and 4-fluoro-3-trifluoromethylstyrene); acrylonitrile, methacrylonitrile; and carboxylic acid-containing radically polymerizable compounds (acrylic acid, methacrylic acid, itaconic acid, crotonic acid, isocrotonic acid, maleic acid, p-carboxylstyrene, metal salts of these acid groups, and ammonium salt compounds). However from the viewpoint of peelability, (meth)acrylic esters containing a hydrocarbon group having 1 to 24 carbon atoms are particularly preferable, and examples thereof include methyl(meth)acrylate, butyl(meth)acrylate, 2-ethylhexyl(meth)acrylate, lauryl(meth)acrylate, stearyl(meth)acrylate, and glycidyl esters, with (meth)acrylates, in particular, acrylates of higher hydric alcohols, such as 2-ethylhexyl(meth)acrylate, lauryl(meth)acrylate, and stearyl(meth)acrylate being preferable.

Examples of commercially available products as the non-polymerizable polymer compound containing a fluorine atom as described above include Teflon (registered trademark) (DuPont), Tefzel (Dupont), Fluon (Asahi Glass Co., Ltd.), Heira (Solvay Solexis Inc.), Heiler (Solvay Solexis Inc.), Lumiflon (Asahi Glass Co., Ltd.), Aflas (Asahi Glass Co., Ltd.), CEFRAL SOFT (Central Glass Co., Ltd.), Sefurarukoto (Central Glass Co., Ltd.), fluorine resin etc., Viton (DuPont), Kalrez (DuPont), SIFEL (fluorine rubber with a trade name of Shin-Etsu Chemical Co., Ltd.), etc., Krytox (DuPont), Fomblin (Daedeok Tech Co., Ltd.), various fluorine oils including a perfluoropolyether oil such as DEMNUM (Daikin Industries, Ltd.), DAIFREE FB series (Daikin Industries, Ltd.), and fluorine-containing releasing agents with a trade name of Megaface series (DIC Corporation), but are not limited thereto, and any one which is a non-polymerizable polymer compound containing a fluorine atom can be suitably used.

The weight average molecular weight of the non-polymerizable polymer compound containing a fluorine atom, as determined by a gel permeation chromatography (GPC) method and calculated in terms of polystyrene, is preferably 2,000 to 100,000, more preferably 2,000 to 50,000, and most preferably 2,000 to 10,000.

In the case where the non-polymerizable polymer compound containing a fluorine atom has a radically polymerizable compound containing a fluorine atom in the adhesive layer precursor, particularly, the effect of improving the peelability is significant and it is most preferable to use a combination of a radically polymerizable compound containing a fluorine atom with a non-polymerizable polymer compound containing a fluorine atom.

In the present invention, the ratio (mass ratio) of the radically polymerizable compound containing a fluorine atom to the non-polymerizable polymer compound containing a fluorine atom in the adhesive layer precursor is preferably 5:95 to 50:50, more preferably 10:90 to 40:60, and still more preferably 15:85 to 30:70.

The content of the non-polymerizable polymer compound containing a fluorine atom is preferably 1% by mass to 99% by mass, more preferably 3% by mass to 95% by mass, and still more preferably 5% by mass to 90% by mass, with respect to the total solid content of the adhesive layer precursor, from the viewpoint of good peelability.

<<Chain Transfer Agent>>

The adhesive layer precursor of the present invention preferably contains a chain transfer agent. The chain transfer agent is defined, for example, in Kobunshi Jiten Polymer Dictionary, Third Edition, pp. 683 to 684 (edited by The Society of Polymer Science, 2005). As the chain transfer agent, for example, compounds having SH, PH, SiH, or GeH in their molecules are used. The compound donates a hydrogen to a low active radical species to generate a radical or is oxidized and then deprotonized to generate a radical. In the temporary adhesive, a thiol compound (for example, 2-mercaptobenzimidazole, 2-mercaptobenzothiazole, 2-mercaptobenzoxazole, 3-mercaptotriazole, and 5-mercaptotetrazole) can be preferably used.

In the case where the adhesive layer precursor has a chain transfer agent, the content of the chain transfer agent is preferably 0.01 parts by mass to 20 parts by mass, more preferably 1 part by mass to 10 parts by mass, and particularly preferably 1 part by mass to 5 parts by mass, with respect to 100 parts by mass of the total solid content of the adhesive layer precursor. One kind or two or more kinds of the chain transfer agent may be used.

In the case where two or more kinds of the chain transfer agents are used, the total sum thereof is preferably within the above range.

<<Polymerization Inhibitor>>

It is preferable to add a small amount of a polymerization inhibitor to the adhesive layer precursor of the present invention in order to inhibit undesirable thermal polymerization of the polymer compound and the radically polymerizable compound during production or storage of the temporary adhesive.

Suitable examples of the polymerization inhibitor include hydroquinone, p-methoxyphenol, di-tert-butyl-p-cresol, pyrogallol, tert-butylcatechol, benzoquinone, 4,4′-thiobis(3-methyl-6-tert-butylphenol), 2,2′-methylenebis(4-methyl-6-tert-butylphenol), and an N-nitrosophenylhydroxyamine aluminum salt.

In the case where the adhesive layer precursor has a polymerization inhibitor, the amount of the polymerization inhibitor to be added is preferably about 0.01% by mass to about 5% by mass, with respect to the total solid of the adhesive layer precursor.

One kind or two or more kinds of the polymerization inhibitor may be used. In the case where two or more kinds of the polymerization inhibitor are used, the total sum thereof is preferably within the above range.

<<Higher Fatty Acid Derivative and the Like>>

A higher fatty acid derivative such as behenic acid and behenic acid amide may be added to the adhesive layer precursor of the present invention, and allowed to exist at the surface of the adhesive layer in the course of the drying step after coating for the purpose of preventing inhibition of polymerization by oxygen.

In the case where the adhesive layer precursor has a higher fatty acid derivative, the amount of the higher fatty acid derivative to be added is preferably about 0.1% by mass to about 10% by mass with respect to the total solid content of the adhesive layer precursor.

One kind or two or more kinds of the higher fatty acid derivative may be used. In the case where two or more kinds of the higher fatty acid derivative or the like are used, the total sum thereof is preferably within the above range.

<<Solvent>>

In the case where a layer is formed by applying the adhesive layer precursor of the present invention, it is preferable to blend a solvent.

As the solvent, any known solvent which can form an adhesive layer can be used without limitation.

Suitable examples of the organic solvent include esters such as ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, alkyl oxyacetate (for example, methyl oxyacetate, ethyl oxyacetate, and butyl oxyacetate (for example, methyl methoxyacetate, ethyl methoxyacetate, butyl methoxyacetate, methyl ethoxyacetate, and ethyl ethoxyacetate)), alkyl 3-oxypropionate esters (for example, methyl 3-oxypropionate and ethyl 3-oxypropionate (for example, methyl 3-methoxypropionate, ethyl 3-methoxypropionate, methyl 3-ethoxypropionate, and ethyl 3-ethoxypropionate)), alkyl 2-oxypropionate esters (for example, methyl 2-oxypropionate, ethyl 2-oxypropionate, and propyl 2-oxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-oxy-2-methyl propionate and ethyl 2-oxy-2-methyl propionate (for example, methyl 2-methoxy-2-methyl propionate and ethyl 2-ethoxy-2-methyl propionate), methyl pyruvate, ethyl pyruvate, propyl pyruvate, methyl acetoacetate, ethyl acetoacetate, methyl 2-oxobutanoate, and ethyl 2-oxobutanoate; ethers such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethy ether acetate, propylene glycol monoethyl ether acetate, and propylene glycol monopropyl ether acetate; ketones such as methyl ethyl ketone, cyclohexanone, 2-heptanone, 3-heptanone, and N-methyl-2-pyrrolidone; and aromatic hydrocarbons such as toluene, xylene, anisole, and limonene.

From the viewpoint of, for example, improving the coated surface state, an embodiment of mixing two or more of these organic solvents is also preferred. In this case, a mixed solution consisting of two or more kinds selected from the aforementioned methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethylcarbitol acetate, butylcarbitol acetate, propylene glycol methyl ether, and propylene glycol methyl ether acetate is particularly preferable.

In the case where the adhesive layer precursor has a solvent, from the viewpoint of coatability, the content of the solvent in the coating liquid of the adhesive layer, is set such that the concentration of the total solid contents of the composition becomes preferably 5% by mass to 80% by mass, more preferably 5% by mass to 70% by mass, and particularly preferably 10% by mass to 60% by mass. One kind or two or more kinds of solvent may be used. In the case where two or more kinds of the solvents are used, the total sum thereof is preferably within the above range.

<<Surfactant>>

From the viewpoint of further improving the coatability, various surfactants may be added to the adhesive layer precursor of the present invention. As the surfactant, various surfactants such as a fluorine-based surfactant, a nonionic surfactant, a cationic surfactant, an anionic surfactant, and a silicone-based surfactant can be used.

In particular, by incorporating a fluorine-based surfactant, the liquid characteristics (in particular, fluidity) of a coating liquid as prepared is further improved, so that the uniformity in the coating thickness or the liquid-saving property can be further improved.

That is, in the case of forming a film by using a coating liquid containing a fluorine-based surfactant, the interface tension between a surface to be coated and the coating liquid is reduced, whereby wettability to the surface to be coated is improved and the coatability on the surface to be coated is enhanced. This is effective in that even when a thin film of about several μm is formed with a small liquid volume, formation of a film with little thickness unevenness and uniform thickness can be carried out in a more suitable manner.

The fluorine content in the fluorine-based surfactant is preferably 3% by mass to 40% by mass, more preferably 5% by mass to 30% by mass, and still more preferably 7% by mass to 25% by mass. The fluorine-based surfactant having a fluorine content within the above range is effective in view of the uniformity in thickness of the coated film and the liquid-saving property, and also exhibits good solubility.

Examples of the fluorine-based surfactant include Megaface F 171, Megaface F 172, Megaface F173, Megaface F176, Megaface F177, Megaface F141, Megaface F142, Megaface F143, Megaface F144, Megaface R30, Megaface F437, Megaface F475, Megaface F479, Megaface F482, Megaface F554, Megaface F780, and Megaface F781 (all manufactured by DIC Corporation), Florad FC430, Florad FC431, and Florad FC171 (all manufactured by Sumitomo 3M Ltd.), Surflon S-382, Surflon SC-101, Surflon SC-103, Surflon SC-104, Surflon SC-105, Surflon SC1068, Surflon SC-381, Surflon SC-383, Surflon S393, and Surflon KH-40 (all manufactured by Asahi Glass Co., Ltd.), and PF636, PF656, PF6320, PF6520, and PF7002 (all manufactured by OMNOVA Solutions Inc.).

Specific examples of the nonionic surfactant include glycerol, trimethylolpropane, trimethylolethane, their ethoxylate and propoxylate (such as glycerol propoxylate and glycerin ethoxy late), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and sorbitan fatty acid ester (PLURONIC L10, L31, L61, L62, 10R5, 17R2, and 25R2, TETRONIC 304, 701, 704, 901, 904, and 150R1 (all manufactured by BASF Corporation), and Solsperse 20,000 (manufactured by The Lubrizol Corporation)).

Specific examples of the cationic surfactant include phthalocyanine derivatives (product name EFKA-745 manufactured by MORISHITA SANGYO Corporation), organosiloxane polymer KP341 (manufactured by Shin-Etsu Chemical Co., Ltd.), (meth)acrylic acid-based (co)polymer Polyflow No. 75, No. 90, and No. 95 (manufactured by KYOEISHA CHEMICAL CO., LTD.), and W001 (manufactured by Yusho Co., Ltd.).

Specific examples of the anionic surfactant include W004, W005, and W017 (manufactured by Yusho Co., Ltd.).

Examples of the silicone-based surfactant include “Toray Silicone DC3PA”, “Toray Silicone SH7PA”, “Toray Silicone DC11PA”, “Toray Silicone SH21PA”, “Toray Silicone SH28PA”, “Toray Silicone SH29PA”, “Toray Silicone SH30PA”, and “Toray Silicone SH8400”, manufactured by Dow Corning Toray, “TSF-4440”, “TSF-4300”, “TSF-4445”, “TSF-4460”, and “TSF-4452”, manufactured by Momentive Performance Materials Inc., “KP341”, “KF6001”, and “KF6002”, manufactured by Shin-Etsu Silicones, and “BYK307”, “BYK323”, and “BYK330”, manufactured by BYK-Chemie.

In the case where the adhesive layer precursor has a surfactant, the amount of the surfactant added is preferably 0.001% by mass to 2.0% by mass and more preferably 0.005% by mass to 1.0% by mass, with respect to the total solid of the adhesive layer precursor.

One kind or two or more kinds of the surfactant may be used. In the case where two or more kinds of the surfactant are used, the total sum thereof is preferably within the above range.

<<Other Additives>>

If desired, various additives such as a curing agent, a curing catalyst, a silane coupling agent, a filler, an adhesion promoting agent, an antioxidant, an ultraviolet absorber, and an anti-aggregation agent may be blended into the adhesive layer precursor within a range not interfering with the effects of the present invention. In the case of blending these additives, the total blending amount is preferably set to 3% by mass or less of the solid content of the adhesive layer precursor.

The adhesive layer can be formed by coating the composition for forming an adhesive layer (adhesive layer precursor coating liquid) by a spin coating method, a spraying method, a roller coating method, a flow coating method, a doctor coating method, or a dipping method, which has been known in the related art, followed by drying (baking). Drying can be carried out by, for example, at 60° C. to 150° C. for 10 seconds to 2 minutes.

The softening point of the adhesive layer is 250° C. or higher, preferably 260° C. or higher, and more preferably 250° C. to 350° C. The softening point is measured as a temperature at which the loss tangent (tans) measured using an viscoelastiity measuring apparatus under a constant temperature rising condition becomes a maximum.

The loss tangent (tan δ) is calculated by the following equation.

tan δ=G″/G′

In the equation, G″ represents a loss shear elastic modulus and G′ represents a storage shear elastic modulus.

The temperature rising rate is preferably in the range of 0.5° C./min to 20° C./min, more preferably in the range of 1° C./min to 10° C./min, and particularly preferably in the range of 2° C./min to 5° C./min.

In the case where a peak of tan δ does not appear by raising the temperature from a sufficiently low temperature of approximately about −100° C. to a predetermined temperature (Ta° C.), in which the softening point of −100° C. or lower is not possibly considered from the compounds constituting the adhesive layer, the softening point can be set to a predetermined temperature (Ta° C.) or higher. That is, the adhesive layer in the present invention is usually a layer in which the structure (Tg) of −100° C. or lower is not possibly considered, and means a layer in which a peak of tan δ does not appear even by raising the temperature from −100° C. to 250° C.

As the dynamic viscoelasticity device, for example, Rheogel-E4000 (manufactured by UBM Co., Ltd.) can be used.

The thickness of the adhesive layer is preferably 1 μm to 500 μm, more preferably 1 μm to 100 μm, and still more preferably 1 μm to 10 μm.

The storage elastic modulus of the adhesive layer at 25° C. is preferably 1 MPa to 10 GPa, more preferably 10 mPa to 10 gPa, and still more preferably 100 MPa to 10 GPa. The elastic modulus can be measured by, for example, Viscoelasticity Measuring Apparatus (Rheosol-G1000 (manufactured by UBM Co., Ltd.). The value thus obtained is defined as an elastic modulus, and further by setting the protective layer to the elastic modulus as will be described later, the unevenness occurring during polishing of the apparatus can be more effective inhibited and the cleaning of the protective layer tends to be improved.

<Support (A)>

The laminate of the present invention has a support (A) (which is also referred to as a carrier substrate).

A material of the support is not particularly limited and examples thereof include a silicon substrate, a glass substrate, and a metal substrate. Taking them into consideration that a silicon substrate which is typically used as a substrate of semiconductor device is hardly contaminated and that an electrostatic chuck which is commonly used in the process of producing a semiconductor device can be used, a silicon substrate is preferable.

The thickness of the support is, for example, in the range of 300 μm to 5 mm, but is not particularly limited.

<Protective Layer (C)>

The laminate of the present invention has a protective layer (C). By providing the protective layer, the protective layer can be combined with the adhesive layer to make the thickness of the laminate uniform and thus effectively inhibit the unevenness when the device wafer is polished.

As the protective layer, any known ones can be used without limitation, but those which can reliably protect the device chip as will described later is preferable.

For the purpose of protecting a base material to be treated, any known compounds can be used without limitation as a material constituting the protective layer. As a specific example thereof, a synthetic resin such as a phenol resin, an epoxy resin, a melamine resin, a urea resin, an unsaturated polyester resin, an alkyd resin, a polyurethane, polyimide, polyethylene, polypropylene, polyvinyl chloride, polystyrene, polyvinyl acetate, Teflon (registered trademark), an ABS resin, an AS resin, an acrylic resin, a polyamide, polyacetal, polycarbonate, polyphenylene ether, polybutylene terephthalate, polyethylene terephthalate, cyclic polyolefin, polyphenylene sulfide, polysulfone, polyether sulfone, polyarylate, polyether ether ketone or polyamideimide; a natural resin such as a natural rubber; or a hydrocarbon resin can be preferably used. As a commercially available product thereof, ZEONEX480R (manufactured by Zeon Corporation) or the like can be preferably used.

As the protective layer, a thermoplastic resin is preferable. Specifically, at least one thermoplastic resin selected from a polyethersulfone resin, a polyimide resin, a polyester resin, a polybenzimidazole resin, a polystyrene resin, a polyamideimide resin, a polycarbonate resin, a hydrocarbon resin, and a polyetheretherketone resin is preferable.

As a commercially available product thereof, Ultrason E 6020P (manufactured by BASF Corporation), PCZ-300 (manufactured by Mitsubishi Gas Chemical Co., Inc.), ESTYRENE MS200NT (Nippon Steel Chemical Co., Ltd.), TOPAS5013 (manufactured by Polyplastics Co., Ltd.), or the like can be suitably used.

The softening point of the protective layer is preferably 170° C. to 250° C., and more preferably 200° C. to 250° C. A polyethersulfone resin, a polycarbonate resin, a polystyrene resin, a hydrocarbon resin, and a polyetheretherketone resin, each having a softening point of 170° C. to 250° C., are more preferable, and a polyethersulfone resin, a polycarbonate resin, a polystyrene resin, and a polyetheretherketone resin, each having a softening point of 170° C. to 250° C., are most preferable.

The softening point of the protective layer is preferably lower than the softening point of the adhesive layer. In the case where the softening point of the protective layer is lower than the softening point of the adhesive layer, the cleaning property of the protective layer tends to be improved. The difference between the softening point of the protective layer and the softening point of the adhesive layer is preferably 10° C. to 300° C., more preferably 10° C. to 200° C., and still more preferably 30° C. to 200° C.

Moreover, the protective layer may contain a compound which can be contained in the adhesive layer precursor, if desired, within a range not interfering with the effects of the present invention.

The protective layer can be formed by coating the composition for forming a protective layer (protective layer coating liquid) by a spin coating method, a spraying method, a roller coating method, a flow coating method, a doctor coating method, a dipping method, or the like, which is known in the related art, followed by drying (baking). Drying can be carried out by, for example, at 60° C. to 150° C. for 10 seconds to 2 minutes. The protective layer coating liquid preferably includes the resin and a solvent.

The thickness of the protective layer is preferably 1 μm to 300 μm, more preferably 10 μm to 200 μm, and still more preferably 20 μm to 150 μm. In the case where there is a structure on the surface of the device wafer, the thickness of the protective layer is preferably no less than the thickness of the structure.

The storage elastic modulus of the protective layer at 25° C. is preferably 10 MPa to 1 GPa, more preferably 100 MPa to 5 GPa, and still more preferably 1,000 MPa to 3 GPa.

The storage elastic modulus of the protective layer is preferably the storage elastic modulus of the adhesive layer, and the value of [the storage elastic modulus of the protective layer]/[the storage elastic modulus of the adhesive layer] is preferably 0.9 to 0.01, more preferably 0.8 to 0.05, and particularly preferably 0.5 to 0.1.

The protective layer of the present invention preferably includes a non-polymerizable polymer compound containing a fluorine atom. Further, a preferred embodiment of the non-polymerizable polymer compound containing a fluorine atom is the same as one described from the non-polymerizable polymer compound containing a fluorine atom included in the adhesive layer precursor as described above, and a preferred range is also the same.

The content of the non-polymerizable polymer compound containing a fluorine atom is preferably 0.01% by mass to 99% by mass, more preferably 0.03% by mass to 50% by mass, and still more preferably 0.05% by mass to 10% by mass, with respect to the total solid content of the protective layer, from the viewpoint of good peelability.

In the case where the adhesive layer precursor has a polymerizable radically polymerizable compound containing a fluorine atom, the non-polymerizable polymer compound containing a fluorine atom particularly has a significant effect of improving peelability, and it is most preferable to use a combination of the polymerizable radically polymerizable compound containing a fluorine atom with the non-polymerizable polymer compound containing a fluorine atom.

The non-polymerizable polymer compound containing a fluorine atom is preferably included in at least one of the protective layer or the adhesive layer precursor, or may be included in both of the layers. From the viewpoint of peelability, it is preferable that the non-polymerizable polymer compound containing a fluorine atom is included in any one of the protective layer or the adhesive layer precursor, and in order to form the adhesive layer having a softening point of 250° C. or higher of the present invention, it is most preferable that non-polymerizable polymer compound containing a fluorine atom is included in the protective layer.

In the present invention, the ratio (mass ratio) of the radically polymerizable compound containing a fluorine atom in the adhesive layer precursor to the non-polymerizable polymer compound containing a fluorine atom in protective layer is preferably 5:95 to 5:95, more preferably 10:90 to 90:10, and preferably 15:85 to 30:70.

<Device Wafer (D)>

The laminate of the present invention has a device wafer (D).

As the device wafer, known ones can be used without limitation, and examples thereof include MEMS and a device for a sensor.

The device wafer is preferably one having a structure on the surface, and as the structure, a structure having a height of 1 μm to 150 μm is preferable. The device wafer is preferably one having a metal structure (also referred to as a metal bump) having a height of 1 μm to 150 μm. The height of the structure is preferably 5 μm to 100 μm.

The film thickness of the device wafer is not particularly limited, and is preferably 100 μm or less, more preferably 80 μm or less, and still more preferably 70 μm or less. The lower limit is not particularly limited and is 10 μm or more.

Kit:

The present invention relates to a kit which includes a composition for forming a protective layer, including a resin and a solvent, and a composition (adhesive layer precursor) for forming an adhesive layer, including a solvent and a polymerizable compound.

It becomes possible to manufacture the laminate of the present invention by coating a composition for forming an adhesive layer on a support to carry out the coating of the composition for forming an adhesive layer, and then coating a composition for forming a protective layer.

Each of the compositions, preferred ranges, and the like of the composition for forming an adhesive layer and the composition for forming a protective layer is the same as those described above in the sections of the adhesive layer precursor and the protective layer.

The laminate, the composition for forming a protective layer, the composition for forming an adhesive layer, and the kit of the present invention are preferably used in production of a semiconductor. As a method for producing a device for producing a semiconductor, a method including a step of adhering a first surface of a member (device wafer) to be treated to a support through an adhesive layer and a protective layer, a step of subjecting a second surface opposite to the first surface of the member to be treated to a mechanical or chemical treatment to obtain a treated member, and a step to separate the adhesive layer from the treated member is exemplified.

Furthermore, it is preferable that the method further includes a step of irradiating the surface of the adhesive layer to be in contact with the protective layer to the actinic rays or radiation or with heat, before the step of adhering the first surface of the member to be treated to the support through the adhesive layer and the protective layer. The actinic rays or radiation is preferably an actinic ray at a wavelength of 350 nm to 450 nm.

Furthermore, it is preferable that the method for producing a semiconductor device further includes a step of heating the adhesive layer at a temperature of 50° C. to 300° C. after the step of adhering the first surface of the member to be treated to the support through the adhesive layer and the protective layer and before a step of subjecting the second surface opposite to the first surface of the member to be treated to a mechanical or chemical treatment to obtain a treated member. In particular, the laminate of the present invention is suitable for being used in an environment for use at 250° C. or higher.

For the laminate of the present invention, a method for adhering a support (A) having an adhesive layer (B) to a device wafer (D) having a protective layer (C) is preferable.

The adhesive layer (B) is converted to an adhesive layer by curing the polymerizable compound in the adhesive layer precursor by the step of irradiating the adhesive layer precursor as described above with actinic rays or radiation, or heat.

Irradiation of actinic rays or radiation, or heat may be a method in which the entire surface of the adhesive layer precursor is irradiated with the same energy, or may be a method in which irregular irradiation is carried out to separate a weakly adhesive region from a strongly adhesive region.

In the case where the entire surface of the adhesive layer precursor is irradiated with the same energy, the reaction rate of the polymerizable compound is preferably 20% to 70%, more preferably 20% to 60%, and most preferably 25% to 50%, from the viewpoints of adhesiveness and release peelability.

In addition, the adhesiveness and the release peelability can be improved by forming the laminate of the present invention, followed by further irradiation of actinic rays or radiation, or heat to control the polymerization rate of the polymerizable compound in the adhesive layer precursor to 50% to 100%.

Furthermore, in the case where irregular irradiation is carried out to separate a weakly adhesive region from a strongly adhesive region, both of the adhesiveness and the release peelability can be satisfied by setting the polymerization rate of the polymerizable compound to 0% to 50% in the strongly adhesive region and to 50% to 100% in the weakly adhesive region.

Hereinafter, the details will be described, but the method for producing a laminate and the method for producing a semiconductor device of the present invention are not limited thereto.

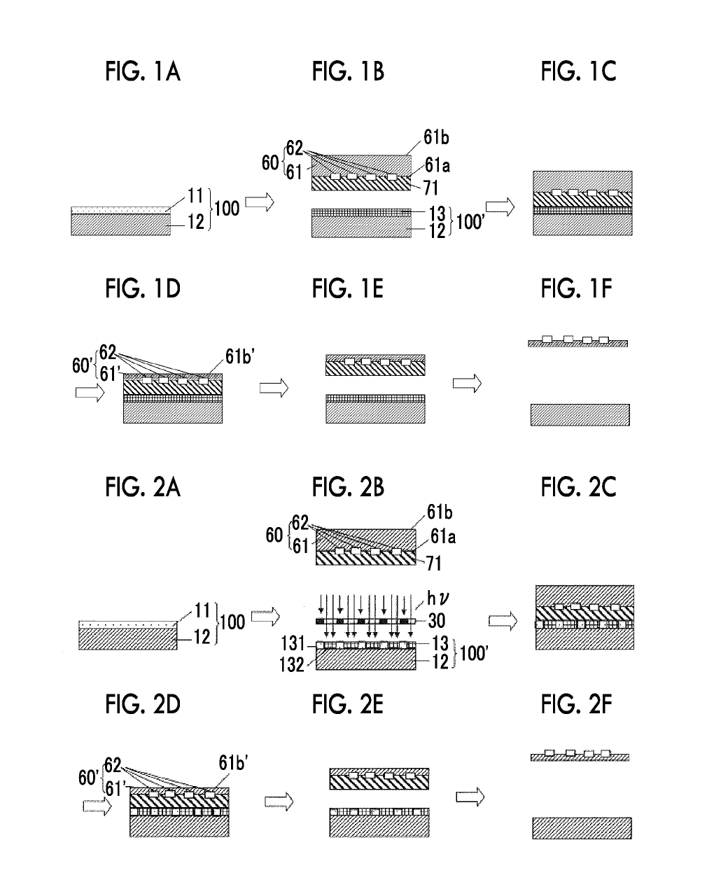

FIGS. 1A, 1B, 1C, 1D, 1E, and 1F are a schematic cross-sectional view illustrating the temporary adhesion between a carrier support and a device wafer, a schematic cross-sectional view showing a state in which the device wafer temporarily adhered to the carrier support becomes thinner, a schematic cross-sectional view showing a state in which the carrier support is peeled from the device wafer, and a schematic cross-sectional view showing a state after cleaning of the surface of the carrier support and the device wafer, respectively.

In an embodiment of the present invention, an adhesive support precursor 100 in which an adhesive layer precursor 11 is provided on a support 12 is prepared as shown in FIG. 1A.

An embodiment in which the adhesive support precursor 100 has a polymerizable compound and does not substantially include a solvent.

The adhesive layer precursor 11 can be formed by coating the adhesive layer precursor coating liquid by a spin coating method, a spraying method, a roller coating method, a flow coating method, a doctor coating method, a dipping method, or the like which is known in the related art, followed by drying (baking). Drying can be carried out by, for example, at 60° C. to 150° C. for 10 seconds to 2 minutes.

The thickness of the adhesive layer precursor 11 is, for example, in the range of 1 μm to 500 μm, preferably 1 μm to 100 μm, and more preferably 1 μm to 10 μm, but is not limited thereto.

The adhesive layer precursor 11 is converted to an adhesive layer 13 by controlling the polymerization rate in the adhesive layer precursor to, for example, 10% to 70% by the step of irradiation of actinic rays or radiation, or heat, as shown in FIG. 1B. The reaction rate of the polymerizable compound is preferably 20% to 60%, and more preferably 25% to 50%, from the viewpoints of adhesiveness and release peelability. By controlling the reaction rate within the above range, it is possible to satisfy both of strong adhesiveness while reducing the thickness of the device wafer as will be described later and release peelability during the separation of the device water.

The softening point of the adhesive layer of the present invention represents the softening point of the adhesive layer after the polymerizable compound of the adhesive layer precursor is polymerized. Further, as described later, in the case where an adhesive support 100 is adhered to a device wafer 60 with an adhesion body, followed by heating (irradiation of heat), the softening point of the adhesive layer represents the softening point of the adhesive layer after the heating.

In the case where the protective layer as will be described later is provided on a carrier substrate 12, the adhesive layer can be formed by applying (preferably coating) the adhesive support precursor onto the surface of the protective layer, followed by drying (baking). Drying can be carried out at 60° C. to 150° C. for 10 seconds to 2 minutes.

Next, the temporary adhesion between the adhesive support having a support and an adhesive layer, obtained as above, and a device wafer (member to be treated) having a protective layer, the reduction in the thickness of a device wafer, and the separation of the adhesive support from the device wafer will be described in detail.

As shown in FIG. 1B, the device wafer 60 (member to be treated) is formed by providing a plurality of device chips 62 on a surface 61a of a silicon substrate 61.

Here, the thickness of the silicon substrate 61 is, for example, in a range of 200 μm to 1,200 μm. The device chip 62 is preferably, for example, a metal structure, and the height is in a range of 10 μm to 100 μm.

In the case where a protective layer 71 is provided on a surface 61a, the protective layer can be formed by applying (preferably coating) the adhesive support precursor onto the surface of the protective layer, followed by drying (baking). Drying can be carried out at 60° C. to 150° C. for 10 seconds to 2 minutes. It is preferable that the protective layer 71 completely covers the device chip 62, and in the case where the height of the device chip is X μm and the thickness of the protective layer is Y μm, it is preferably represented by a formula of X+100≧Y>X.

The embodiment where the protective layer 71 completely covers the device chip 62 as described above is effective in the case of attempting to more reduce TTV (Total Thickness Variation) of a thin device wafer obtained by reducing the thickness of the device wafer 60 temporarily adhered by the adhesive support 100′ (that is, when attempting to more enhance the flatness of the thin device wafer).

That is, in the case of reducing the thickness of the device wafer 60 temporarily adhered by the adhesive support 100, the uneven profile of the device wafer 60, which is created by a plurality of device chips 62, tends to be transferred to the back surface 61b′ of the thin device wafer 60′, which may be a TTV increasing factor.

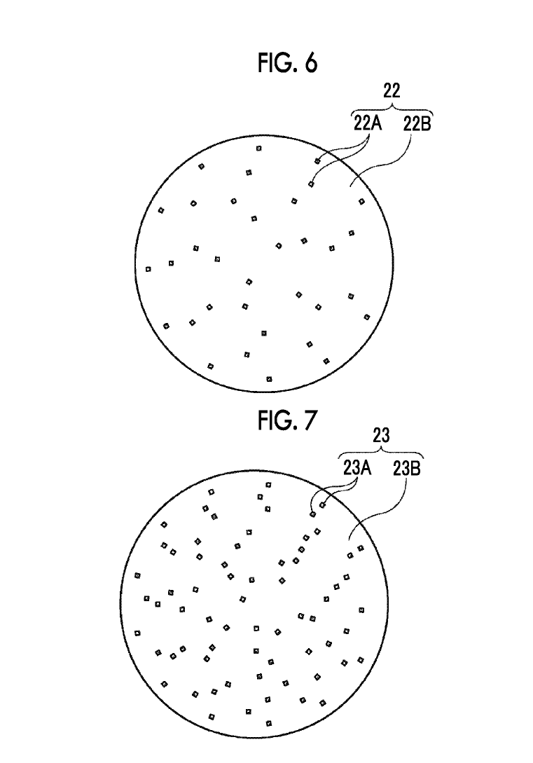

On the other hand, in the case of reducing the thickness of the protective layer-attached device wafer 60 temporarily adhered by the adhesive support 100′, as shown in FIG. 6B, a plurality of device chips 62 are protected by a protective layer and therefore, the uneven profile can be substantially eliminated on the contact surface of the protective layer-attached device wafer with the adhesive support 100′. Accordingly, even when such a protective layer-attached device wafer becomes thinner in the state of being supported by the adhesive support 100′, the profile attributable to a plurality of device chips 62 is less likely to be transferred to the back surface 61b of the protective layer-attached thin device wafer, as a result, the TTV of the finally obtained thin device wafer can be more reduced.

Next, in the case where a protective layer 71 is provided on a surface 61 a as shown in FIG. 1C, a protective layer 71 is pressed against the adhesive layer 13 of the adhesive support 100′. Thus, the protective layer 71 and the adhesive layer 13 are adhered to each other and thus, the adhesive support 100′ and the device wafer 60 are temporarily adhered to each other.

Furthermore, thereafter, if desired, the adhesion body of the adhesive support 100′ and the device wafer 60 may be heated (irradiated with heat), thereby making the adhesive layer more tough. Thus, since not only the anchor effect at the interface between the adhesive support and the member to be treated is accelerated but also the cohesion failure of the adhesive layer, which may likely occur when the device wafer 60 is subjected to a mechanical or chemical treatment as will described below, can be prevented, the adhesiveness of the adhesive support 100′ is increased, and in addition, the elastic modulus of the adhesive layer is improved, whereby the release peelability during the separation of the device wafer can also be improved.

The heating temperature in this case is preferably 50° C. to 300° C., more preferably 80° C. to 250° C., and still more preferably 80° C. to 220° C.

The heating time in this case is preferably 20 seconds to 10 minutes, more preferably 30 seconds to 5 minutes, and still more preferably 40 seconds to 3 minutes.

Next, a back surface 61b of the silicon substrate 61 is subjected to a mechanical or chemical treatment, specifically, a treatment for reducing the thickness of a film, such as grinding and chemical mechanical polishing (CMP) to reduce the thickness (for example, a thickness of 1 μm to 200 μm) of the silicon substrate 61, thereby obtaining a thin device wafer 60′, as shown in FIG. 1D.

Furthermore, as the mechanical or chemical treatment, after the treatment for reducing the thickness of a film, a treatment for forming a through hole (not shown) passing through the silicon substrate from the back surface 61b′ of the thin device wafer 60′ and forming a though-silicon electrode (not shown) in the through hole may be carried out, if desired.

Next, the surface 61a of the thin device wafer 60′ is dissociated from the adhesive layer 13 of the adhesive support 100′ as shown in FIG. 1E.

A method for the dissociation is not particularly limited and is preferably carried out by bringing the adhesive layer 13 into contact with the peeling solution as will be described later, and then, if desired, sliding the thin device wafer 60′ to the adhesive support 100′ and then pulling in the direction perpendicular to the device wafer from an edge of the thin device wafer 60′ while not carrying out the peeling.

<Peeling Solution>

Hereinafter, the peeling solution will be described in detail.

As the peeling solution, water and a solvent (organic solvent) can be used. Further, as the peeling solution, an organic solvent in which the protective layer 71 is dissolved is preferable. Examples of the organic solvent include an aliphatic hydrocarbon (hexane, heptane, Isopar E, H, and G (manufactured by Exxon Chemical Co., Ltd.), and the like), an aromatic hydrocarbon (toluene, xylene, and the like), a halogenated hydrocarbon (methylene dichloride, ethylene dichloride, triclene, monochlorobenzene, and the like), and a polar solvent. Examples of the polar solvent include alcohols (methanol, ethanol, propanol, isopropanol, 1-butanol, 1-pentanol, 1-hexanol, 1-heptanol, 1-octanol, 2-octanol, 2-ethyl-1-hexanol, 1-nonanol, 1-decanol, benzyl alcohol, ethylene glycol monomethyl ether, 2-ethoxyethanol, diethylene glycol monoethyl ether, diethylene glycol monohexyl ether, triethylene glycol monomethyl ether, propylene glycol monoethyl ether, propylene glycol monomethyl ether, polyethylene glycol monomethyl ether, polypropylene glycol, tetraethylene glycol, ethylene glycol monobutyl ether, ethylene glycol monobenzyl ether, ethylene glycol monophenyl ether, propylene glycol monophenyl ether, methyl phenyl carbinol, n-amyl alcohol, methylamyl alcohol, and the like), ketones (acetone, methyl ethyl ketone, ethyl butyl ketone, methyl isobutyl ketone, cyclohexanone, and the like), esters (ethyl acetate, propyl acetate, butyl acetate, amyl acetate, benzyl acetate, methyl lactate, butyl lactate, ethylene glycol monobutyl acetate, polyethylene glycol monomethyl ether acetate, diethylene glycol acetate, diethyl phthalate, butyl levulinate, and the like), and others (triethyl phosphate, tricresyl phosphate, N-phenylethanolamine, N-phenyldiethanolamine, N-methyldiethanolamine, N-ethyldiethanolamine, 4-(2-hydroxyethyl)morpholine, N,N-dimethylacetamide, N-methylpyrrolidone, and the like).

Furthermore, from the viewpoint of peelability, the peeling solution may include an alkali, an acid, and a surfactant. In the case of blending these components, the blending amounts are each preferably 0.1% by mass to 5.0% by mass with respect to the peeling solution.

In addition, from the viewpoint of the peelability, an embodiment of mixing two or more kinds of the organic solvents and water or an embodiment of mixing two or more kinds the alkalis, acids and surfactants is also preferable.

As the alkali, an inorganic alkali agent such as, for example, sodium tertiary phosphate, potassium tertiary phosphate, ammonium tertiary phosphate, sodium secondary phosphate, potassium secondary phosphate, ammonium secondary phosphate, sodium carbonate, potassium carbonate, ammonium carbonate, sodium hydrogen carbonate, potassium hydrogen carbonate, ammonium hydrogen carbonate, sodium borate, potassium borate, ammonium borate, sodium hydroxide, ammonium hydroxide, potassium hydroxide, and lithium hydroxide, or an organic alkali agent such as, for example, monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, pyridine, and tetramethylammonium hydroxide can be used. The alkali agents can be used singly or in combination of two or more kinds thereof.

As the acid, an inorganic acid such as hydrogen halide, sulfuric acid, nitric acid, phosphoric acid, and boric acid, or an organic acid such as methanesulfonic acid, ethanesulfonic acid, benzenesulfonic acid, p-toluenesulfonic acid trifluoromethanesulfonic acid, acetic acid, citric acid, formic acid, gluconic acid, lactic acid, oxalic acid, and tartaric acid can be used.

As the surfactant, an anionic, cationic, nonionic or amphoteric surfactant can be used. In this case, the content of the surfactant is preferably 1% by mass to 20% by mass, and more preferably 1% by mass to 10% by mass, with respect to the total amount of the aqueous alkali solution.

By controlling the content of the surfactant to the above range, the peelability of the thin device wafer 60′ from the adhesive support 100′ tends to be further improved.

The anionic surfactant is not particularly limited and examples thereof include fatty acid salts, abietates, hydroxyalkane sulfonates, alkane sulfonates, dialkylsulfosuccinates, linear alkylbenzene sulfonates, branched alkylbenzene sulfonates, alkylnaphthalene sulfonates, alkyldiphenyl ether(di)sulfonates, alkylphenoxy polyoxyethylene alkyl sulfonates, polyoxyethylene alkylsulfophenyl ether salts, N-alkyl-N-oleyltaurine sodium salts, N-alkylsulfosuccinic acid monoamide disodium salts, petroleum sulfonates, sulfated castor oil, sulfated beef tallow oil, sulfate ester salts of fatty acid alkyl ester, alkyl sulfate ester salts, polyoxyethylene alkyl ether sulfate ester salts, fatty acid monoglyceride sulfate ester salts, polyoxyethylene alkyl phenyl ether sulfate ester salts, polyoxyethylene styryl phenyl ether sulfate ester salts, alkyl phosphate ester salts, polyoxyethylene alkyl ether phosphate ester salts, polyoxyethylene alkyl phenyl ether phosphate ester salts, partially saponified products of styrene-maleic anhydride copolymers, partially saponified products of olefin-maleic anhydride copolymers, and naphthalene sulfonate foimalin condensates. Among these, alkylbenzene sulfonates, alkylnaphthalene sulfonates, and alkyldiphenyl ether(di)sulfonates are particularly preferably used.

The cationic surfactant is not particularly limited and cationic surfactants known in the related art can be used. Examples of the cationic surfactant include alkylamine salts, quaternary ammonium salts, alkylimidazolinium salts, polyoxyethylene alkyl amine salts, and polyethylene polyamine derivatives.

The nonionic surfactant is not particularly limited and examples thereof include polyethylene glycol type higher alcohol ethylene oxide adducts, alkylphenol ethylene oxide adducts, alkylnaphthol ethylene oxide adducts, phenol ethylene oxide adducts, naphthol ethylene oxide adducts, fatty acid ethylene oxide adducts, polyhydric alcohol fatty acid ester ethylene oxide adducts, higher alkylamine ethylene oxide adducts, fatty acid amide ethylene oxide adducts, ethylene oxide adducts of fat, polypropylene glycol ethylene oxide adducts, dimethylsiloxane-ethylene oxide block copolymers, dimethylsiloxane-(propylene oxide-ethylene oxide) block copolymers, fatty acid esters of polyhydric alcohol type glycerol, fatty acid esters of pentaerythritol, fatty acid esters of sorbitol and sorbitan, fatty acid esters of sucrose, alkyl ethers of polyhydric alcohols and fatty acid amides of alkanolamines. Among these, those having an aromatic ring and an ethylene oxide chain are preferable, and alkyl-substituted or unsubstituted phenol ethylene oxide adducts and alkyl-substituted or unsubstituted naphthol ethylene oxide adducts are more preferable.

The amphoteric surfactant is not particularly limited and examples thereof include amine oxides such as alkyldimethylamine oxide, betaines such as alkyl betaine, and amino acids such as sodium salts of alkylamino fatty acids. In particular, alkyldimethylamine oxide which may have a substituent, alkyl carboxyl betaine which may have a substituent, and alkyl sulfo betaine which may have a substituent are preferably used. Specifically, the compounds represented by Formula (2) described in paragraph No. “0256” of JP2008-203359A, the compounds represented by Formulae (I), (II), and (VI) described in paragraph No. “0028” of JP2008-276166A, and the compounds described in paragraph Nos. “0022” to “0029” of JP2009-47927A can be used.

The peeling solution can also contain an additive such as a defoaming agent and a water softener, if desired.

Next, it is possible to obtain a thin device wafer by removing a protective layer 71 on a device wafer surface 61a, as shown in FIG. 1F. Examples of a method for removing the protective layer 71 include a method in which the protective layer 71 is removed in the form of a film itself, a method in which the protective layer 71 is dissolved in an aqueous solution or an organic solvent and removed, and a method in which the protective layer 71 is decomposed and vaporized by irradiation with actinic rays or radiation, or heat, and a method in which the protective layer 71 is dissolved in an organic solvent and removed can be preferably used. As the aqueous solution or organic solvent, any solution which is capable of dissolving the protective layer and removing it can be used, and specifically, the peeling solution as described above, capable of dissolving the protective layer and removing it, can be preferably used, with a more preferred embodiment being the same as for the peeling solution.

After the thin device wafer 60′ is dissociated from the adhesive support 100′, if desired, the thin device wafer 60′ is subjected to various known treatments to produce a semiconductor device having the thin device wafer 60′.

Furthermore, as shown in FIG. 1F, the support can be regenerated by removing the adhesive layer on the support. Examples of a method for removing the adhesive layer include a physical removal method such as a method in which the adhesive layer is removed in the form a film itself, a method in which the adhesive layer is removed by a brush or by spraying ultrasonic waves, ice particles, or aerosol; and a chemical removal method such as a method in which the adhesive layer is dissolved in an aqueous solution or an organic solvent and removed, and a method in which the adhesive layer is decomposed and vaporized by irradiation with actinic rays or radiation, or heat, but existing cleaning methods in the related art can be used.

For example, in the case of using a silicon substrate, existing methods for cleaning silicon wafers in the related art can be used, and examples of the aqueous solution or organic solvents that can be used in the case of chemical removal include strong acids, strong bases, strong oxidizing agents, or a mixture thereof, specifically, acids such as sulfuric acid, hydrochloric acid, hydrofluoric acid, nitric acid, and organic acids, bases such as tetramethylammonium, ammonium, and organic bases, oxidizing agents such as hydrogen peroxide, or a mixture of ammonia and hydrogen peroxide, a mixture of hydrochloric acid and aqueous hydrogen peroxide, a mixture of sulfuric acid and aqueous hydrogen peroxide, a mixture of hydrofluoric acid and aqueous hydrogen peroxide, and a mixture of hydrofluoric acid and ammonium fluoride.

From the viewpoint of adhesiveness in the case of using the regenerated support, it is preferable to use a support cleaning liquid.

It is preferable that the support cleaning liquid contains an acid having a pKa of less than 0 and hydrogen peroxide. The acid having a pKa of less than 0 is selected from inorganic acids such as hydrogen iodide, perchloric acid, hydrogen bromide, hydrogen chloride, nitric acid, and sulfuric acid, and organic acids such as alkylsulfonic acid and arylsulfonic acid. From the viewpoint of cleaning of the adhesive layer on the support, the inorganic acids is preferable and sulfuric acid is most preferable.

As the hydrogen peroxide, 30 w/v % hydrogen peroxide can be preferably used, and the mixing ratio of the strong acid to the 30 w/v % hydrogen peroxide is preferably 0.1:1 to 100:1, more preferably 1:1 and 10:1, and most preferably 3:1 to 5:1.

Furthermore, the method for manufacturing a laminate and the method for producing a semiconductor device of the present invention may also be carried out as shown in an example of FIGS. 2A to 2F.

FIGS. 2A to 2F are each a view showing an example in which an adhesive layer precursor is irradiated with radiation through a photomask in a halftone dot shape to separately form a weakly adhesive region and a strongly adhesive region. In the schemes shown in FIGS. 1 and 2, the polymerization of the compounds is in progress on the whole surface, or there is only a difference in polymerizable compounds are uniformly polymerized and the other steps are the same.

In the method shown in FIG. 2, the polymerization rate of the polymerizable compound of the weakly adhesive region is set to preferably 50% to 100%, and more preferably 70% to 100%. On the other hand, the polymerization rate of the polymerizable compound of the strongly adhesive region is preferably 0% to 50%, and more preferably 0% to 20%.

Examples of carrying out non-uniform polymerization include a pattern exposure using a mask. A strongly adhesive region 131 and a weakly adhesive region 132 are provided by the pattern exposure for exposing with light hv, using the mask 30, and each of the areas and the shapes of the light-transmitting region and the light-shielding region in the mask 30 can be controlled in an order of micron to nanometer. Thus, since each of the areas and the shapes of the strongly adhesive region 131 and the weakly adhesive region 132 formed in the adhesive layer 13 of the adhesive support 100 can be finely controlled by the pattern exposure, the adhesiveness of the adhesive layer as a whole can be controlled in a high accuracy and easily to an adhesive property in such a degree that not only the silicon substrate 61 of the device wafer 60 is temporarily supported more firmly and easily but also the temporary support for the silicon substrate of the thin display wafer 60′ is more easily released while not damaging the thin display wafer 60′. The weakly adhesive region means a region having low adhesiveness as compared with the strongly adhesive region, and includes a region not having adhesiveness (that is, a “non-adhesive region”). Similarly, the strongly adhesive region means a region having high adhesiveness as compared with the weakly adhesive region.

Incidentally, the exposure may be pattern exposure using a mask as well as selective exposure by drawing using electron beams or the like. In addition, for example, the mask 30 used for the pattern exposure may be a binary mask or a halftone mask.

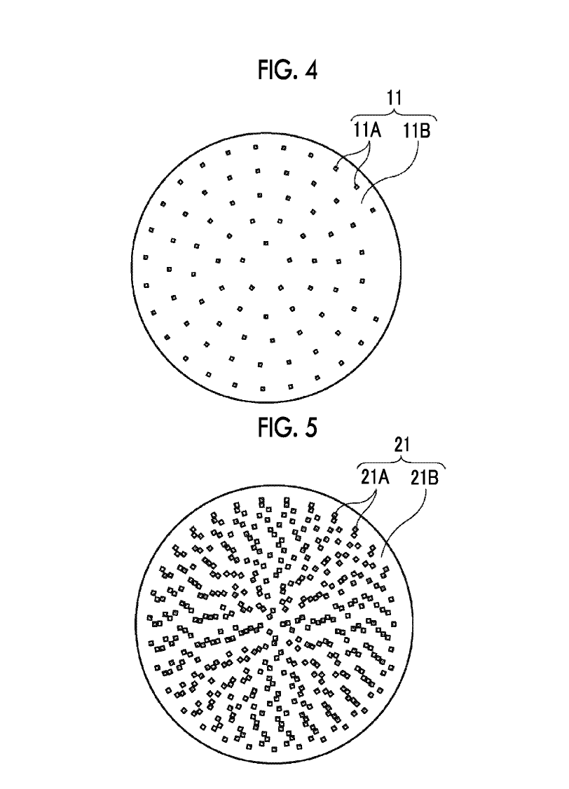

FIG. 4 is an example of a schematic top view of an adhesive support.

As shown in FIG. 4, in an embodiment of the present invention, the adhesive layer 11 in the adhesive support may be an adhesive layer in which a strongly adhesive region 11A as a halftone dot area and a weakly adhesive region 11B as a peripheral area surrounding the halftone dot area are formed. Further, the weakly adhesive region 11B and the strongly adhesive region 11A are arranged at an approximately equal interval over the entire surface of the adhesive layer 11.

The weakly adhesive region 11A and the strongly adhesive region 11B are formed by a method in which an adhesive layer the adhesiveness increases or decreases by irradiation with actinic rays or radiation is subjected to pattern exposure for a halftone dot image.

The pattern exposure for a halftone dot image is preferably exposure in which the halftone dot area in a halftone dot shape in the adhesive layer is used as a strongly adhesive region and a peripheral area surrounding the halftone dot area is used as a weakly adhesive region.

The area of the halftone dot area is preferably 0.0001 mm² to 9 mm², preferably 0.1 mm² to 4 mm², and most preferably 0.01 mm² to 2.25 mm².

The form of the halftone dot shape in the adhesive layer is also not particularly limited and for example, as shown in the schematic top view of FIG. 5, the adhesive layer may be an adhesive layer 21 having strongly adhesive region 21A and the weakly adhesive region 21B and containing a halftone dot shape in which the strongly adhesive region 21A is formed so as to form a radiation shape extending toward the outside from the center.

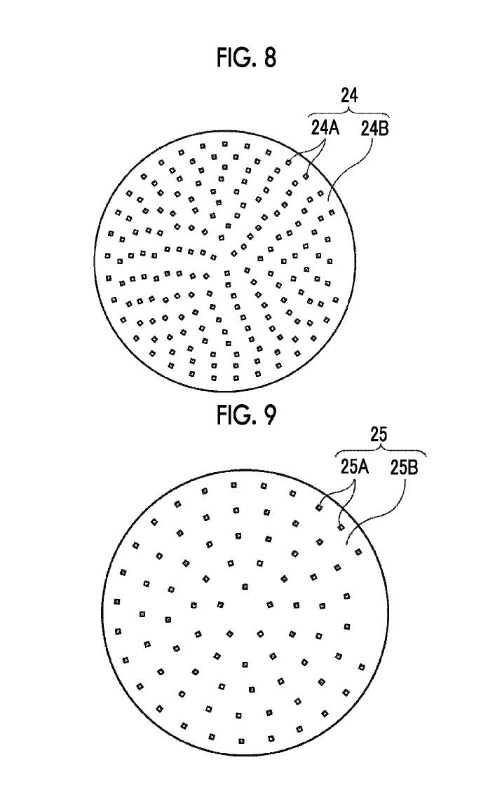

Furthermore, as shown in the schematic top views of FIGS. 6, 7, and 8, the adhesive layers may be respectively adhesive layers 22, 23, and 24, having strongly adhesive regions 22A, 23A, and 24A and weakly adhesive regions 22B, 23B, and 24B, and containing a halftone dot shape in which the area ratio of the strongly adhesive layers 22A, 23A, and 24A is less than the area ratio of the strongly adhesive region 21A in the adhesive layer 21 (see FIG. 5), and is formed so as to form a radiation shape extending toward the outside from the center.

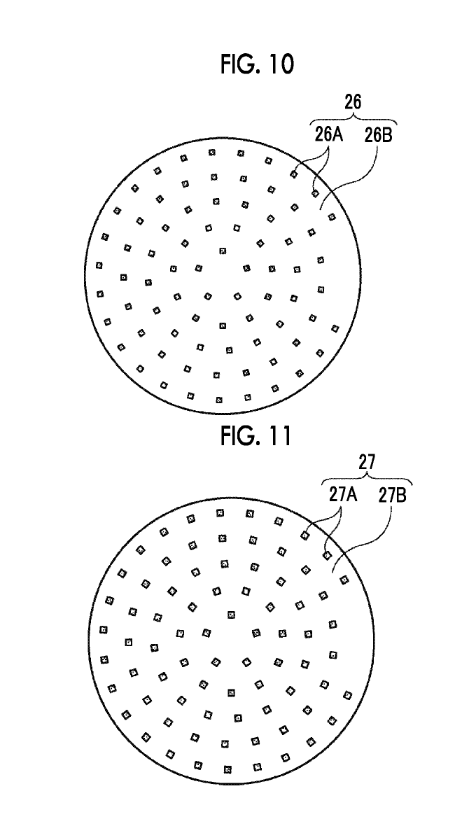

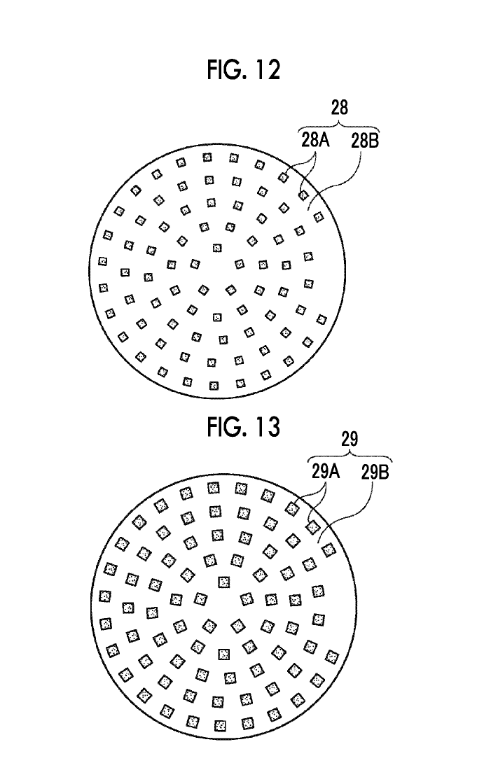

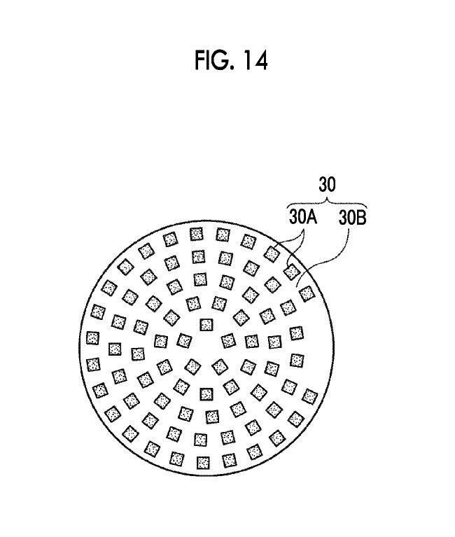

In addition, the size of the strongly adhesive region in the halftone dot shape is not particularly limited and the adhesive layers may be adhesive layers 25, 26, 27, 28, 29, and 30, having strongly adhesive regions 25A, 26A, 27A, 28A, 29A, and 30A, as shown in FIGS. 9 to 14, and weakly adhesive regions 25B, 26B, 27B, 28B, 29B, and 30B, in which the size of the changed adhesive regions 25A, 26A, 27A, 28A, 29A, and 30A are modified from the strongly adhesive region 11A in the adhesive layer 11 (see FIG. 4).

Moreover, after forming the laminate of the present invention, the adhesive and the release peelability can be improved by controlling the polymerization rate of the polymerizable compound in the strongly adhesive region by a step of further irradiating actinic rays or radiation, or heat to 50% to 100%.

Next, an embodiment in the related art will be described.

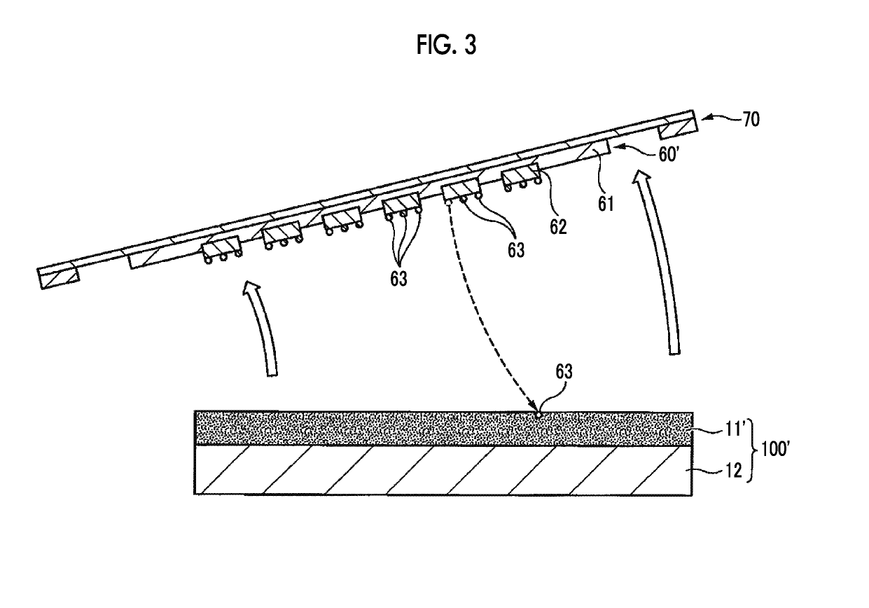

FIG. 3 is a schematic cross-sectional view illustrating the release of a temporary adhering state between an adhesive support and a device wafer in the related art.

In the embodiment in the related art, as shown in FIG. 3, except for using as the adhesive support, an adhesive support 100′ having an adhesive layer 11′ formed from a temporary adhesive in the related art provided on a carrier substrate 12, the temporary adhesion of the adhesive support 100′ to a device wafer and the treatment for reducing the thickness of a film of the silicon substrate in the device wafer are carried out by the same procedures as described with reference to FIGS. 1A and 1B, and then a thin device wafer 60′ is peeled from the adhesive support 100′ by the same procedure as described above.

However, according to the temporary adhesive in the related art, it is difficult to temporarily support a member to be treated with a strongly adhesive force and to easily release the temporary support for the member processed while not damaging the member processed. For example, when a temporary adhesive having a high adhesiveness out of the temporary adhesives in the related art is adopted in order to perform sufficiently temporary adhesion between a device wafer and a carrier substrate, the temporary adhesion between the device wafer and the carrier substrate tends to become too strong. Thus, for example, as shown in FIG. 3, in the case where a tape (for example, a dicing tape) 70 is adhered on a back surface of a thin device wafer 60′ and the thin device wafer 60′ is peeled from the adhesive support 100′ for the purpose of releasing such a strong temporary adhesion, an inconvenience is apt to occur in that a device chip 62 is damaged, for example, a structure 63 is dissociated from the device chip 62 having the structure 63 provided thereon.

On the other hand, when a temporary adhesive having a low adhesiveness out of the temporary adhesives in the related art is adopted, although the temporary support for the member processed can be easily released, the temporary adhesion between a device wafer and a carrier substrate is too weak and thus, has a problem in that the device wafer cannot be firmly supported by the carrier substrate.

However, the laminate of the present invention exhibits sufficient adhesiveness, and the temporary adhesion between the device wafer 60 and the adhesive support 100 can be easily released particularly by bringing the adhesive layer 11 into contact with the peeling solution. That is, by the laminate of the present invention, the device wafer 60 can be provided with a temporary support with a strongly adhesive force and the temporary support for the thin device wafer 60′ can be easily released while not damaging the thin device wafer 60′.

The method for forming a laminate and the method for producing a semiconductor device of the present invention are not limited to the embodiments as described above, and appropriate modifications, improvements, and the like can be made therein.

In the embodiments as described above, the adhesive layer formed from the adhesive layer precursor of the present invention is provided on the support to constitute the adhesive support before the temporary adhesion of a device wafer, but the adhesive layer may be formed on a member to be treated, for example, a device wafer and then the member to be treated having the adhesive layer provided thereon may be temporarily adhered to the support.

In addition, in the embodiments as described above, the adhesive layer has a single-layer structure, but the adhesive layer may have a multilayer structure. Examples of the method for forming an adhesive layer having a multilayer structure include a method of stepwise coating a temporary adhesive by the above-described method in the related art before irradiation of actinic rays, radiation, or heat, and a method of coating a temporary adhesive by the above-described method in the related art after irradiation of actinic rays, radiation, or heat.

In the embodiments as described above, as the member to be treated which is supported by the adhesive support, a silicon substrate is exemplified, but the member to be treated is not limited thereto and may be any member to be treated which may be subjected to a mechanical or chemical treatment in the method for producing a semiconductor device.

For example, examples of the member to be treated include a compound semiconductor substrate, and specific examples of the compound semiconductor substrate include an SiC substrate, an SiGe substrate, a ZnS substrate, a ZnSe substrate, a GaAs substrate, an InP substrate, and a GaN substrate.

Furthermore, in the embodiments as described above, as the mechanical or chemical treatment coated on the silicon substrate which is supported by the adhesive support, a treatment for reducing the thickness of the silicon substrate or a treatment for forming a through-silicon electrode is exemplified, but the treatment is not limited thereto and may be any treatment required in the method for producing a semiconductor device.

The shape, the dimension, the number, the arrangement positions, and the like of the device chip in the device wafer are arbitrary and not limited as long as the present invention can be achieved.

### EXAMPLES

The present invention will be described more specifically with reference to Examples, but the present invention is not limited thereto as long as the gist of the present invention is not deviated. Here, “part(s)” and “%” are on the basis of mass unless otherwise specified.

<Formation of Support Having Adhesive Layer>

The adhesive layer precursor (composition for forming an adhesive layer) as described below was coated on a 200-mm Si wafer by a spin coater and then baked at 120° C. for 30 seconds to form a wafer having provided thereon an adhesive precursor having a thickness of 0.2 μm. Thereafter, light irradiation was carried out by using a mask (area ratio of the light-shielding area: 3%) so as to form a halftone dot region as in FIG. 4 using light at a wavelength of 365 nm, by means of a heating or UV Exposure Apparatus (LC8 manufactured by Hamamatsu Photonics K. K.) using a hot plate under the polymerization conditions shown in the following table (bake conditions or exposure doses), thereby forming a support having an adhesive layer.

<Composition of Adhesive Layer Precursor>
Radically polymerizable monomer (b-1) described in the following table parts by mass described in the following table
Radically polymerizable monomer (b-1′) described in the following table parts by mass described in the following table
Photo-radical polymerization initiator (b-2) described in the following table parts by mass described in the following table
Thermo-radical polymerization initiator (b-3) described in the following table parts by mass described in the following table
Polymer compound (b-4) described in the following table parts by mass described in the following table
Polymerization inhibitor (p-methoxyphenol, manufactured by Tokyo Chemical Industry Co., Ltd.) 0.008 parts by mass
Surfactant (PF6320, manufactured by OMNOVA) 0.032 parts by mass
Solvent (propylene glycol monopropyl ether acetate) 94.96 parts by mass

TABLE 1

| | Material | | | | | | | | | | | |
|---|---|---|---|---|---|---|---|---|---|---|---|---|
| | | | | | | | | | Polymer compound | | | |
| | | | | | | | | | (b-4) | | | |
| Support | | | | | Photo-radical | | Thermo-radical | | Compound | | | |
| having | Polymerizable | | Polymerizable | | polymerization | | polymerization | | containing | | | |
| adhesive | monomer (b-1) | | monomer (b-1′) | | initiator (b-2) | | initiator (b-3) | | fluorine atom | | Polymerization | Softening |
| layer | Type | Weight | Type | Weight | Type | Weight | Type | Weight | Type | Weight | conditions | point (° C.) |
| (1) | b-1-1 | 5.0 | — | 0.0 | — | 0 | — | 0 | — | 0 | 180° C. | 250° C. or |
| | | | | | | | | | | | 3 minutes | higher |
| (2) | b-1-2 | 5.0 | — | 0.0 | — | 0 | — | 0 | — | 0 | 180° C. | 250° C. or |
| | | | | | | | | | | | 3 minutes | higher |
| (3) | b-1-3 | 5.0 | — | 0.0 | — | 0 | — | 0 | — | 0 | 180° C. | 250° C. or |
| | | | | | | | | | | | 3 minutes | higher |
| (4) | b-1-4 | 5.0 | — | 0.0 | — | 0 | — | 0 | — | 0 | 180° C. | 250° C. or |
| | | | | | | | | | | | 3 minutes | higher |
| (5) | b-1-5 | 5.0 | — | 0.0 | — | 0 | — | 0 | — | 0 | 180° C. | 250° C. or |
| | | | | | | | | | | | 3 minutes | higher |
| (6) | b-1-6 | 5.0 | — | 0.0 | — | 0 | — | 0 | — | 0 | 180° C. | 250° C. or |
| | | | | | | | | | | | 3 minutes | higher |
| (7) | b-1-7 | 5.0 | — | 0.0 | — | 0 | — | 0 | — | 0 | 180° C. | 250° C. or |
| | | | | | | | | | | | 3 minutes | higher |
| (8) | b-1-8 | 5.0 | — | 0.0 | — | 0 | — | 0 | — | 0 | 180° C. | 250° C. or |
| | | | | | | | | | | | 3 minutes | higher |
| (9) | b-1-9 | 5.0 | — | 0.0 | — | 0 | — | 0 | — | 0 | 180° C. | 250° C. or |
| | | | | | | | | | | | 3 minutes | higher |
| (10) | b-1-5 | 4.8 | b-1-7 | 0.3 | — | 0 | — | 0 | — | 0 | 180° C. | 250° C. or |
| | | | | | | | | | | | 3 minutes | higher |
| (11) | b-1-5 | 4.8 | b-1-8 | 0.3 | — | 0 | — | 0 | — | 0 | 180° C. | 250° C. or |
| | | | | | | | | | | | 3 minutes | higher |
| (12) | b-1-5 | 4.8 | b-1-9 | 0.3 | — | 0 | — | 0 | — | 0 | 180° C. | 250° C. or |
| | | | | | | | | | | | 3 minutes | higher |
| (13) | b-1-5 | 4.8 | b-1-10 | 0.3 | — | 0 | — | 0 | — | 0 | 180° C. | 250° C. or |
| | | | | | | | | | | | 3 minutes | higher |
| (14) | b-1-5 | 4.0 | b-1-8 | 1.0 | — | 0 | — | 0 | — | 0 | 180° C. | 250° C. or |
| | | | | | | | | | | | 3 minutes | higher |
| (15) | b-1-5 | 2.5 | b-1-8 | 2.5 | — | 0 | — | 0 | — | 0 | 180° C. | 250° C. or |
| | | | | | | | | | | | 3 minutes | higher |
| (16) | b-1-5 | 4.8 | — | 0.0 | b-2-1 | 0.25 | — | 0 | — | 0 | 2,000 mJ/cm² | 250° C. or |
| | | | | | | | | | | | | higher |
| (17) | b-1-8 | 4.8 | — | 0.0 | b-2-1 | 0.25 | — | 0 | — | 0 | 2,000 mJ/cm² | 250° C. or |
| | | | | | | | | | | | | higher |
| (18) | b-1-5 | 2.4 | b-1-8 | 2.4 | b-2-1 | 0.25 | — | 0 | — | 0 | 2,000 mJ/cm² | 250° C. or |
| | | | | | | | | | | | | higher |
| (19) | b-1-5 | 4.8 | — | 0.0 | b-2-2 | 0.25 | — | 0 | — | 0 | 2,000 mJ/cm² | 250° C. or |
| | | | | | | | | | | | | higher |
| (20) | b-1-8 | 4.8 | — | 0.0 | b-2-2 | 0.25 | — | 0 | — | 0 | 2,000 mJ/cm² | 250° C. or |
| | | | | | | | | | | | | higher |
| (21) | b-1-5 | 2.4 | b-1-8 | 2.4 | b-2-2 | 0.25 | — | 0 | — | 0 | 2,000 mJ/cm² | 250° C. or |
| | | | | | | | | | | | | higher |
| (22) | b-1-5 | 4.8 | — | 0.0 | — | 0 | b-3-1 | 0.25 | — | 0 | 150° C. | 250° C. or |
| | | | | | | | | | | | 3 minutes | higher |
| (23) | b-1-8 | 4.8 | — | 0.0 | — | 0 | b-3-1 | 0.25 | — | 0 | 150° C. | 250° C. or |
| | | | | | | | | | | | 3 minutes | higher |
| (24) | b-1-5 | 2.4 | b-1-8 | 2.4 | — | 0 | b-3-1 | 0.25 | — | 0 | 150° C. | 250° C. or |
| | | | | | | | | | | | 3 minutes | higher |
| (25) | b-1-5 | 3.8 | — | 0.0 | — | 0 | b-3-1 | 0.25 | b-4-2 | 0.95 | 150° C. | 250° C. or |
| | | | | | | | | | | | 3 minutes | higher |
| (26) | b-1-8 | 3.8 | — | 0.0 | — | 0 | b-3-1 | 0.25 | b-4-1 | 0.95 | 150° C. | 250° C. or |
| | | | | | | | | | | | 3 minutes | higher |
| (27) | b-1-5 | 1.9 | b-1-8 | 1.9 | — | 0 | b-3-1 | 0.25 | b-4-2 | 0.95 | 150° C. | 250° C. or |
| | | | | | | | | | | | 3 minutes | higher |
| (28) | b-1-5 | 4.5 | — | 0.0 | — | 0 | — | 0 | b-5-1 | 0.5 | 180° C. | 250° C. or |
| | | | | | | | | | | | 3 minutes | higher |
| (29) | b-1-7 | 4.5 | — | 0.0 | — | 0 | — | 0 | b-5-1 | 0.5 | 180° C. | 250° C. or |
| | | | | | | | | | | | 3 minutes | higher |
| (30) | b-1-8 | 4.5 | — | 0.0 | — | 0 | — | 0 | b-5-1 | 0.5 | 180° C. | 250° C. or |
| | | | | | | | | | | | 3 minutes | higher |
| (1) for | b-1-11 | 5.0 | — | 0.0 | — | 0 | — | 0 | — | 0 | 180° C. | -23° C. |
| Comparative | | | | | | | | | | | 3 minutes | |
| Example | | | | | | | | | | | | |
| (2) for | b-1-12 | 5.0 | — | 0.0 | — | 0 | — | 0 | — | 0 | 180° C. | 70° C. |
| Comparative | | | | | | | | | | | 3 minutes | |
| Example | | | | | | | | | | | | |
| (3) for | b-1-12 | 5.0 | — | 0.0 | — | 0 | — | 0 | — | 0 | 180° C. | 120° C. |
| Comparative | | | | | | | | | | | 3 minutes | |
| Example | | | | | | | | | | | | |
| (4) for | None | | | | | | | | | | | |
| Comparative | | | | | | | | | | | | |
| Example | | | | | | | | | | | | |

The softening point of the adhesive layer was measured with a viscoelasticity measuring apparatus Rhosol-G1000 (manufactured by UBM Co., Ltd.). Specifically, the softening point of the adhesive layer was measured as a temperature at which the loss tangent (tans) is maximized using a viscoelasticity measuring apparatus under a constant temperature rising conditions. In Examples, the temperature rising rate was set to 5° C./min and the temperature of the adhesive layer was raised from −100° C. to 250° C. by using a viscoelasticity measuring apparatus Rheosol-G5000, and the strain at a strain angle of 0.05 degrees was measured at a cycle of 1 Hz. In the case where a peak at a loss tangent (tan δ) up to 250° C. did not appear, the softening point was set to 250° C. or higher.

The compounds described in Table 1 are as follows.

[Polymerizable Monomer (b-1)]

(b-1-1) A-TMMT (manufactured by Shin-Nakamura Chemical Industry Co., Ltd.)

(b-1-2) A-9300 (manufactured by Shin-Nakamura Chemical Industry Co., Ltd.)

(b-1-3) Light Acrylate TMP-A (manufactured by Kyoeisha Chemical Co., Ltd.)

(b-1-4) AD-TMP (manufactured by Shin-Nakamura Chemical Industry Co., Ltd.)

(b-1-5) A-DPH (manufactured by Shin-Nakamura Chemical Industry Co., Ltd.)

(b-1-6) A-TMM-3 (manufactured by Shin-Nakamura Chemical Industry Co., Ltd.)

(b-1-7) RS-76-E (fluorine-based monomer manufactured by DIC Corporation)

(b-1-8) RS-72-K (fluorine-based monomer manufactured by DIC Corporation)

(b-1-9) OPTOOL DAC-HP (fluorine-based monomer manufactured by Daikin Industry Co., Ltd.)

(b-1-10) X-22-164 (silicon-based monomer manufactured by Shin-Etsu Chemical Co., Ltd., bifunctional monomer)

(b-1-11 for Comparative Example) A-600 (manufactured by Shin-Nakamura Chemical Industry Co., Ltd.)

(b-1-12 for Comparative Example) A-NPG (manufactured by Shin-Nakamura Chemical Industry Co., Ltd.)

(b-1-13 for Comparative Example) A-TMPT-9 EO (manufactured by Shin-Nakamura Chemical Industry Co., Ltd.)

The compounds described in Table 1 are as follows.

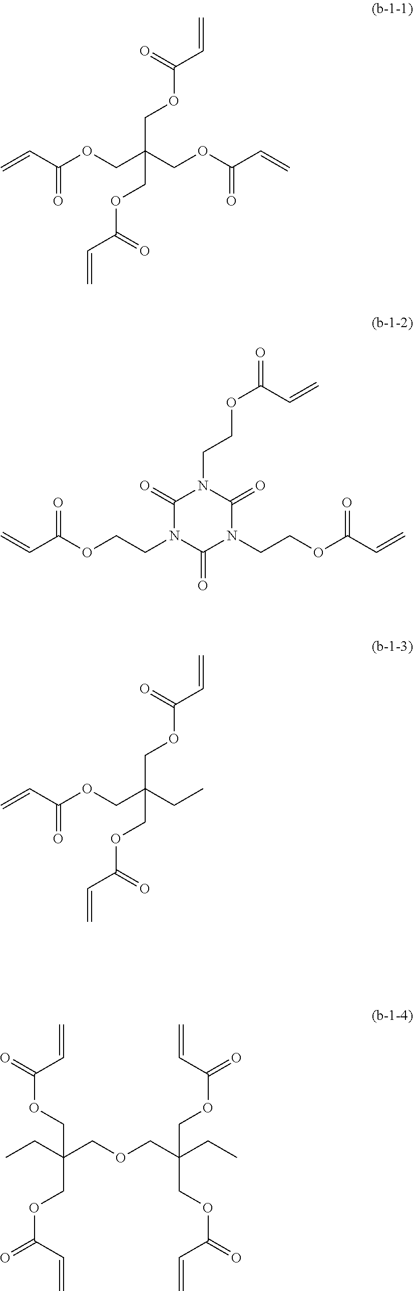

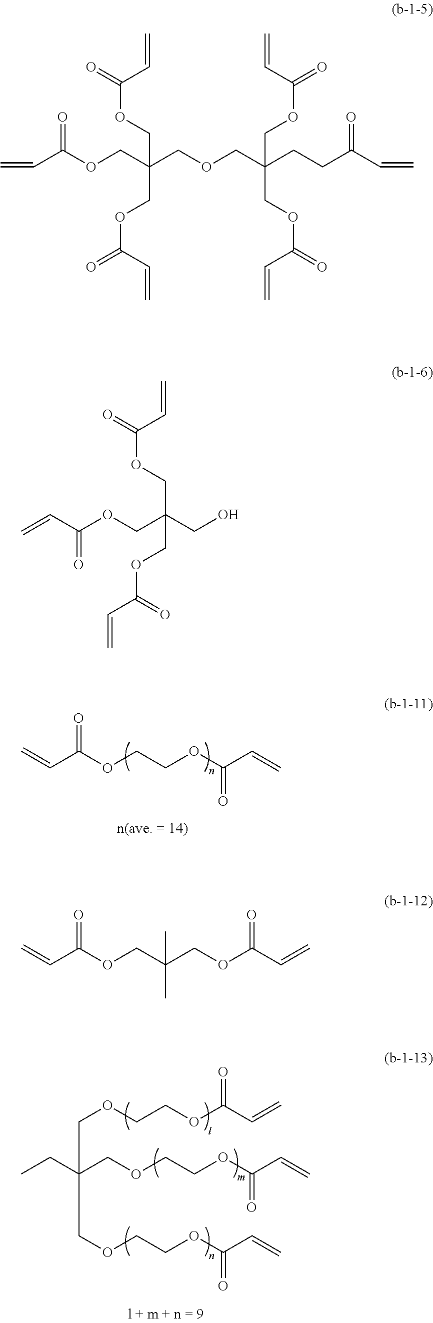

[Photo-Radical Polymerization Initiator (b-2)]

(b-2-1) IRGACURE OXE 02 (manufactured by BASF Corporation)

(b-2-2) n-1919 (manufactured by AEKA)

[Thermo-Radical Polymerization Initiator (b-3)]

(b-3-1) PERBUTYL Z (manufactured by NOF Co., Ltd., tert-butylperoxybenzoate, decomposition temperature (10-hour half-life temperature=104° C.))

[Thermo-Radical Polymerization Initiator (b-4)] (b-4-1) Methyl methacrylate/styrene copolymerized resin, ESTYRENE MS600 (manufactured by Nippon Steel & Sumikin Chemical Co., Ltd.)

(b-4-2) Polymethyl methacrylate (manufactured by Aldrich, Mw: 120,000)

[Compound (b-5) Containing Fluorine Atom]

(b-5-1) DAIFREE FB-962 (manufactured by Daikin Industries Co., Ltd.)

<Manufacture of Member to be Treated>

The composition for forming a protective layer described in the following table was coated on a 200 mm Si wafer to which a Cu-based metal structure having a height of 10 μm had been attached, using a spin coater, followed by carrying out the baking once or twice under the conditions described in the following table to form a wafer provided with a protective layer having a thickness of 20 μm.

The kind and the like of the polymer compound were changed as shown in the following table to form a wafer provided with another protective layer.

The softening point of the protective layer was measured in the same manner as for the adhesive layer.

<Composition of Composition 1 for Forming Protective Layer>

The resin components described in the following Table 2 The amount described in the following table

The solvent described in the following Table 2 The amount described in the following table

TABLE 2

| Member to be | Composition for forming protective layer | | | | | |
|---|---|---|---|---|---|---|
| treated having | Resin component | | Solvent | | Bake | Softening |
| protective layer | Type | Weight | Type | Weight | conditions | point |
| (1) | C-1-1 | 25.0 | C-2-1 | 75.0 | 100° C. 5 min | 240° C. |
| | | | | | 250° C. 10 min | |
| (2) | C-1-2 | 23.0 | C-2-2 | 77.0 | 130° C. 5 min | 250° C. |
| | | | | | 190° C. 25 min | |
| (3) | C-1-3 | 30.0 | C-2-3 | 70.0 | 140° C. 15 min | 99° C. |
| (4) | C-1-4 | 25.0 | C-2-4 | 75.0 | 100° C. 5 min | 135° C. |
| | | | | | 150° C. 10 min | |
| (5) | C-1-1 | 24.75 | C-2-1 | 75.0 | 100° C. 5 min | 240° C. |
| | C-3-1 | 0.25 | | | 250° C. 10 min | |
| (6) | C-1-3 | 29.7 | C-2-3 | 70.0 | 140° C. 15 min | 135° C. |
| | C-3-1 | 0.3 | | | | |
| (1) for | None | | | | | |
| Comparative | | | | | | |
| Example | | | | | | |

The compounds described in Table 2 are as follows.

[Polymer Compound]

(C-1-1) Ultrason E6020P (manufactured by BASF, a polyethersulfone resin)

(C-1-2) PCZ-300 (manufactured by Mitsubishi Gas Chemical Co., Ltd, polycarbonate resin)

(C-1-3) ESTYRENE MS200NT (manufactured by Nippon Steel Chemical Co., Ltd., a polystyrene resin)

(C-1-4) TOPAS5013 (manufactured by Polyplastics Co., Ltd., hydrocarbon resin)

[Compound (C-3) Containing Fluorine Atom]

(C-3-1) DAIFREE FB-962 (manufactured by Daikin Industries Co., Ltd.)

[Solvent]

(C-2-1) N-Methyl-2-pyrrolidone (NMP) (manufactured by Wako Pure Chemical Industries, Ltd.)

(C-2-2) Anisole (manufactured by Wako Pure Chemical Industries, Ltd.)

(C-2-3) Propylene glycol monomethyl ether acetate (PGMEA) (manufactured by Wako Pure Chemical Industries, Ltd.)

(C-2-4) Limonene (manufactured by Kanto Chemical Co., Inc.)

<Manufacture of Adhesiveness Test Piece>

As described in the following table, a member to be treated, having each of a support having an adhesive layer and a protective layer, was subjected to compression under a pressure of 1,000 N and at 190° C. in vacuum, thereby manufacturing an adhesiveness test sample.

<Adhesive Strength Measurement of Adhesiveness Test Piece>

The shear adhesion test piece that had prepared under the conditions described in the following table was subjected to a tensile measurement using a tensile tester (Digital Force Gauge manufactured by Imada Ltd., Model: ZP-50N) in a direction along the surface of the adhesive layer under the condition of 250 mm/min, and evaluated by the following criteria.

A: More strongly adhered as a wafer is more cracked

B: Peeled with a force of more than 10 N and 50 N or less

C: Peeled with a force of 10 N or less

<Peelability>

A test piece which had been manufactured under the conditions described in the following table was pulled in the direction perpendicular to the adhesive layer under the condition of 250 mm/min to confirm the peelability. Further, the manufactured test piece was heated at 250° C. for 30 minutes, and pulled in the vertical direction of the adhesive layer under the condition of 250 mm/min in the same manner to confirm the peelability after the thermal process, and evaluation was carried out by the following criteria. Further, the presence or absence of damage to the Si wafer was visually confirmed.

A: Peeled at a maximum peeling force of less than 15 N

B: Peeled at a maximum peeling force of 15 N or more and less than 25 N

C: Peeled at a maximum peeling force of 25 N or more and less than 40 N

D: The maximum peeling force was 50 N or more and the wafer was damaged

<Total Thickness Variation: TTV>

For a bonding wafer, the back surface side with respect to the bonding surface of the member to be treated became thinner using a grinder (DFG8560) manufactured by DISCO Corporation until the film thickness of the member to be treated became 100 μm. Then, the layer thickness of the member to be treated was measured using a semiconductor substrate surface inspecting apparatus (SemDex300) manufactured by ISIS Corporation, and a difference between the minimum value and the maximum value in the thickness was determined and evaluated by the following criteria.

A: The difference between the minimum value and the maximum value is 5 μm or less

B: The difference between the minimum value and the maximum value is more than 5 μm

<Cleaning and Removing Properties>

A 200-mm wafer (exposed to the test conditions for heat resistance) installed in a dicing frame was set in a spin coater having the adhesive layer on the top thereof through a dicing tape after completion of the peelability test, a solvent described in the following table as a cleaning solvent was used and sprayed for 5 minutes, and then while rotating the wafer, isopropyl alcohol (IPA) was sprayed for rinsing. Thereafter, the appearance was visually observed to check the presence or absence of the remaining adhesive resin and evaluated by the following criteria.

A: The residual resin is not perceived

B: The residual resin is perceived

TABLE 3

| | | Member to | | | | | | |
|---|---|---|---|---|---|---|---|---|
| | Support | be treated | | Peelability | | | Cleaning and | |
| | having an | having | Measurement | | After | | removing | |
| | adhesive | protective | of adhesive | | process at | TTV | properties | |
| | layer | layer | force | Normal | 250° C. | μm | Solvent | Results |
| Example 1 | (1) | (2) | A | B | C | A | Anisole | A |
| Example 2 | (2) | (2) | A | B | C | A | Anisole | A |
| Example 3 | (3) | (2) | A | B | C | A | Anisole | A |
| Example 4 | (4) | (2) | A | B | C | A | Anisole | A |
| Example 5 | (5) | (2) | A | B | B | A | Anisole | A |
| Example 6 | (6) | (2) | A | B | C | A | Anisole | A |
| Example 7 | (7) | (2) | A | A | A | A | Anisole | A |
| Example 8 | (8) | (2) | A | A | A | A | Anisole | A |
| Example 9 | (9) | (2) | A | A | A | A | Anisole | A |
| Example 10 | (10) | (2) | A | B | B | A | Anisole | A |
| Example 11 | (11) | (2) | A | B | B | A | Anisole | A |
| Example 12 | (12) | (2) | A | B | B | A | Anisole | A |
| Example 13 | (13) | (2) | A | B | C | A | Anisole | A |
| Example 14 | (14) | (2) | A | A | B | A | Anisole | A |
| Example 15 | (15) | (2) | A | A | A | A | Anisole | A |
| Example 16 | (16) | (2) | A | B | B | A | Anisole | A |
| Example 17 | (17) | (2) | A | A | B | A | Anisole | A |
| Example 18 | (18) | (2) | A | A | A | A | Anisole | A |
| Example 19 | (19) | (2) | A | B | B | A | Anisole | A |
| Example 20 | (20) | (2) | A | A | B | A | Anisole | A |
| Example 21 | (21) | (2) | A | A | A | A | Anisole | A |
| Example 22 | (22) | (2) | A | B | B | A | Anisole | A |
| Example 23 | (23) | (2) | A | A | B | A | Anisole | A |
| Example 24 | (24) | (2) | A | A | A | A | Anisole | A |
| Example 25 | (25) | (2) | A | B | B | A | Anisole | A |
| Example 26 | (26) | (2) | A | A | B | A | Anisole | A |
| Example 27 | (27) | (2) | A | A | A | A | Anisole | A |
| Example 28 | (5) | (1) | A | B | B | A | NMP | A |
| Example 29 | (8) | (1) | A | A | A | A | PGMEA | A |
| Example 30 | (11) | (1) | A | B | B | A | Limonene | A |
| Example 31 | (5) | (3) | A | C | C | A | NMP | A |
| Example 32 | (8) | (3) | A | A | A | A | PGMEA | A |
| Example 33 | (11) | (3) | A | B | B | A | Limonene | A |
| Example 34 | (5) | (4) | A | C | C | A | NMP | A |
| Example 35 | (8) | (3) | A | A | A | A | PGMEA | A |
| Example 36 | (11) | (4) | A | B | B | A | Limonene | A |
| Example 37 | (28) | (2) | A | A | B | A | Anisole | A |
| Example 38 | (29) | (2) | A | A | A | A | Anisole | A |
| Example 39 | (30) | (2) | A | A | A | A | Anisole | A |
| Example 40 | (5) | (5) | A | A | B | A | NMP | A |
| Example 41 | (5) | (6) | A | A | B | A | PGMEA | A |
| Example 42 | (28) | (5) | A | A | B | A | NMP | A |
| Example 43 | (29) | (5) | A | A | A | A | NMP | A |
| Example 44 | (30) | (5) | A | A | A | A | NMP | A |
| Example 45 | (28) | (6) | A | A | B | A | PGMEA | A |
| Example 46 | (29) | (6) | A | A | A | A | PGMEA | A |
| Example 47 | (30) | (6) | A | A | A | A | PGMEA | A |
| Example 48 | (5) | (5) | A | A | B | A | NMP | A |
| Example 49 | (5) | (6) | A | B | C | A | PGMEA | A |
| Example 50 | (11) | (5) | A | A | A | A | NMP | A |
| Example 51 | (11) | (6) | A | A | A | A | PGMEA | A |
| Comparative | (1) for | (2) | A | D | D | A | Anisole | B |
| Example 1 | Comparative | | | | | | | |
| | Example | | | | | | | |
| Comparative | (2) for | (2) | A | D | D | A | Anisole | B |
| Example 2 | Comparative | | | | | | | |
| | Example | | | | | | | |
| Comparative | (3) for | (2) | A | D | D | A | Anisole | B |
| Example 3 | Comparative | | | | | | | |
| | Example | | | | | | | |
| Comparative | (4) for | (2) | C | A | A | B | Anisole | A |
| Example 4 | Comparative | | | | | | | |
| | Example | | | | | | | |
| Comparative | (5) | (1) for | C | C | C | B | — | B |
| Example 5 | | Comparative | | | | | | |
| | | Example | | | | | | |

It could be seen that Examples 1 to 36, relating to the laminate of the present invention, good results in terms of adhesiveness and peelability were obtained, and the TTV and the cleaning properties were also excellent. On the other hand, it could be seen that the peelability is deteriorated in Comparative Examples 1 to 4, using the adhesive layer having a softening point of lower than 250° C. Further, it could be seen that Comparative Example 5 having no protective layer is deteriorated in all of adhesiveness, peelability, TTV, and cleaning properties.

Furthermore, it could be seen that adhesive force, peelability, TTV, and cleaning properties can be further improved by incorporating a radically polymerizable monomer containing a fluorine atom into an adhesive layer precursor (Examples 7, 8, 15, 18, 21, 24, 27, 29, 32, and 35).

Further, it could be seen that the peelability is further improved by incorporating a radically polymerizable monomer containing a fluorine atom into an adhesive layer precursor and further incorporating a compound containing a fluorine atom into an adhesive layer precursor or protective layer (Examples 38, 39, 43, 44, 46, 47, 50, and 51)

### EVALUATION OF REFERENCES

11 Adhesive layer precursor

12 Support (carrier substrate)

13, 21 to 30, 11′ Adhesive layers

11A, 21A to 30A, 131 Strongly adhesive regions

11B, 21B to 30B, 132 Weakly adhesive regions

30 Mask

60 Device wafer

60′ Thin device wafer

61′ Silicon substrate

61a Surface of silicon substrate

61b Back surface of silicon substrate

61b′ Back surface of thin device wafer

62 Device chip

63 Structure

70 Tape

71 Protective layer

80 Temporary adhesive layer

100, 100′ Adhesive supports

1. A laminate comprising, on a support (A):
an adhesive layer having a softening point of 250° C. or higher (B);
a protective layer (C); and
a device wafer (D) in this order,
wherein the adhesive layer (B) is a cured product of an adhesive layer precursor and the adhesive layer precursor has a polymerizable compound (b-1).

2. The laminate according to claim 1, wherein the adhesive layer has a 3-dimensional crosslinked structure.

3. The laminate according to claim 1, wherein the polymerizable compound (b-1) includes at least one kind of trifunctional or higher functional radically polymerizable compound.

4. The laminate according to claim 1, wherein the polymerizable compound (b-1) includes at least one kind of radically polymerizable compound containing a fluorine atom.

5. The laminate according to claim 1, wherein the adhesive layer precursor further includes a photo-radical initiator (b-2).

6. The laminate according to claim 1, wherein the adhesive layer precursor further includes a thermo-radical initiator (b-3).

7. The laminate according to claim 1, wherein the adhesive layer precursor further includes a polymer compound (b-4).

8. The laminate according to claim 1, wherein the softening point of the protective layer (C) is from 170° C. to 250° C.

9. The laminate according to claim 1, wherein the protective layer (C) is a thermoplastic resin.

10. The laminate according to claim 1, wherein the protective layer (C) is at least one kind of thermoplastic resin selected from a polyethersulfone resin, a polyimide resin, a polyester resin, a polybenzimidazole resin, a polyester resin, a polyamideimide resin, and a polyetheretherketone resin.

11. The laminate according to claim 1, wherein the device wafer (D) has a structure having a height of from 1 μm to 150 μm on the surface.

12. The laminate according to claim 1, wherein the film thickness of the device wafer (D) is 100 μm or less.

13. The laminate according to claim 1, wherein the temperature difference in the softening point between the adhesive layer and the protective layer is from 10° C. to 300° C.

14. A composition for forming a protective layer, used for producing the laminate according to claim 1, comprising a resin and a solvent.

15. The composition for forming a protective layer according to claim 14, wherein the softening point of the resin is from 170° C. to 250° C.

16. A composition for forming an adhesive layer, used for producing an adhesive layer of the laminate according to claim 1, comprising a solvent and a polymerizable compound (b-1).

17. The composition for forming an adhesive layer according to claim 16, further comprising a photo-radical initiator (b-2).

18. The composition for forming an adhesive layer according to claim 16, further comprising a thermo-radical initiator (b-3).

19. The composition for forming an adhesive layer according to claim 16, further comprising a polymer compound (b-4).

20. A kit comprising a composition for forming a protective layer, comprising a resin and a solvent, and a composition for forming an adhesive layer, including a solvent and a polymerizable compound.

21. The kit according to claim 20, in which the softening point of the resin included in the composition for forming a protective layer is from 170° C. to 250° C.

22. The kit according to claim 20, which is a kit for the production of a laminate comprising, on a support (A):
an adhesive layer having a softening point of 250° C. or higher (B);
a protective layer (C); and
a device wafer (D) in this order,
wherein the adhesive layer (B) is a cured product of an adhesive layer precursor and the adhesive layer precursor has a polymerizable compound (b-1).
